(19) United States
(12) Patent Application Publication
(10) Pub. No.: US 2026/0244101 A1
(43) Pub. Date: Aug. 20, 2026

(54) PHOTOSENSITIVE RESIN COMPOSITION, METHOD FOR PRODUCING CURED RELIEF PATTERN, CURED FILM, AND SEMICONDUCTOR DEVICE

(71) Applicant: ASAHI KASEI KABUSHIKI KAISHA, Tokyo (JP)

(72) Inventors: Kohei MURAKAMI, Tokyo (JP); Kazuhisa YAMOTO, Tokyo (JP); Yuka SATO, Tokyo (JP); Satoshi SHIBUI, Tokyo (JP)

(73) Assignee: ASAHI KASEI KABUSHIKI KAISHA, Tokyo (JP)

(21) Appl. No.: 19/160,998

(22) PCT Filed: Mar. 29, 2024
(86) PCT No.: PCT/JP2024/013126

§ 371 Date: Aug. 29, 2025

(30) Foreign Application Priority Data
Apr. 4, 2023 (JP) 2023-060777

(51) Int. Cl. G03F 7/037; C08G 73/10; G03F 7/028

(52) U.S. Cl. CPC G03F 7/037; C08G 73/1071; G03F 7/028

(57) ABSTRACT

The present disclosure relates to a photosensitive resin composition, a method for producing a cured relief pattern, a cured film, and a semiconductor device. The photosensitive resin composition comprises: (A) a polyimide (A1) having an aromatic ring in a side chain and/or a polyimide (A2) having a structure represented by general formula (1); (B) a solvent; and (C) a photopolymerization initiator.

### FIELD

The present disclosure relates to a photosensitive resin composition, a method for producing a cured relief pattern, and a cured film, and a semiconductor device.

### BACKGROUND

There have conventionally been used, as insulating materials for electronic components, passivation films, surface protective films and interlayer insulating films for semiconductor devices, polyimide resins, polybenzoxazole resins and phenolic resins which have excellent heat resistance, electrical properties and mechanical properties. Of these resins, those provided in the form of a photosensitive resin composition can easily form a heat-resistant relief pattern film by application, exposure, development and ring closure treatment (imidization, benzoxazolization) and thermal crosslinking due to curing of the composition, thus enabling significant reduction in terms of processing compared to conventional non-photosensitive materials, and is therefore used in the fabrication of semiconductor devices.

It should be noted that semiconductor devices (hereinafter also referred to as “elements”) are mounted on a printed circuit board by various methods according to purposes. Conventional elements have commonly been produced by a wire bonding method in which a thin wire is used to connect an external terminal (pad) of the element to a lead frame. However, in recent years, the speed of the element has increased and the operating frequency has reached GHz levels, and thus a difference in wiring length of each terminal in mounting affects the operation of the element. Therefore, in the mounting of the element for high-end applications, it has become necessary to accurately control the length of the mounting wiring, leading to difficulty in meeting demand by wire bonding.

Therefore, there has been proposed flip-chip mounting in which a rewiring layer is formed on the surface of a semiconductor chip and, after forming bumps (electrodes) thereon, the chip is flipped over and mounted directly on a printed circuit board. Since this flip-chip mounting can accurately control the wiring distance, it has been adopted for high-end devices which handle high-speed signals, or mobile phones due to its small mounting size, and therefore demand is growing rapidly. More recently, there has been proposed a semiconductor chip mounting technique called fan-out wafer level package (FOWLP) in which a pre-processed wafer is diced to produce individual chips, which are then reconstructed on a support, and after sealing with a mold resin, a rewiring layer is formed after stripping off the support. In FOWLP, since the rewiring layer is formed at a small film thickness, the height of the package can be reduced, resulting in advantages such as high-speed transmission and cost reduction. Photosensitive resin compositions for use in the rewiring layer are known from, for example, PTL 1 and PTL 2.

### CITATION LIST

### Patent Literature

[PTL 1] WO 2018/037997 A
[PTL 2] JP 2021-162834 A

### SUMMARY

### Technical Problem

It should be noted that in the case of FOWLP, the rewiring layer often has a multi-layered structure. In the photolithography process using a photoresist, if the photosensitive resin composition has poor flatness, the focus depth shifts, thus causing a problem that the resolution significantly deteriorates. Therefore, the film of the photosensitive resin compositions are required to have high flatness. Since the copper wiring and the rewiring layer are in contact with each other due to the structure of the package, the photosensitive resin composition is also required to have adhesion to copper, and to suppress the migration effect of copper ions. Furthermore, from the viewpoint of protection of semiconductor chips, good mechanical properties and chemical resistance are required.

However, when a polyimide film is formed using the polyimide precursor mentioned in PTL 1, the side chain component volatilizes as imide cyclization occurs during curing of the precursor, and the film shrinks, so that the film conforms to the irregular shape of the base, thus making it difficult to obtain a flat insulating layer. In view of this, using an already ring-closed resin (e.g., polyimide) has been considered. However, when the polyimide has a rigid planar structure, such polyimide has low solubility, thus making it difficult to obtain a desired photosensitive resin composition.

PTL 2 reports that by using a polyimide having a fluorine atom in the main chain skeleton as a resin, the solubility is ensured despite the already ring-closed structure, and cure shrinkage is successfully suppressed. However, PTL 2 had a problem in that, since the main chain skeleton has a fluorine atom, the film density of the cured film is reduced, leading to an improvement in oxygen permeability, resulting in copper migration.

An object of the present disclosure is to provide a photosensitive resin composition which has high solubility despite using a resin having an already ring-closed structure, and which is capable of forming a cured relief pattern that can achieve improved mechanical properties, suppressed cure shrinkage, improved copper adhesion, improved chemical resistance, and suppressed copper migration.

Another object of the present disclosure is to provide a polyimide obtained by using such a photosensitive resin composition, a method for producing a cured relief pattern, a cured film, and a semiconductor device.

### Solution to Problem

Specifically, one embodiment of the present invention is as follows.

[1]

A photosensitive resin composition comprising:
(A) a polyimide of the following (A1) and/or (A2):
(A1) a polyimide having an aromatic ring in a side chain, and
(A2) a polyimide having a structure represented by the following general formula (1):

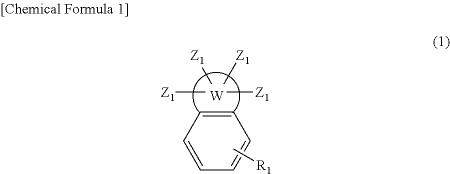

wherein W is an aromatic ring or aliphatic ring which may have any substituent other than Z₁ (in which those having an aromatic ring are excluded), at least two Z₁ of a plurality of Z₁ form a main chain together with W, the remaining Z₁ is a hydrogen atom, and R₁ is a hydrogen atom or a monovalent organic group (in which those having an aromatic ring are excluded),
(B) a solvent, and
(C) a photopolymerization initiator.
   [2]

The photosensitive resin composition according to item 1, wherein, in (A1), the side chain has a structure represented by the following general formula (2):

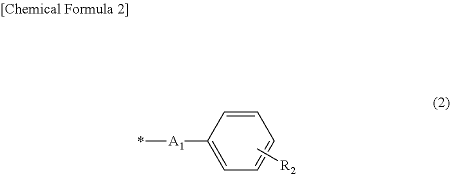

wherein A1 is a single bond, an alkylene group or an oxygen atom, * is a bonding site to the main chain, and R₂ is a hydrogen atom or a monovalent organic group, and
in the side chain, a ring containing an aromatic ring and R₂ in the general formula (2) may be formed.
   [3]

The photosensitive resin composition according to item 2, wherein the polyimide (A) does not have a photopolymerizable group in the side chain,
in the general formula (2), * is a bonding site to the aromatic ring of the main chain, and
the photopolymerization initiator (C) is a photoradical polymerization initiator.
   [4]

The photosensitive resin composition according to item 2, wherein the polyimide (A) does not contain a fluorine atom and a weighted average of the number of aromatic rings of a tetracarboxylic acid derivative used as a raw material is 2 or less, and
in which the weighted average is a weighted average of the number of aromatic rings contained in the one or plural tetracarboxylic acid derivative(s) used as the raw material when the mixing amount of the tetracarboxylic acid derivatives used as the raw material is treated as weight, and
the photopolymerization initiator (C) is a photoradical polymerization initiator.
   [5]

The photosensitive resin composition according to item 2, wherein the weighted average of the number of aromatic rings of a tetracarboxylic acid derivative used as a raw material of the polyimide (A) is 2 or less, and
in the general formula (2), * is a bonding site to the aromatic ring of the main chain, and
the photopolymerization initiator (C) is a photoradical polymerization initiator.
   [6]

The photosensitive resin composition according to item 2, wherein the polyimide (A) does not contain a fluorine atom, and does not have a photopolymerizable group in the side chain, and
the photopolymerization initiator (C) is a photoradical polymerization initiator.
   [7]

The photosensitive resin composition according to any one of items 1 to 6, wherein the general formula (1) has a structure represented by the following formula:

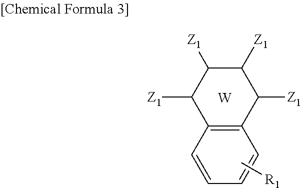

wherein W is a 6-membered ring, and Z1 and R1 are the same as in the general formula (1).
[8]

The photosensitive resin composition according to any one of items 1 to 7, wherein, in (A1), R₂ of the general formula (2) is a hydrogen atom.

[9]

The photosensitive resin composition according to any one of items 1 to 8, wherein the polyimide (A) has a structure represented by the following general formula (3):

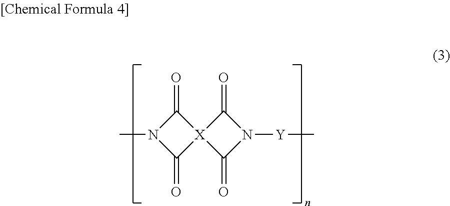

wherein n is a positive integer, and X is a tetravalent organic group having a structure represented by at least one selected from the group consisting of the following general formulas (4), (5) and (6):

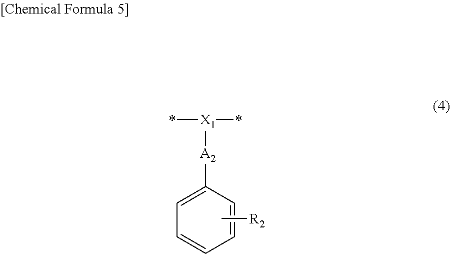

wherein X₁ is CH, C(CH₂)ₘCH₃ or a nitrogen atom, * forms a main chain together with X₁, A₂ is a single bond, an alkylene group or an oxygen atom, R₂ is a hydrogen atom or a monovalent organic group, and m is an integer of 0 to 10:

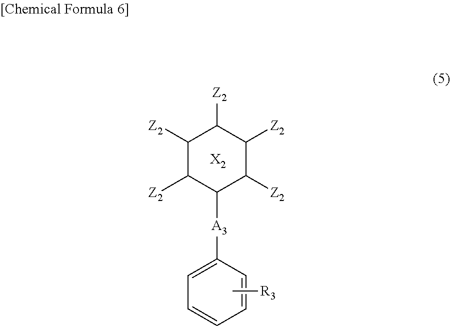

wherein X₂ is a 6-membered aromatic ring or 6-membered aliphatic ring which may have any substituent other than Z₂, A₃ is a single bond, an alkylene group or an oxygen atom, one to three Z₂ of a plurality of Z₂ is/are a hydrogen atom, the remaining Z₂ forms a main chain together with X₂, and R₃ is a hydrogen atom or a monovalent organic group, and:

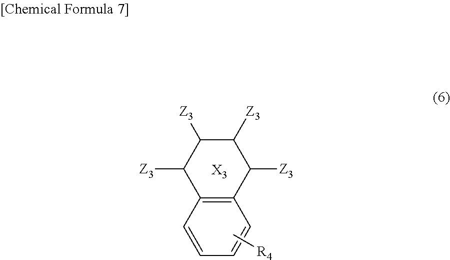

wherein X₃ is an aromatic ring or aliphatic ring which may have any substituent other than Z₃, zero to two Z₃ of a plurality of Z₃ is/are a hydrogen atom, the remaining Z₃ forms a main chain together with X₃, and R₄ is a hydrogen atom or a monovalent organic group, and/or
Y is a divalent organic group having a structure represented by at least one selected from the group consisting of the following general formulas (7) and (8):

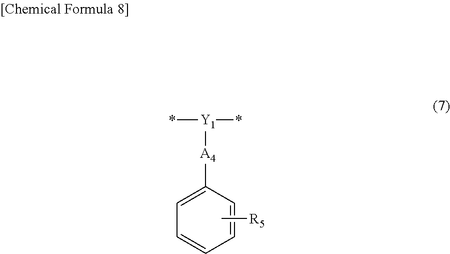

wherein Y₁ is CH, C(CH₂)ₘCH₃, a nitrogen atom, or a 6-membered aromatic ring, * forms a main chain together with Y₁, A₄ is a single bond, an alkylene group, or an oxygen atom, R₅ is a hydrogen atom or a monovalent organic group, and m is an integer of 0 to 10, and:

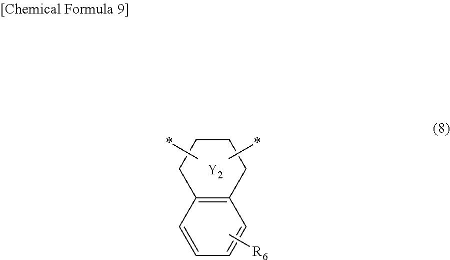

wherein Y₂ is a 6-membered aromatic ring or a 6-membered aliphatic ring, * forms a main chain together with Y₂, and R₆ is a hydrogen atom or a monovalent organic group.
[10]

The photosensitive resin composition according to item 9, wherein, in the general formulas (4) to (8), R₂ to R₆ are each independently a hydrogen atom or a hydroxy group.

[11]

The photosensitive resin composition according to any one of items 1 to 6, wherein X in the general formula (3) has a structure represented by the following general formula (9):

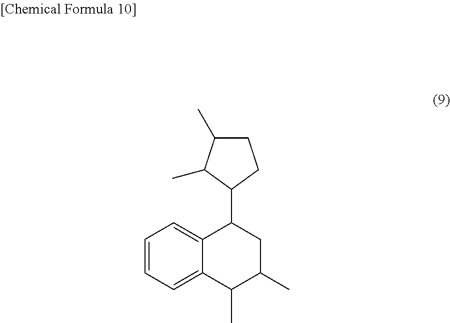

The photosensitive resin composition according to item 9 or 10, wherein Y in the general formula (3) has a structure represented by the following general formula (10):

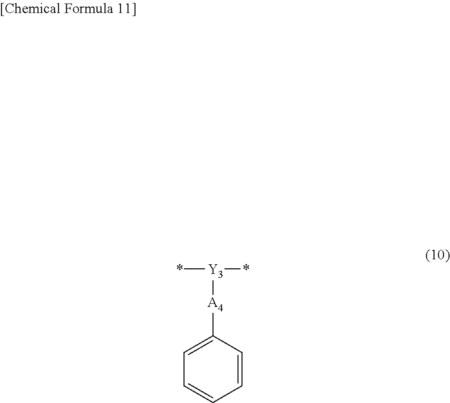

wherein Y₃ is a nitrogen atom, CH, C(CH₃) or an aromatic ring, * forms a main chain together with Y₃, and A₄ is a single bond or an oxygen atom.
[13]

The photosensitive resin composition according to any one of items 9 to 12, wherein Y in the general formula (3) has a structure represented by at least one selected from the group consisting of the following general formulas (11) to (14):

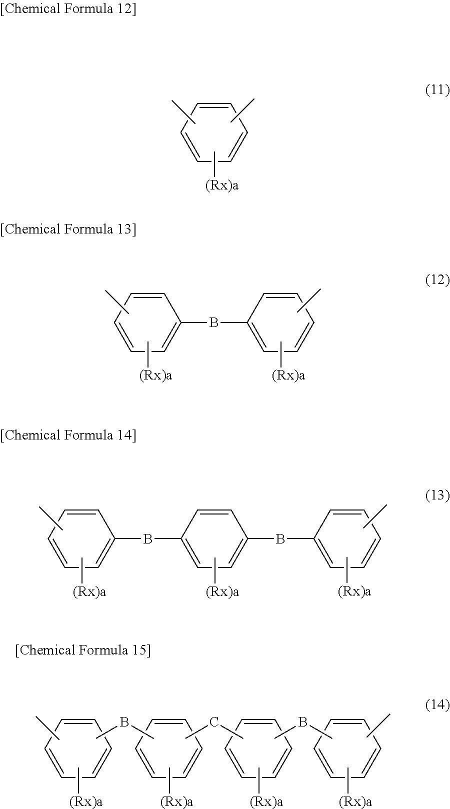

wherein R_{X} is each independently a monovalent organic group having 1 to 10 carbon atoms, and at least one of R_{X} as the side chain contains an aromatic ring, and a is each independently an integer of 0 to 4 (in which a corresponding to R_{X} as the side chain is an integer of 1 or more), B is a single bond, a methylene group or an oxygen atom, and C is a single bond or at least one selected from the group consisting of the following formulas, and:

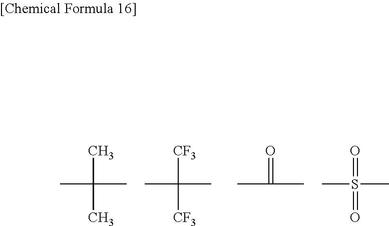

[14]

The photosensitive resin composition according to any one of items 9 to 13, wherein Y in the general formula (3) has a structure represented by at least one selected from the group consisting of the following general formulas (15) to (19):

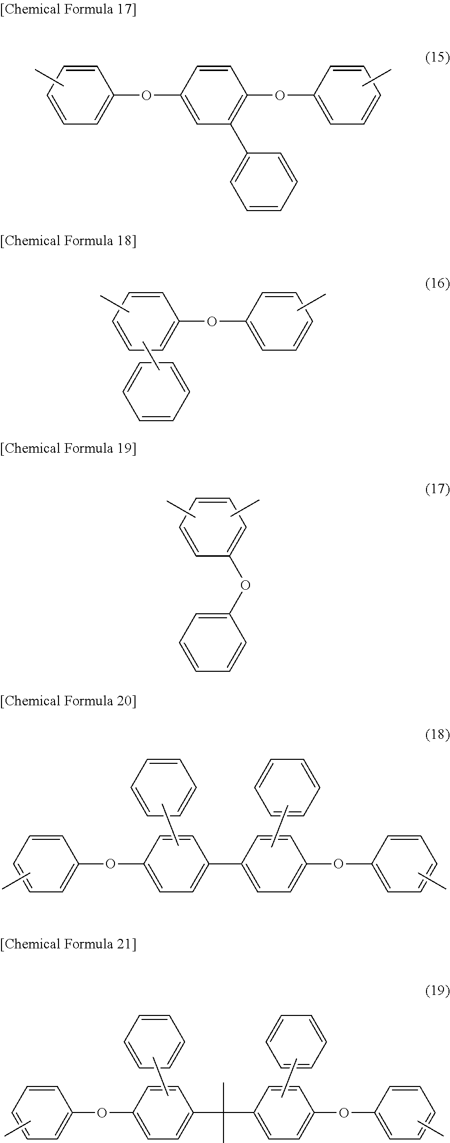

The photosensitive resin composition according to any one of items 9 to 14, wherein X in the general formula (3) has a structure represented by at least one selected from the group consisting of the following general formulas (20) to (25):

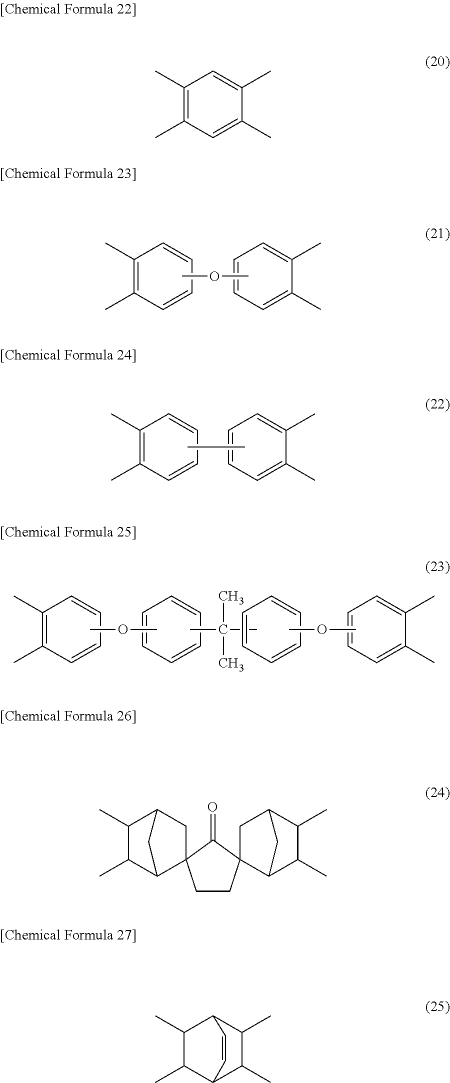

The photosensitive resin composition according to any one of items 9 to 15, wherein Y in the general formula (3) has a structure represented by at least one selected from the group consisting of the following general formulas (26) to (28):

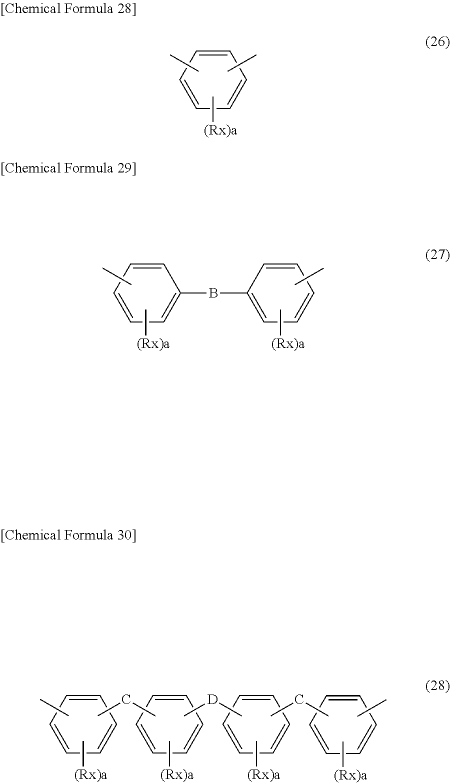

wherein R_{X} is each independently a monovalent organic group having 1 to 10 carbon atoms (in which those having an aromatic ring are excluded), a is each independently an integer of 0 to 4, B is a single bond, a methylene group, an oxygen atom or a sulfur atom, C is each independently an oxygen atom or a sulfur atom, and D is at least one selected from the group consisting of the following formulas:

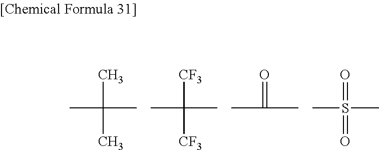

The photosensitive resin composition according to any one of items 1 to 16, further comprising (D) a monomer having a polymerizable functional group.

[18]

The photosensitive resin composition according to any one of items 1 to 17, further comprising, as (D) a monomer having a polymerizable functional group, (D1) a monofunctional monomer and (D2) a polyfunctional monomer, wherein a mass ratio (D1/D2) of the monofunctional monomer (D1) with respect to the polyfunctional monomer (D2) is more than 0.01 and less than 5.

[19]

The photosensitive resin composition according to any one of items 1 to 18, further comprising (E) a silane coupling agent.

[20]

The photosensitive resin composition according to any one of items 1 to 19, further comprising (F) a rust inhibitor.

[21]

The photosensitive resin composition according to any one of items 1 to 20, further comprising (G) an organic titanium compound.

[22]

The photosensitive resin composition according to any one of items 1 to 21, further comprising (H) a plasticizer.

[23]

The photosensitive resin composition according to any one of items 1 to 22, further comprising (I) a thermal crosslinking agent.

[24]

The photosensitive resin composition according to any one of items 1 to 23, further comprising (J) a thermal polymerization initiator.

[25]

The photosensitive resin composition according to any one of items 1 to 24, wherein the polyimide (A) has polymerizable functional group at the end of the main chain.

[26]

A method for producing a cured relief pattern, which comprises the following steps:
(1) a step of applying a photosensitive resin composition according to any one of items 1 to 24 on a substrate to form a photosensitive resin layer on the substrate,
(2) a step of exposing the photosensitive resin layer,
(3) a step of developing the photosensitive resin layer after exposure to form a relief pattern, and
(4) a step of subjecting the relief pattern to a heat treatment to form a cured relief pattern.
   [27]

A cured film comprising a cured product of the photosensitive resin composition according to any one of items 1 to 24.

[28]

A semiconductor device comprising the cured film according to item 27 as the insulating layer.

[29]

A polyimide (A) of the following (A1) and/or (A2):
(A1) a polyimide having an aromatic ring in a side chain, and
(A2) a polyimide having a structure represented by the following general formula (1):

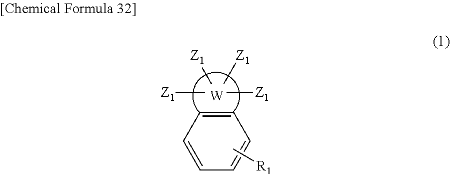

wherein W is an aromatic ring or aliphatic ring which may have any substituent other than Z₁ (in which those having an aromatic ring are excluded), at least two Z₁ of a plurality of Z₁ form a main chain together with W, the remaining Z₁ is a hydrogen atom, and R₁ is a hydrogen atom, or a monovalent organic group (in which those having an aromatic ring are excluded).
[30]
(A) a polyimide comprising, as raw materials, at least an acid anhydride having a Hansen Solubility Parameter (HSP) value of 25.5<δt<28.9, as estimated by Hansen Solubility Parameters in Practice (HSPiP), and/or a diamine having an HSP value of δd>20.0 and δp<7.6.
   [31]

A photosensitive resin composition comprising:
(A) a polyimide having, as raw materials, at least an acid anhydride having a Hansen Solubility Parameter (HSP) value of 25.5<δt<28.9, as estimated by Hansen Solubility Parameters in Practice (HSPiP), and/or a diamine having an HSP value of δd>20.0 and δp<7.6,
(B) a solvent, and
(C) a photopolymerization initiator.

### Advantageous Effects of Invention

According to the present disclosure, it is possible to provide a photosensitive resin composition which has high solubility despite using a resin having an already ring-closed structure, and which is capable of forming a cured relief pattern that can achieve improved mechanical properties, suppressed cure shrinkage, improved copper adhesion, improved chemical resistance, and suppressed copper migration.

According to the present disclosure, it is possible to provide a method for producing a cured relief pattern obtained by using such a photosensitive resin composition, a cured film, and a semiconductor device.

### DESCRIPTION OF EMBODIMENTS

Hereafter, embodiments of the present invention (hereinafter referred to as “present embodiments”) will be described in detail. Throughout the present description, structures represented by the same reference numerals in the general formulas may be independently selected and may be the same or different from each other, unless otherwise specified, when a plurality of structures are present in the molecule.

Structures represented by common reference numerals in different general formulas are also independently selected and may be the same or different from each other, unless otherwise specified.

In the following description, the upper limit or lower limit of a numerical range described in stages may be replaced with the upper limit or lower limit of another numerical range described in stages. In the following description, the upper or lower limit of a certain numerical range may be replaced with a value mentioned in Examples. Further, with regard to the term “step” in the following description, not only an independent step but also a step that cannot be clearly distinguished from other steps is included in this term, as long as the function of that “step” is achieved.

### First Embodiment

### <Negative Photosensitive Resin Composition>

The negative photosensitive resin composition of the present disclosure (hereinafter referred to as “photosensitive resin composition”) includes (A) a specific polyimide, (B) a solvent, and (C) a photopolymerization initiator. The photosensitive resin composition of the present disclosure may further include, in addition to the above-mentioned components, additives selected from the group consisting of (D) a monomer having a polymerizable functional group (radical polymerizable compound), (E) a silane coupling agent, (F) a rust inhibitor, (G) an organic titanium compound, (H) a plasticizer, (I) a thermal crosslinking agent and (J) a thermal polymerization initiator, and other components.

### (A) Polyimide

The photosensitive resin composition includes:
(A) a polyimide of the following (A1) and/or (A2):
(A1) a polyimide having an aromatic ring in a side chain, and
(A2) a polyimide having a structure represented by the following general formula (1):

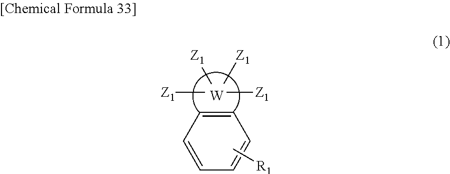

wherein W is an aromatic ring or aliphatic ring which may have any substituent other than Z₁ (in which those having an aromatic ring are excluded), at least two Z₁ of a plurality of Z₁ form a main chain together with W, the remaining Z₁ is a hydrogen atom, and R₁ is a hydrogen atom or a monovalent organic group (in which those having an aromatic ring are excluded).

By using such polyimide (A), solvent (B) and photopolymerization initiator (C), it is possible to provide a photosensitive resin composition which has high solubility despite using a resin having an already ring-closed structure (polyimide (A)), and which is capable of forming a cured relief pattern that can achieve improved mechanical properties, suppressed cure shrinkage, improved copper adhesion, improved chemical resistance, and suppressed copper migration.

Generally, aromatic polyimides often have a rigid planar structure, and in this case, they easily form an ordered structure, so that they are insoluble or infusible or in a state close to that in solvents generally assumed in this technical field, and as a result, they have the drawback of poor moldability. However, when the polyimide (A) is the polyimide (A1) and/or (A2) described above, an aromatic group is introduced into the polymer chain at a position somewhat distant from the main chain (e.g., a phenyl group is introduced as a side chain of the polymer, or an aromatic group is introduced by linking to a ring constituting the main chain of the polymer, or a fluorene structure is introduced as a side chain of the polymer), and therefore, despite not having a fluorine atom, the solubility in a solvent is greatly improved as compared with conventional aromatic polyimides having a rigid planar structure. This makes it possible to increase the molecular weight of the polyimide (A) even when the polyimide (A) has an already ring-closed structure, and also makes it possible for the resulting film to exhibit high mechanical properties.

Furthermore, as compared with a soluble polyimide containing a fluorine atom in the skeleton, the polyimide (A) can suppress copper ion migration while having the same degree of solubility in a solvent. Furthermore, since the (A) polyimide has an already ring-closed structure, the amount of volatilization in the curing step, and therefore the volumetric shrinkage of the film, can be suppressed as compared to the case where a polyimide precursor is used as the resin, and thus it is possible to obtain a cured film with high flatness.

In the present description, the term “already ring-closed structure” in relation to the polyimide refers to a structure obtained by already carrying out imidization (i.e., imide cyclization) of a polyimide precursor.

In the present description, the term “aromatic ring” includes not only a benzene ring structure but also a heterocyclic structure. Such heterocyclic ring structures may contain oxygen, nitrogen, sulfur, phosphorus atoms and the like.

In the present description, the “ring” may be, for example, a 4-membered ring, a 5-membered ring, or a 6-membered ring, and of these, a 6-membered ring is preferable. Even in an embodiment that includes such a ring and is likely to have high rigidity, the effects of the present embodiments can be suitably obtained according to the present embodiments.

In the above formula (1), when W is an aliphatic ring, W may have any substituent other than Z₁ (in which those having an aromatic ring are excluded). Any substituent mentioned here is preferably a monovalent organic group, for example, a hydrocarbon group having 1 to 4 carbon atoms.

It is preferable that the general formula (1) has a structure represented by the following formula:

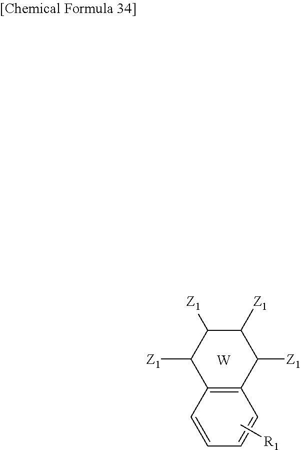

wherein W is a 6-membered ring, and Z₁ and R₁ are the same as in the above formula (1). This makes it easier to achieve the effects of the present embodiments.

In the above (A1), the side chain preferably has a structure represented by the following general formula (2):

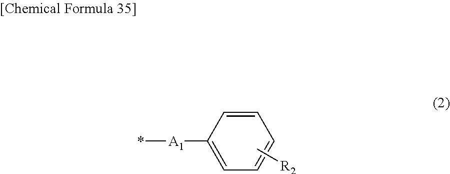

wherein A₁ is a single bond, an alkylene group or an oxygen atom, * is a bonding site to the main chain, and R₂ is a hydrogen atom or a monovalent organic group.

According to this, the aromatic group is introduced at a suitable position that is somewhat distant from the main chain, thus making it easier to achieve the effects of the present embodiments. In particular, in the above (A1) of formula (2), R₂ is preferably a hydrogen atom.

In the general formula (2), * is preferably a bonding site to the aromatic main chain from the viewpoint of the heat resistance.

In the side chain, a ring containing an aromatic ring and R2 in the above general formula (2) may be formed. When a ring containing an aromatic ring and R2 is formed, for example, a side chain having a fluorene structure is provided.

An example of a preferred embodiment of the present embodiments is as follows.

The above photosensitive resin composition, wherein the polyimide (A) does not have a photopolymerizable group in the side chain,
in the general formula (2), * is a bonding site to the aromatic ring of the main chain, and
the photopolymerization initiator (C) is a photoradical polymerization initiator.

A further example of a preferred embodiment of the present embodiments is as follows.

The above photosensitive resin composition, wherein the polyimide (A) does not contain a fluorine atom and a weighted average of the number of aromatic rings of a tetracarboxylic acid derivative used as a raw material is 2.0 or less, and
the photopolymerization initiator (C) is a photoradical polymerization initiator.

A further example of a preferred embodiment of the present embodiments is as follows.

The above photosensitive resin composition, wherein the weighted average of the number of aromatic rings of a tetracarboxylic acid derivative used as a raw material of the polyimide (A) is 2 or less, and
in the general formula (2), * is a bonding site to the aromatic ring of the main chain, and
the photopolymerization initiator (C) is a photoradical polymerization initiator.

A further example of a preferred embodiment of the present embodiments is as follows.

The above photosensitive resin composition, wherein the polyimide (A) does not contain a fluorine atom, and does not have a photopolymerizable group in the side chain, and
the photopolymerization initiator (C) is a photoradical polymerization initiator.

Specific examples of the polyimide (A) include a polyimide having a structure represented by the following general formula (3):

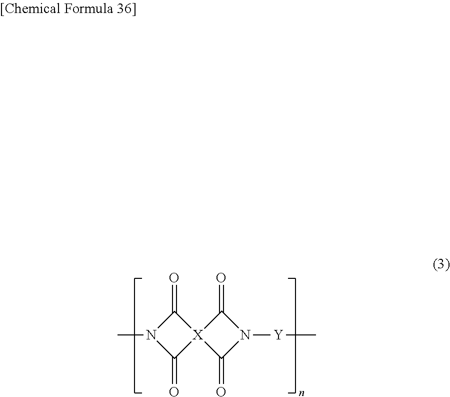

wherein n is a positive integer, and X is a tetravalent organic group having a structure represented by at least one selected from the group consisting of the following general formulas (4), (5) and (6):

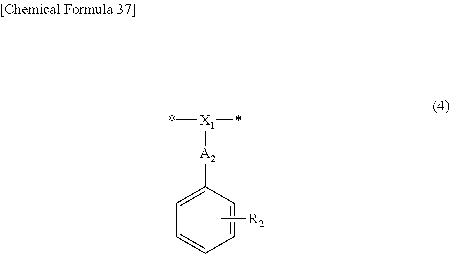

wherein X₁ is CH, C(CH₂)ₘCH₃ or a nitrogen atom, * forms a main chain together with X₁, A₂ is a single bond, an alkylene group or an oxygen atom, R₂ is a hydrogen atom or a monovalent organic group, and m is an integer of 0 to 10:

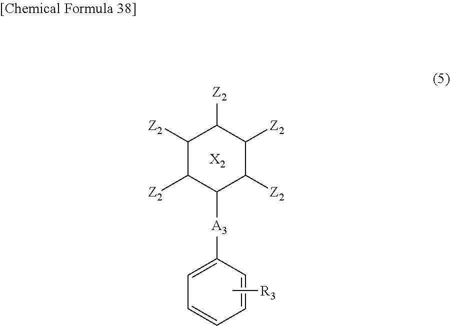

wherein X₂ is a 6-membered aromatic ring or 6-membered aliphatic ring which may have any substituent other than Z₂, A₃ is a single bond, an alkylene group or an oxygen atom, one to three Z₂ of a plurality of Z₂ is/are a hydrogen atom, the remaining Z₂ forms a main chain together with X₂, and R₃ is a hydrogen atom or a monovalent organic group, and:

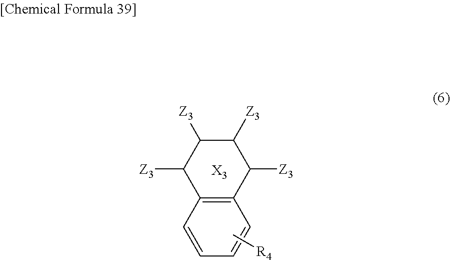

wherein X₃ is an aromatic ring or aliphatic ring which may have any substituent other than Z₃, zero to two Z₃ of a plurality of Z₃ is/are a hydrogen atom, the remaining Z₃ forms a main chain together with X₃, and R₄ is a hydrogen atom or a monovalent organic group, and/or
Y is a divalent organic group having a structure represented by at least one selected from the group consisting of the following general formulas (7) and (8):

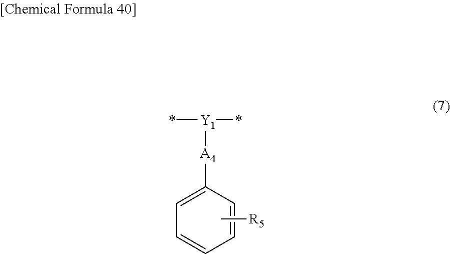

wherein Y₁ is CH, C(CH₂)ₘCH₃, a nitrogen atom, or a 6-membered aromatic ring, * forms a main chain together with Y₁, A₄ is a single bond, an alkylene group, or an oxygen atom, R₅ is a hydrogen atom or a monovalent organic group, and m is an integer of 0 to 10, and:

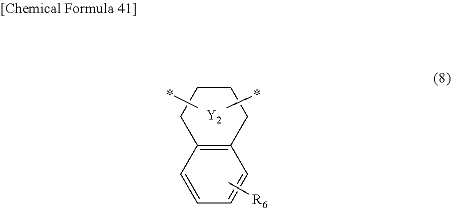

wherein Y₂ is a 6-membered aromatic ring or a 6-membered aliphatic ring, * forms a main chain together with Y₂, and R₆ is a hydrogen atom or a monovalent organic group.

This makes it easier to realize the embodiment in which an aromatic group is introduced into a position that is somewhat distant from the polymer main chain. This makes it easier to realize the present embodiment, and thus makes it easier to exhibit the effects of the present embodiments.

In formulas (4) to (8), it is preferable that R₂ to R₆ are each independently a hydrogen atom or a hydroxy group. Selecting a hydrogen atom or a hydroxy group may be sometimes advantageous for the solubility of the resin composition, and in particular, selecting a hydrogen atom may be sometimes advantageous for achieving both the solubility of the resin composition and various physical properties of the resulting film (e.g., chemical resistance, heat resistance, mechanical properties, etc.).

Polyimides having structures represented by the above formulas (4), (5) and (7) correspond to the component (A1), and polyimides having structures represented by the above formulas (6) and (8) correspond to the component (A2).

X may have a structure other than the structures represented by the above formulas (4) to (6), and Y may have a structure other than the structures represented by the above formulas (7) and (8).

X may contain a plurality of structures represented by the above formula (4), which may be the same or different from each other,
X may contain a plurality of structures represented by the above formula (5), which may be the same or different from each other, and
X may contain a plurality of structures represented by the above formula (6), which may be the same or different from each other.
Y may contain a plurality of structures represented by the above formula (7), which may be the same or different from each other, and
Y may contain a plurality of structures represented by the above formula (8), which may be the same or different from each other.

In the formula (3), n is preferably an integer of 2 to 200, and more preferably an integer of 3 to 100, from the viewpoints of the photosensitive properties and mechanical properties.

In this case, a plurality of X that can appear in each repeating unit may have structures different from each other, that is, a plurality of X may each independently have a structure represented by formula (4), (5) or (6).

A plurality of Y that can appear in each repeating unit may have structures different from each other, that is, a plurality of Y may each independently have a structure represented by formula (7) or (8).

X and Y may each have a structure corresponding to (A1) and/or (A2) and further have a structure other than the above.

The polyimide used in the present disclosure is synthesized from a tetracarboxylic dianhydride and a diamine. In formula (3), X represents a structure derived from a tetracarboxylic dianhydride, and Y represents a structure derived from a diamine. That is, the structure represented by the above formula (4), (5) or (6) introduced at the X position is a structure derived from a tetracarboxylic dianhydride, and the structure represented by the above formula (7) or (8) introduced at the Y position is a structure derived from a diamine.

Examples of X in formula (3) include a structure represented by the following general formula (9):

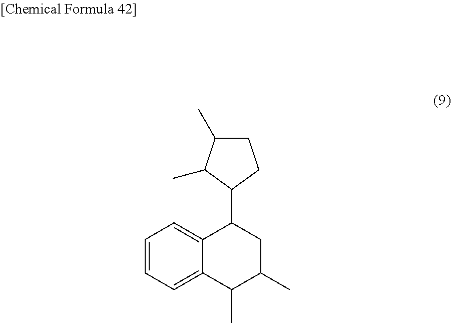

This makes it easier to realize an embodiment in which an aromatic group is introduced at a position somewhat distant from the polymer main chain. This makes it easier to realize the present embodiments, and ultimately makes it easier to achieve the effects of the present embodiments.

Examples of X having a structure represented by formula (4) include a structure selected from the group consisting of the following general formula (I):

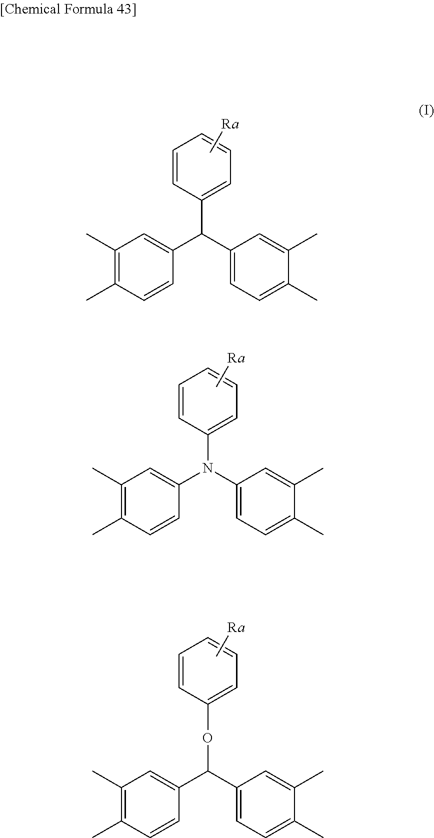

wherein Rₐ is each independently the same as R₂ in the above formula (4), and is, for example, at least one selected from the group consisting of a hydrogen atom and a monovalent hydrocarbon group having 1 to 10 carbon atoms.

Examples of X having a structure represented by formula (5) include a structure selected from the group consisting of the following general formula (II):

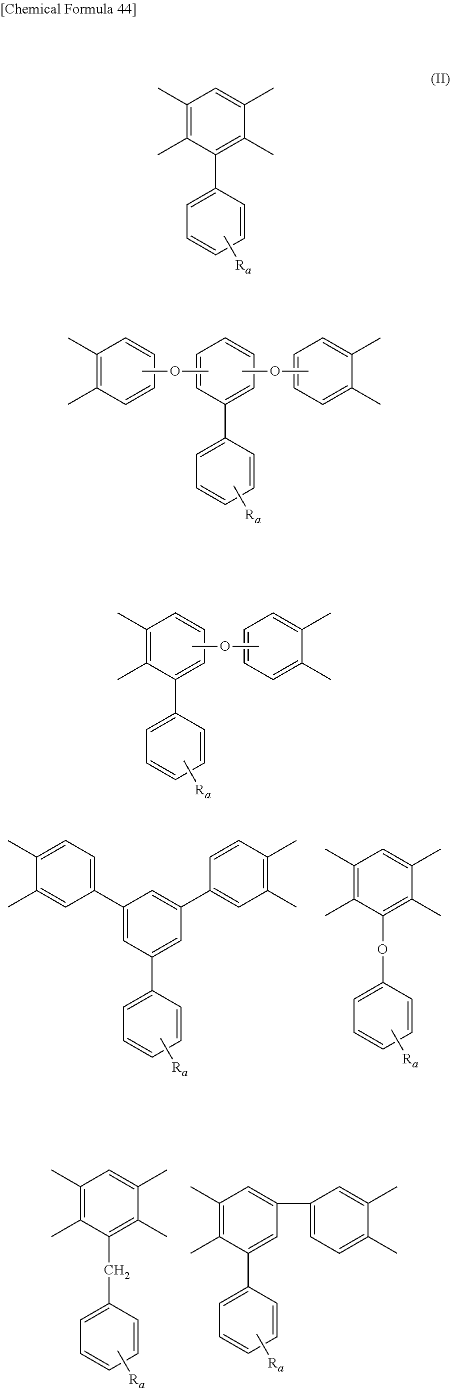

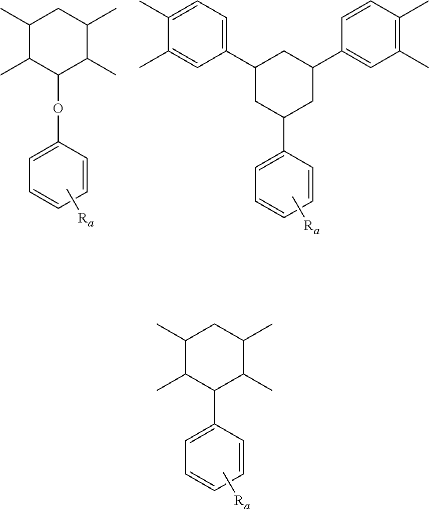

Rₐ is each independently the same as R₄ in the above formula (6), and is, for example, at least one selected from the group consisting of a hydrogen atom and a monovalent hydrocarbon group having 1 to 10 carbon atoms.

Examples of X having a structure represented by formula (6) include a structure selected from the group consisting of the following general formula (III):

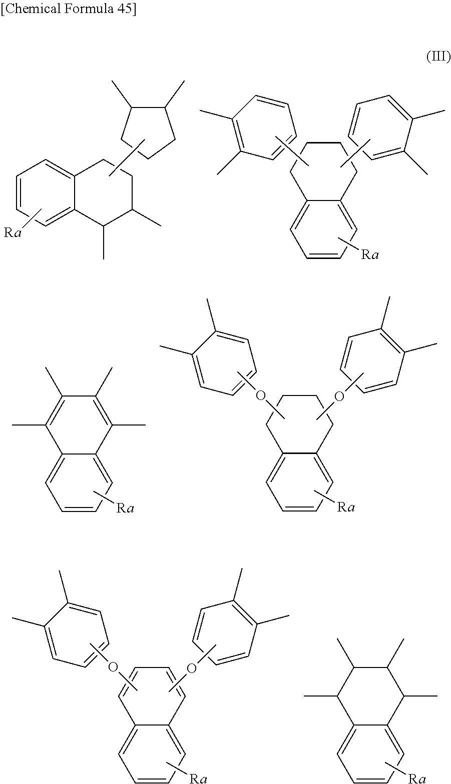

wherein Rₐ is each independently the same as R₃ in the above formula (5), and is, for example, at least one selected from the group consisting of a hydrogen atom and a monovalent hydrocarbon group having 1 to 10 carbon atoms.

The structure of X may be one or a combination of two or more of the above formulas (4) to (6), and further may be combined with a group selected from the group consisting of the following (IV):

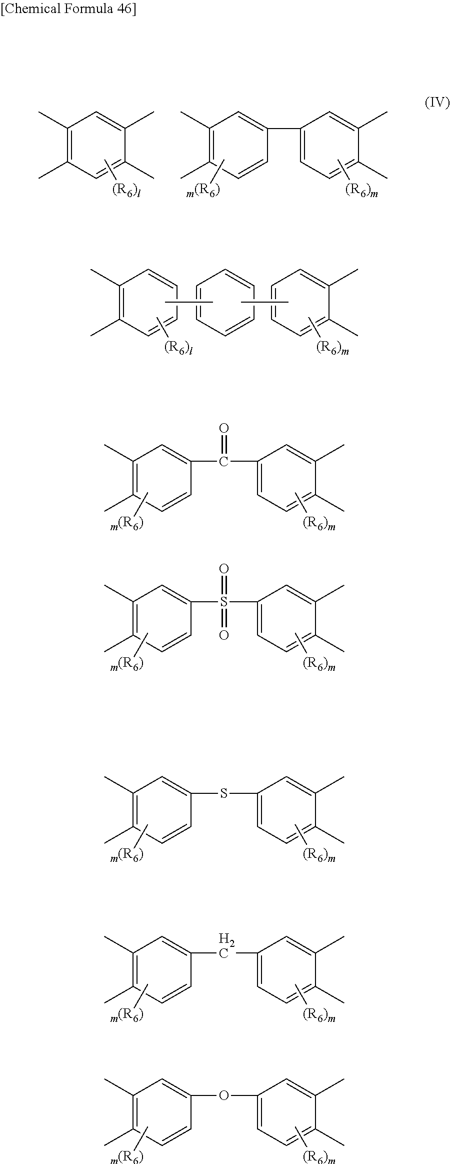

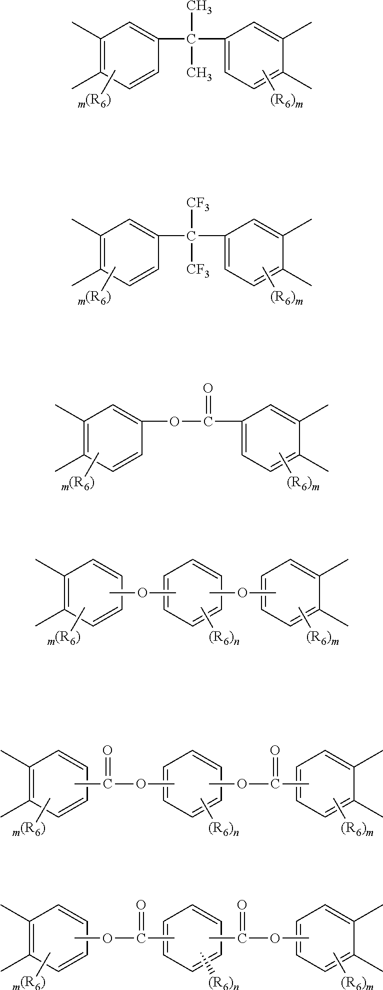

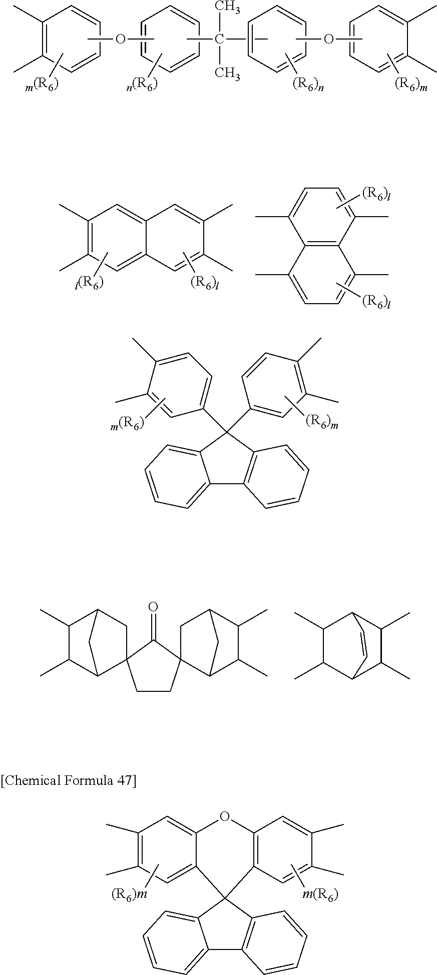

wherein R₆ is each independently at least one selected from the group consisting of a hydrogen atom and a monovalent hydrocarbon group having 1 to 10 carbon atoms; 1 is each independently an integer selected from 0 to 2; m is each independently an integer selected from 0 to 3; and n is each independently an integer selected from 0 to 4.

When X has a structure represented by the above (IV), of the above (IV), preferred is a group having a structure selected from the group consisting of the following general formula:

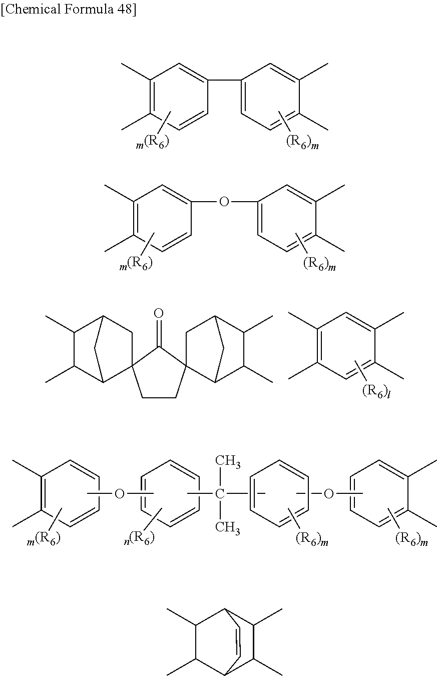

wherein R₆, l, m and n are the same as R₆, l, m and n in the above formula (IV), from the viewpoints of the mechanical properties, copper adhesion and chemical resistance.

It is particularly preferable that X in the general formula (3) has a structure represented by at least one selected from the group consisting of the following general formulas (20) to (25):

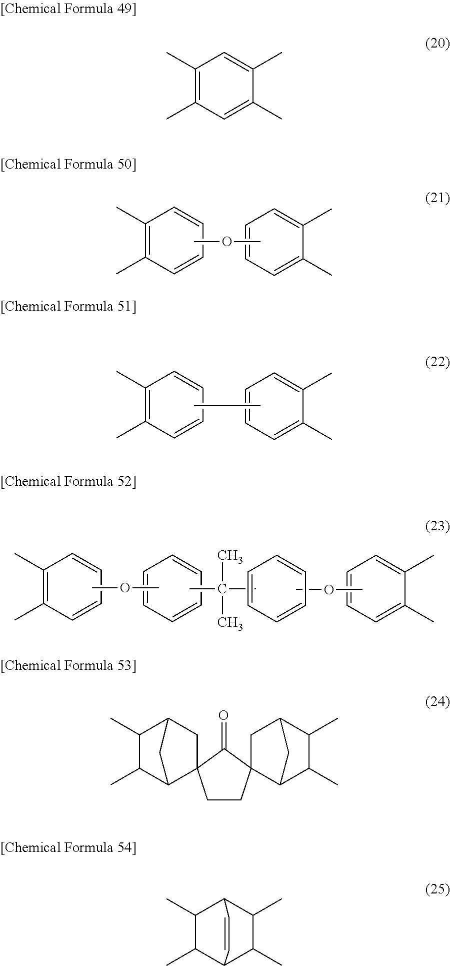

The proportion of the structures represented by the above formulas (4) to (6) in X, particularly the proportion of the structures represented by the above formulas (I) to (III), may be appropriately considered from the viewpoint of suitably obtaining the effects of the formulas (4) to (6).

From the viewpoint of the chemical resistance, it is preferable that a weighted average of the number of aromatic rings of a tetracarboxylic acid derivative used as a raw material of the polyimide is 2.0 or less. Here, the weighted average is a weighted average of the number of aromatic rings contained in the tetracarboxylic acid derivative used as the raw material when the mixing amount of one or plural tetracarboxylic acid(s) derivative used as the raw material is treated as weight. The value of the “weighted average of the number of aromatic rings” can be controlled by adjusting the type and amount of the tetracarboxylic acid derivative used as the raw material.

For example, in the production of the polyimide, when a tetracarboxylic acid derivative Ai having Ni aromatic rings is used in an amount of Wi (g), the above-described “weighted average of the number of aromatic rings” is calculated by the following formula:

$$\sum \{ ( Ni \times Wi ) / Wi \}$$

where i is an integer of 1 or more, and it may be, for example, 10 or less.

It is preferable that Y in formula (3) has a structure represented by the following general formula (10):

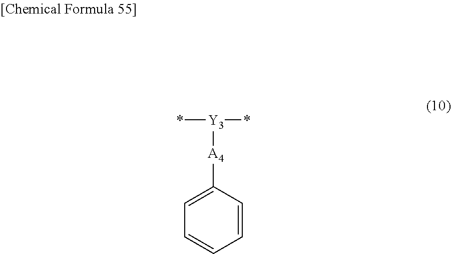

wherein Y₃ is a nitrogen atom, CH, C(CH₃) or an aromatic ring, * forms a main chain together with Y₃, and A₄ is a single bond or an oxygen atom.

This makes it easier to realize an embodiment in which an aromatic group is introduced at a position somewhat distant from the polymer main chain. This makes it easier to realize the present embodiments, and ultimately makes it easier to achieve the effects of the present embodiments.

It is preferable that Y in the formula (3) has at least one structure selected from the group consisting of the following general formulas (11) to (14):

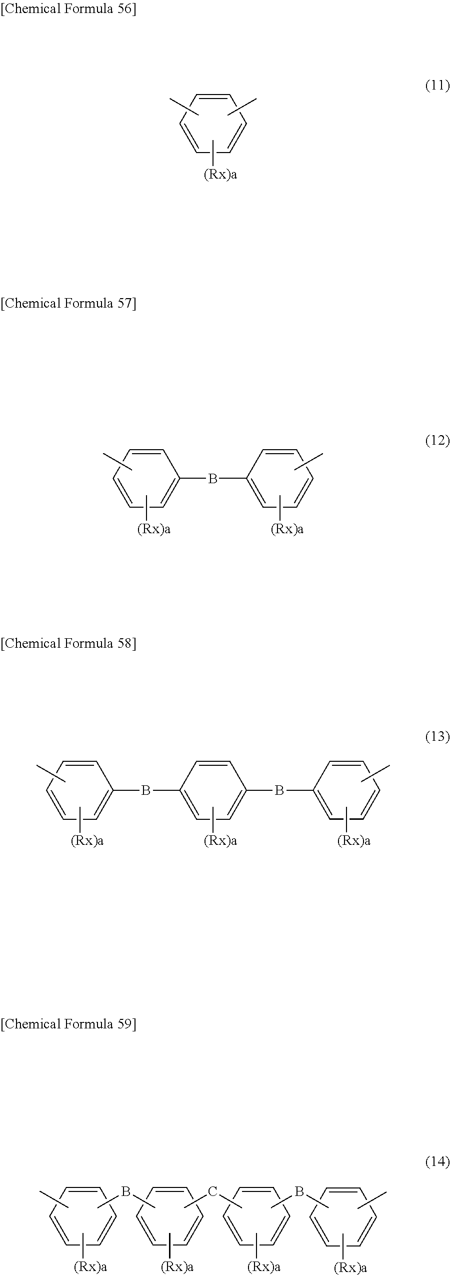

wherein R_{X} is each independently a monovalent organic group having 1 to 10 carbon atoms, and at least one of R_{X} as a side chain contains an aromatic ring, a is each independently an integer of 0 to 4 (in which a corresponding to R_{X} as a side chain is an integer of 1 or more), B is a single bond, a methylene group or an oxygen atom, and C is a single bond or at least one selected from the group consisting of the following formulas:

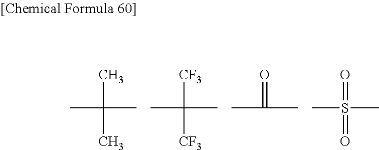

This makes it easier to realize an embodiment in which an aromatic group is introduced at a position somewhat distant from the polymer main chain. This makes it easier to realize the present embodiments, and ultimately makes it easier to achieve the effects of the present embodiments.

Formulas (11) to (14) include an embodiment in which a phenyl group is bonded to an aromatic ring constituting the main chain, and also include an embodiment in which an aromatic group is bonded to an aromatic ring constituting the main chain via any group. For example, formulas (11) to (14) include an embodiment in which an aromatic group is bonded to an aromatic ring constituting the main chain via an oxygen atom, and in this case, R_{X} can be a phenoxy group (—O-Ph).

Examples of Y having a structure represented by formula (7) include a structure selected from the group consisting of the following general formula (V):

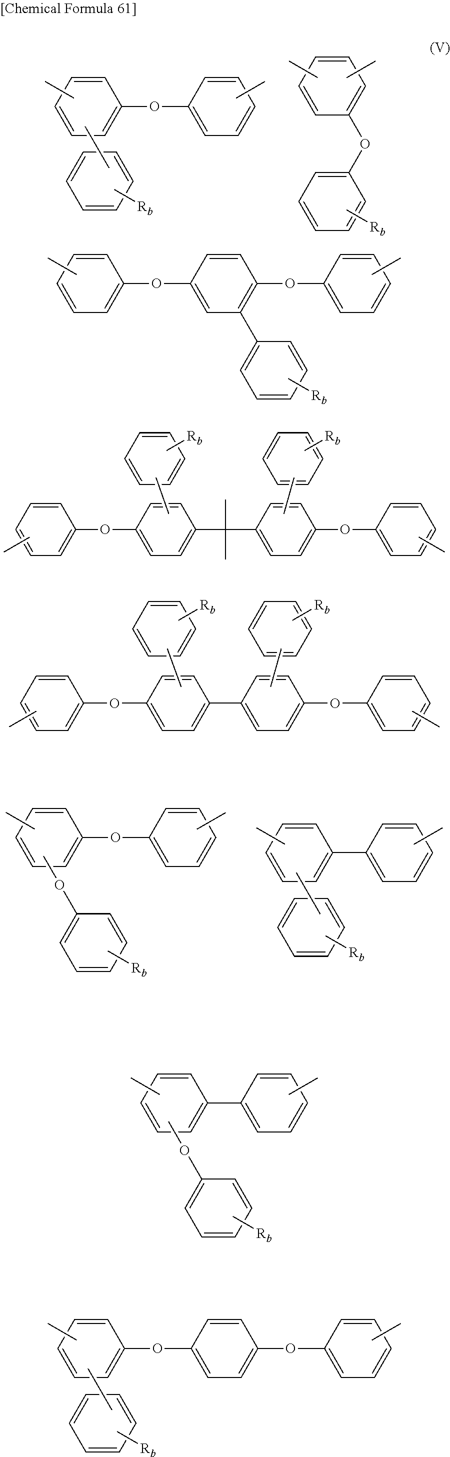

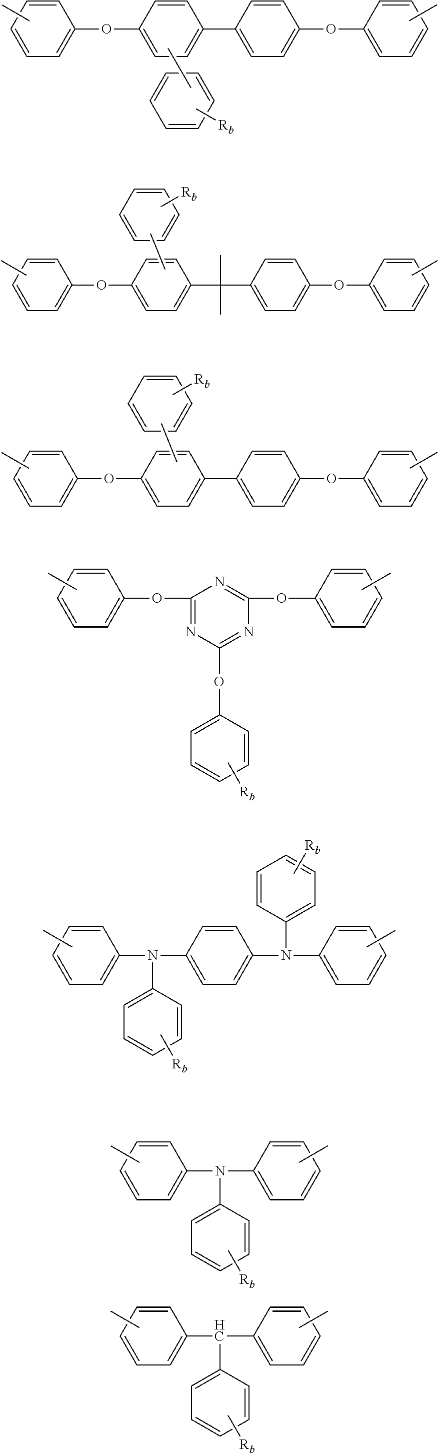

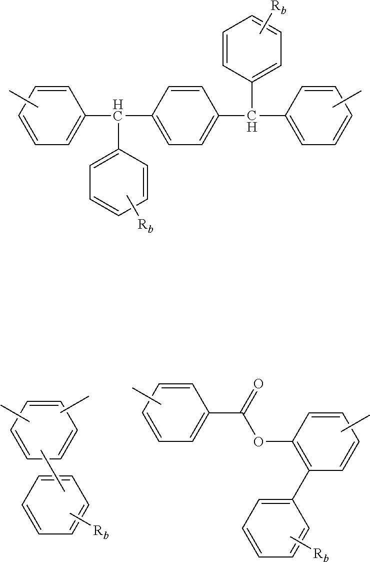

where R_{b} is each independently the same as R₅ in the above formula (7), and is, for example, at least one selected from the group consisting of a hydrogen atom and a monovalent hydrocarbon group having 1 to 10 carbon atoms.

Examples of Y having a structure represented by formula (8) include a structure selected from the group consisting of the following general formula (VI):

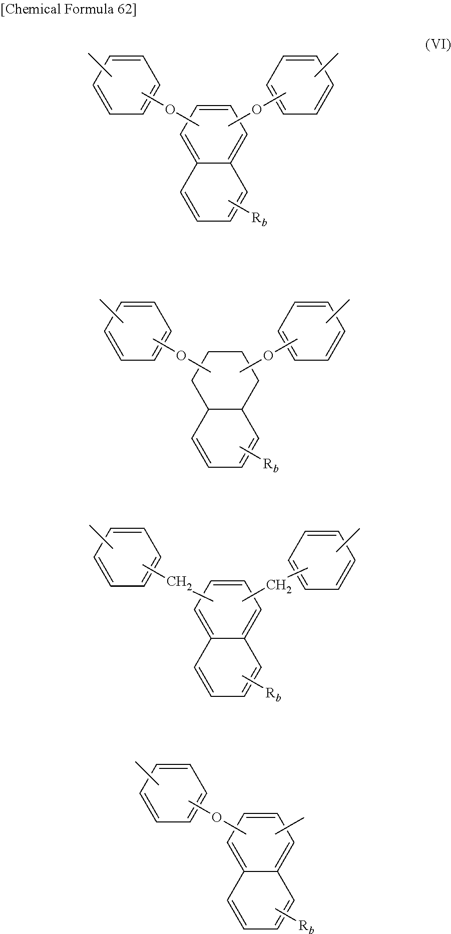

wherein R_{b} is each independently the same as R₆ in the above formula (8), and is, for example, at least one selected from the group consisting of a hydrogen atom and a monovalent hydrocarbon group having 1 to 10 carbon atoms.

In the formula (3), Y having a structure represented by the formulas (7) and (8) preferably has a structure represented by at least one selected from the group consisting of the following general formula (VII) in other words, the following general formulas (15) to (19):

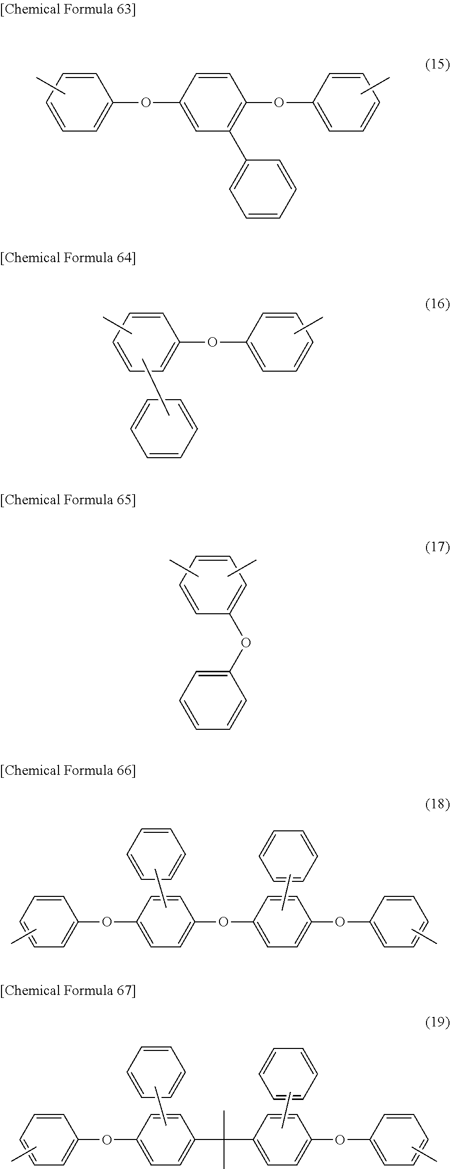

from the viewpoint of the solubility and mechanical properties.

In the formula (3), Y having a structure represented by the formulas (7) and (8) is particularly preferably a structure selected from the group consisting of the following general formula (VIII):

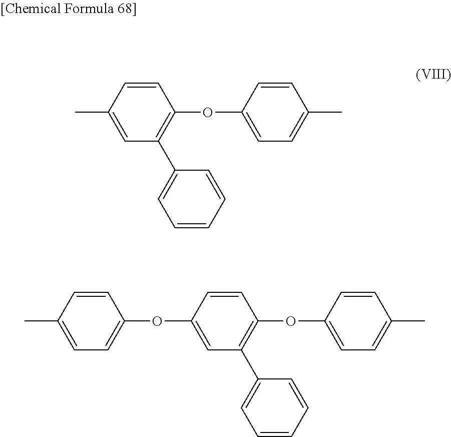

from the viewpoint of the chemical resistance and heat resistance.

The structure of Y may be one or a combination of two or more of the above (IV) to (VIII), and further may be combined with a group selected from the group consisting of the following (IX) and (X):

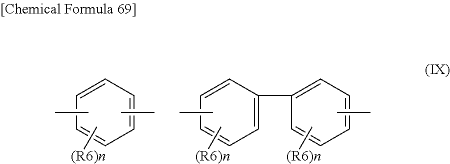

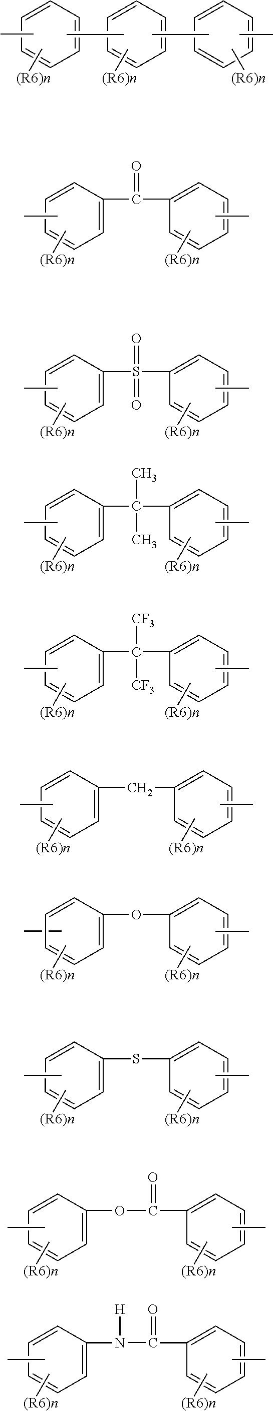

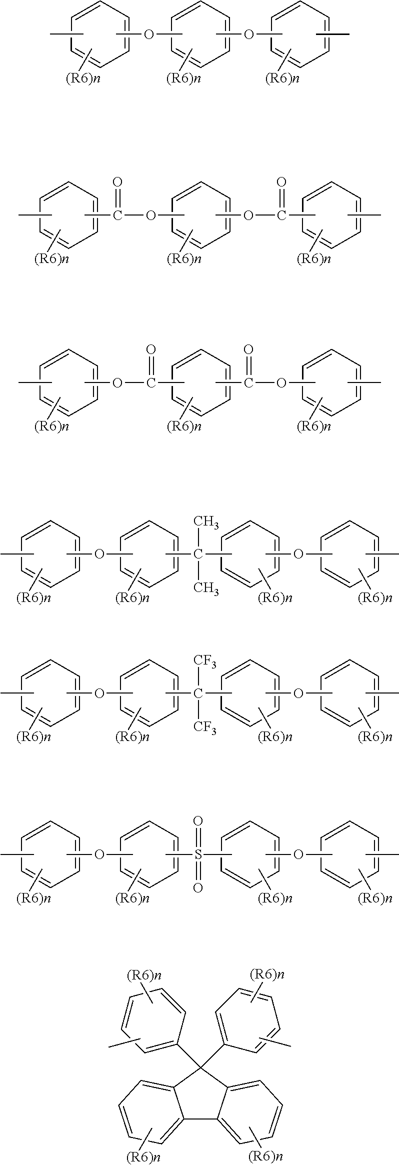

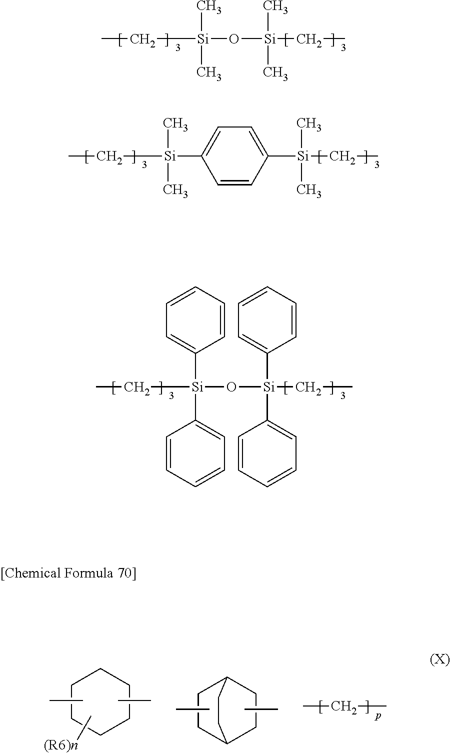

wherein R₆ is independently at least one selected from the group consisting of a hydrogen atom and a monovalent hydrocarbon group having 1 to 10 carbon atoms, n is each independently an integer selected from 0 to 4, and p is an integer selected from 1 to 20.

Y in formula (3) may have a structure represented by at least one selected from the group consisting of the following general formulas (26) to (28):

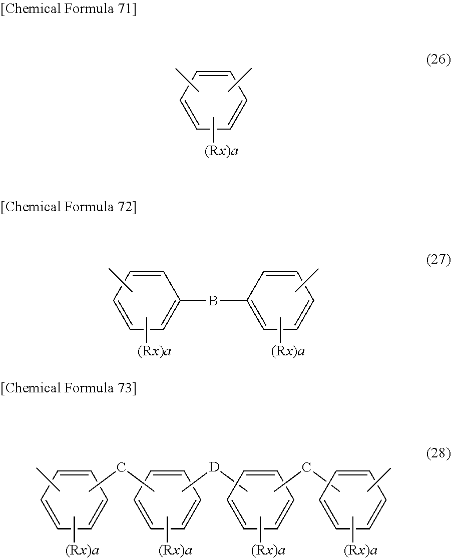

wherein R_{X} is each independently a monovalent organic group having 1 to 10 carbon atoms (in which those having an aromatic ring are excluded), a is each independently an integer of 0 to 4, B is a single bond, a methylene group, an oxygen atom or a sulfur atom, C is each independently an oxygen atom or a sulfur atom, and D is at least one selected from the group consisting of the following formula:

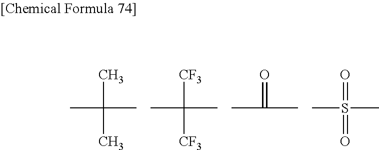

The proportion of the structures represented by the above formulas (7) to (8) in Y, particularly the proportion of the structures represented by the above formulas (V) to (VI), may be appropriately considered from the viewpoint of suitably obtaining the effects due to formulas (7) to (8).

Of Y, a diamine having no photopolymerizable group is preferable from the viewpoint of the copper adhesion. It is believed that, regarding a polymer having a plurality of photopolymerizable groups in the side chains, the movement of an imide structure in the polymer is restricted by the polymerization of the side chain upon exposure to light, thus making it difficult for the imide structure in the polymer to approach copper surface, leading to deterioration of the adhesion.

### Physical Properties of Polyimide (A)

The molecular weight distribution (Mw/Mn) of the polyimide (A) is preferably 1.0 or more and 1.8 or less. From the viewpoint of production efficiency of the molecular weight distribution, the lower limit is more preferably 1.15 or more, and still more preferably 1.25 or more. From the viewpoint of the resolution, the upper limit is more preferably 1.80 or less, and still more preferably 1.7 or less.

The weight-average molecular weight (Mw) of the polyimide (A) is not particularly limited as long as it is dissolved in the solvent (B). From the viewpoint of the mechanical properties of a cured film obtained from the photosensitive resin composition of the present disclosure, the lower limit thereof is preferably 5,000 or more, more preferably 8,000 or more, and still more preferably 10,000 or more. The upper limit thereof is more preferably 40,000 or less, still more preferably 30,000 or less, and yet more preferably 25,000 or less, from the viewpoints of the solubility in the solvent (B) and in-plane uniformity (flatness) during coating.

The polyimide (A) may have a polymerizable functional group at the end of the main chain for the purpose of improving the mechanical properties, chemical resistance and resolution. However, from the viewpoint of the copper adhesion, it is preferable that the polyimide (A) does not have a photopolymerizable group in the side chain. In a polymer having a photopolymerizable group in the side chain, the movement of the imide structure in the polymer is likely to be restricted by the polymerization of the side chain upon exposure to light, and therefore the imide structure in the polymer is difficult to approach the copper surface. For this reason, it is believed that the adhesion tends to deteriorate.

<Method for producing Polyimide>

The method for producing a polyimide (A) includes a step of heating a polyamic acid, which is obtained by reacting a tetracarboxylic dianhydride with a diamine, to undergo dehydration ring-closure, thus obtaining a polyimide, and a desired functional group may be introduced to the end of the polymer as necessary.

The temperature at which the polyamic acid is heated to undergo dehydration ring-closure is not particularly limited, but since the ring-closing reaction tends not to be completed at low temperature, the lower limit thereof is preferably 150° C. or higher, and more preferably 160° C. or higher. Meanwhile, since side reactions tend to proceed at high temperature, the upper limit thereof is preferably 200° C. or lower, and more preferably 180° C.

Examples of the tetracarboxylic dianhydride include those having the structures represented by the above formulas (4) to (6).

Specific examples thereof include tetracarboxylic acid dianhydrides corresponding to the structures represented by the above formulas (I) to (III), and examples thereof include 1,3,3a,4,5,9b-hexahydro-5-(tetrahydro-2,5-dioxo-3-furanyl)naphtho[1,2-c]furan-1,3-dione (trade name, Rikacid TDA-100: manufactured by New Japan Chemical Co., Ltd.), 3-phenyl-1,2,4,5-benzenetetracarboxylic anhydride and the like.

Examples of the diamines include those corresponding to the structures represented by the above formulas (7) and (8).

Specific examples thereof include diamines corresponding to the structures represented by the above formulas (V) to (VI), and examples thereof include 4,4′-diamino-2-phenyldiphenyl ether, 1,4-bis(4-aminophenoxy)-2-phenylbenzene, 2-phenoxybenzene-1,4-diamine, 3,3′-diphenyl-4,4′-bis(4-aminophenoxy)biphenyl, 2,2′-bis[3-phenyl-4-(4-aminophenoxy)phenyl]propane, 4,4′-diaminotriphenylamine, 4,4′-[(6-phenoxy-1,3,5-triazine-2,4-diyl)bis(oxy)]dianiline, 1,4-bis(4-aminophenoxy)naphthalene and the like.

Regarding acid anhydrides and diamines that can be used as raw materials for the polyimide, it is preferable to contain at least an acid anhydride having an HSP value of 25.5<δt<28.9 as estimated by HSPiP, and/or a diamine having an HSP value of δd>20.0 and δp<7.6 for the following reasons.

By setting the HSP value of the acid anhydride to δt>25.5, δt of the acid anhydride is different from δt of the solvent used in the test that has excellent chemical resistance (in one embodiment, DMSO, whose δt is 24.9), thus making it possible to obtain a polyimide with high chemical resistance can be obtained. By making the HSP value of the acid anhydride δt<28.9, δt of the acid anhydride becomes close to that of a highly versatile solvent (in one embodiment, GBL, DMSO, NMP, etc., where δt of GBL is 24.6, δt of DMSO is 24.9, and δt of NMP is 21.8), thus making it possible to obtain a polyimide with excellent solvent solubility.

By making the HSP value of the diamine δd>20.0, the diamine has a high dispersing power, so that aggregation due to stacking of imide groups in the polyimide is suppressed. This allows the solvent to easily penetrate into the inside of the polymer, thus obtaining a polyimide with excellent solvent solubility. Furthermore, by making the HSP value of the diamine δp<7.6, aggregation caused by the mutual attraction between polymers due to dipoles can be suppressed, which makes it easier for the solvent to penetrate into the inside of the polymer, thus obtaining a polyimide with more excellent solvent solubility.

The HSP values of exemplary acid anhydrides and diamines, which are used as raw materials for polyimide, estimated by HSPiP are as follows. The HSP value of the solvent used in the production of a polyimide, as estimated by HSPiP, is as follows.

TABLE 1

| Acid anhydride | δd | δp | δh | δt |
|---|---|---|---|---|
| 4,4′-Oxydiphthalic dianhydride | 22.5 | 16.1 | 9.2 | 29.1 |
| 4,4′-(4,4′- | 22.4 | 10.6 | 5.8 | 25.4 |
| Isopropylidenediphenoxy)diphthalic | | | | |
| anhydride | | | | |
| Pyromellitic anhydride | 19.1 | 6.0 | 6.6 | 21.1 |
| Norbornane-2-spiro-α-cyclopentanone-α′- | 20.5 | 16.7 | 11.6 | 28.9 |
| spiro-2″-norbornane-5,5″,6,6″- | | | | |
| tetracarboxylic dianhydride | | | | |
| Bicyclo[2.2.2.]oct-7-ene-2,3,5,6- | 19.3 | 15.5 | 6.2 | 25.5 |
| tetracarboxylic dianhydride | | | | |
| 1,3,3a,4,5,9b-Hexahydro-5-(tetrahydro-2,5- | 20.7 | 14.8 | 6.3 | 26.2 |
| dioxo-3-furanyl)naphtho[1,2-c]furan-1,3- | | | | |
| dione | | | | |
| Spiro[difuro[3,4-b:3′,4′i]xantene-11,9′- | 23.6 | 10.4 | 4.6 | 26.2 |
| fluorene]-1,3,7,9-tetraone | | | | |
| 4,4′-(9H-Fluorene-9,9-diyl)diphthalic | 23.1 | 10.6 | 4.5 | 25.8 |
| anhydride | | | | |
| 4,4′-(Hexafluoroisopropylidene)diphthalic | 19.3 | 11.8 | 5.3 | 23.2 |
| anhydride | | | | |

TABLE 2

| Diamine | δd | δp | δh | δt |
|---|---|---|---|---|
| 4,4′-Diamino-2-phenyldiphenyl ether | 20.7 | 5.5 | 9.5 | 23.4 |
| 4,4′-Dimethylbiphenyl-4,4′-diamine | 20 | 5.1 | 9.9 | 22.9 |
| 4,4′-(Bipheny1-2,5-diyldioxy)dianiline | 21.2 | 5.2 | 8.2 | 23.3 |
| 2-Phenoxybenzene-1,4-diamine | 20.5 | 6.6 | 12.0 | 24.6 |
| 3,3′-Diphenyl-4,4′-bis(4-aminophenoxy) | 21.8 | 2.9 | 5.5 | 22.7 |
| biphenyl | | | | |
| 2,2′-Bis [3-phenyl-4-(4- | 21.3 | 2.3 | 4.6 | 21.9 |
| aminophenoxy)phenyl]propane | | | | |
| 4,4′-Diaminotriphenylamine | 20.9 | 4.9 | 9.9 | 23.6 |
| 1,4-Bis(4-aminophenoxy)naphthalene | 21.5 | 5.0 | 9.6 | 24.1 |
| 4,4′-Diaminodiphenyl ether | 20.8 | 7.6 | 12.2 | 25.3 |
| 2,2′-Bis(trifluoromethyl)benzidine | 17.5 | 5.1 | 8.2 | 20.0 |
| 9,9-Bis(4-aminophenyl)fluorene | 21.1 | 4.3 | 6.4 | 22.5 |

TABLE 3

| Solvent | δd | δp | δh | δt |
|---|---|---|---|---|
| NMP | 17.9 | 9.9 | 7.4 | 21.8 |
| GBL | 17.5 | 15.5 | 7.8 | 24.6 |
| DMSO | 18.4 | 14.6 | 8.1 | 24.9 |

### <Method for Producing Polyimide Having Polymerizable Functional Group at Main Chain End>

By reacting a compound having a polymerizable functional group with the main chain ends of the polyimide obtained by the above method, it is possible to obtain a polyimide which has a polymerizable functional group at the main chain end.

The terminal structure of the polyimide before the introduction of the polymerizable functional group may be a carboxyl group or acid anhydride group derived from a tetracarboxylic dianhydride, or an amino group derived from a diamine.

The compound having a polymerizable functional group at the end is preferably at least one compound selected from the group consisting of isocyanate-based compounds, chloride-based compounds and alcohol-based compounds.

Specific examples of the compound having a polymerizable functional group at the end include isocyanate-based compounds such as 2-methacryloyloxyethyl isocyanate, 2-acryloyloxyethyl isocyanate, 1,1-(bisacryloyloxymethyl)ethyl isocyanate and 2-(2-methacryloyloxyethyloxy)ethyl isocyanate; chloride-based compounds such as acryloyl chloride and methacryloyl chloride; and alcohol-based compounds such as 2-hydroxyethyl methacrylate (2-hydroxyethyl methacrylate: HEMA), 2-hydroxyethyl acrylate, 4-hydroxyethyl methacrylate and 4-hydroxyethyl acrylate.

The isocyanate-based compound reacts with the amino group of the dehydrated ring-closed polyimide to form a urea bond.

The chloride-based compound reacts with the amino group of the dehydrated ring-closed polyimide to form an amide bond.

The alcohol-based compound reacts with the carboxyl group of the dehydrated ring-closed polyimide to form an ester bond.

The method for reacting the isocyanate-based compound is not particularly limited, but it is possible to react with amino groups of the dehydrated ring-closed polyimide by stirring at room temperature.

The method for reacting the chloride-based compound is not particularly limited, but it is possible to react with amino groups of the dehydrated ring-closed polyimide by ice-cooling the dehydrated ring-closed polyimide solution and adding dropwise the chloride-based compound.

The method for reacting the alcohol-based compound is not particularly limited, but the carboxyl group of the dehydrated ring-closed polyimide can be reacted with the alcohol-based compound using a condensing agent such as N,N′-dicyclohexylcarbodiimide (DCC), or an esterification catalyst such as p-toluenesulfonic acid.

In the production of the polyimide (A), a reaction solvent may be used to efficiently carry out the reaction in a homogeneous system. The reaction solvent is not particularly limited as long as it can uniformly dissolve or suspend the tetracarboxylic dianhydride, the diamine, and the compound having a polymerizable functional group at the end.

Examples thereof include γ-butyrolactone (GBL), dimethyl sulfoxide, N,N-dimethylacetoacetamide, 1,3-dimethyl-2-imidazolidinone, 3-methoxy-N,N-dimethylpropanamide, 3-butoxy-N,N-dimethylpropanamide, N,N-dimethylformamide, N-methyl-2-pyrrolidone, N-ethyl-2-pyrrolidone, N,N-dimethylacetamide and the like.

The polyimide (A) may be purified by a known method mentioned in JP 2012-194520 A. For example, there may be mentioned a method in which a solution of a polyimide (A) is added dropwise in water to cause reprecipitation and an unreacted material is removed, a method in which a condensing agent or the like insoluble in a reaction solvent is removed by filtration, a method in which a catalyst is removed by an ion exchange resin. After such purification, the polyimide (A) may be dried by a known method and isolated in a powder state.

The polyimide (A) is included in an amount of, for example, 35% by mass relative to the photosensitive resin composition of the present disclosure. The polyimide (A) is included in an amount of preferably 20 to 70% by mass, and more preferably 25 to 65% by mass relative to the photosensitive resin composition of the present disclosure.

### (B) Solvent

The solvent (B) may be any solvent capable of uniformly dissolving or suspending a polyimide (A) and a photopolymerization initiator (C). Examples of such solvent include γ-butyrolactone (GBL), dimethyl sulfoxide, tetrahydrofurfuryl alcohol, ethyl acetoacetate, N,N-dimethylacetoacetamide, $-caprolactone, 1,3-dimethyl-2-imidazolidinone, 3-methoxy-N,N-dimethylpropanamide, 3-butoxy-N,N-dimethylpropanamide, N,N-dimethylformamide, N-methyl-2-pyrrolidone, N-ethyl-2-pyrrolidone, N,N-dimethylacetamide and the like. These solvents may be used alone or in combination of two or more thereof.

The solvent (B) can be used depending on the desired coating thickness and viscosity of the photosensitive resin composition. The solvent (B) can be used in an amount within a range of, for example, 30 to 1,000 parts by mass, and preferably 140 to 1,000 parts by mass, relative to 100 parts by mass of the polyimide (A).

When the solvent (B) contains an alcohol having no olefinic based double bond, the content of the alcohol having no olefinic based double bond in the total solvent is preferably 5 to 50% by mass. The upper limit thereof is more preferably 10% by mass or more from the viewpoint of the storage stability of the photosensitive resin composition. The lower limit thereof is more preferably 30% by mass or less from the viewpoint of the solubility of the polyimide (A).

### (C) Photopolymerization Initiator

The photopolymerization initiator (C) is a compound that generates radicals with active light, thereby polymerizing a compounds having an ethylenically unsaturated group. That is, the photopolymerization initiator (C) is preferably a photoradical polymerization initiator. Examples of the initiator which generates radicals with active light include compounds having structures such as benzophenone, N-alkylaminoacetophenone, oxime ester, acridine, phosphine oxide and lophine.

Examples thereof include, but are not limited to, aromatic ketones such as benzophenone, N,N,N′,N′-tetramethyl-4,4′-diaminobenzophenone (Michler's ketone), N,N,N′,N′-tetraethyl-4,4′-diaminobenzophenone, 4-methoxy-4′-dimethylaminobenzophenone, 2-benzyl-2-dimethylamino-1-(morpholinophenyl)-butanone-1,2-methyl-1-[4-(methylthio)phenyl]-2-morpholino-propanone-1, acrylated benzophenone, and 4-benzoyl-4′-methyldiphenyl sulfide; benzoin ether compounds such as benzoin methyl ether, benzoin ethyl ether, and benzoin phenyl ether; benzoin compounds such as benzoin, methylbenzoin, and ethylbenzoin; oxime ester compounds such as 1,2-octanedione, 1-[4-(phenylthio)-2-(O-benzoyloxime)], ethanone, 1-[9-ethyl-6-(2-methylbenzoyl)-9H-carbazol-3-yl]-1-(O-acetyloxime) (Irgacure Oxe02, manufactured by BASF Japan Ltd.), 1-[4-(phenylthio)phenyl]-3-cyclopentylpropane-1,2-dione-2-(o-benzoyloxime) (PBG305, manufactured by Changzhou Tronly New Electronic Materials Co., Ltd.), 1-(6-O-methylbenzoyl-9-ethylcarbazol-3-yl)-(3-cyclopentylacetone)-1-oxime acetate (TR-PBG-304, manufactured by Changzhou Tronly New Electronic Materials Co., Ltd.), trade name: TR-PBG-3057 (manufactured by Changzhou Tronly New Electronic Materials Co., Ltd.), 1,2-propanedione, 3-cyclohexyl-1-[9-ethyl-6-(2-furanylcarbonyl)-9H-carbazol-3-yl]-, 2-(0-acetyloxime) (manufactured by Nikko Chemtech Co., Ltd., product name: TR-PBG-326), and NCI-831 (trade name, manufactured by ADEKA Corporation); benzyl derivatives such as benzyl dimethyl ketal; acridine derivatives such as 9-phenylacridine and 1,7-bis(9,9′-acridinyl)heptane; N-phenylglycine derivatives such as N-phenylglycine; coumarin compounds; oxazole compounds; phosphine oxide compounds such as 2,4,6-trimethylbenzoyl-diphenyl-phosphine oxide; and lophine compounds such as 2,2′-bis(2-chlorophenyl)-4,4′,5,5′-tetraphenyl-1,2′-biimidazole.

The photopolymerization initiator (C) described above may be used alone or in combination of two or more thereof. Of the above photopolymerization initiators, oxime ester compounds are more preferable, particularly from the viewpoint of the resolution.

The mixing amount of the photopolymerization initiator (C) is preferably 1 part by mass or more and 30 parts by mass or less relative to 100 parts by mass of the polyimide (A). The lower limit thereof is more preferably 2 parts by mass or more from the viewpoint of the photocurability. The upper limit thereof is more preferably 20 parts by mass or less from the viewpoint of the curability at the bottom of the relief pattern.

### (D) Monomer Having Polymerizable Functional Group (Radical Polymerizable Compound)

From the viewpoints of improving the resolution of the cured relief pattern and suppressing cure shrinkage during heat-curing, the photosensitive resin composition may optionally include a radically polymerizable compound. Such compound is preferably a (meth)acrylic compound which undergoes a radical polymerization reaction with the photopolymerization initiator (C). The (meth)acrylic compound includes a monofunctional monomer and a polyfunctional monomer.

Examples of the monofunctional monomer include 2-hydroxyethyl (meth)acrylate, 2-hydroxypropyl methacrylate, 2-hydroxybutyl methacrylate, 4-hydroxybutyl acrylate, 2-hydroxy-3-phenoxypropyl acrylate, 2-ethylhexyl (meth)acrylate, butoxydiethylene glycol methacrylate, isobornyl (meth)acrylate, m-phenoxybenzyl acrylate, o-phenylphenoxyethyl acrylate, 4-methacryloyloxybenzophenone, EO-modified paracumylphenol acrylate, nonylphenoxyethyl acrylate, 6-acrylamidohexanoic acid, dicyclopentanyl acrylate, dicyclopentanyl methacrylate and the like.

Examples of the polyfunctional monomer include di(meth)acrylates of ethylene glycol or polyethylene glycol, including diethylene glycol dimethacrylate and tetraethylene glycol dimethacrylate, di(meth)acrylates of propylene glycol or polypropylene glycol, di(meth)acrylate or tri(meth)acrylate of glycerol, cyclohexane di(meth)acrylate, di(meth)acrylate of 1,4-butanediol, di(meth)acrylate of 1,6-hexanediol, di(meth)acrylate of neopentyl glycol, di(meth)acrylate of bisphenol A, (meth)acrylamide, and derivatives thereof, trimethylolpropane tri(meth)acrylate, di(meth)acrylate or tri(meth)acrylate of glycerol, di(meth)acrylate, tri(meth)acrylate or tetra(meth)acrylate of pentaerythritol, ethylene oxide (e.g., 4-hydroxybutyl acrylate glycidyl ether) or propylene oxide adducts of these compounds; urethane acrylates such as product name: KRM7735 (manufactured by Daicel-Allnex Ltd.), product name: EBECRYL230 (manufactured by Daicel-Allnex Ltd.), product name: EBECRYL4491 (manufactured by Daicel-Allnex Ltd.), product name: EBECRYL8413 (manufactured by Daicel-Allnex Ltd.), product name: EBECRYL8411 (manufactured by Daicel-Allnex Ltd.), product name: EBECRYL8402 (manufactured by Daicel-Allnex Ltd.), product name: EBECRYL8465 (manufactured by Daicel-Allnex Ltd.), product name: EBECRYL8667 (manufactured by Daicel-Allnex Ltd.), product name: EBECRYL4740 (manufactured by Daicel-Allnex Ltd.), and product name: KRM9276 (manufactured by Daicel-Allnex Ltd.), and polyfunctional monomers such as tris-(2-hydroxyethyl)isocyanurate acrylate.

Of these radically polymerizable compounds, it is preferable to use a compound having three or more radically polymerizable functional groups from the viewpoints of suppressing cure shrinkage, and the chemical resistance.

The radically polymerizable compound may be used alone or in combination of plural.

(D1) a monofunctional monomer and (D2) a polyfunctional monomer are contained as the radical polymerizable compound (D), and the mass ratio (D1/D2) of the monofunctional monomer (D1) with respect to the polyfunctional monomer (D2) is preferably more than 0.001 and more preferably more than 0.01 from the viewpoint of the copper adhesion, and is preferably less than 10, more preferably less than 7, and still more preferably less than 5 from the viewpoint of the chemical resistance.

The content of the radical polymerizable compound in the photosensitive resin composition is preferably 0.5 part by mass to 100 parts by mass relative to 100 parts by mass of the polyimide (A). The lower limit thereof is more preferably 5 parts by mass or more, still more preferably 10 parts by mass or more, and particularly preferably 20 parts by mass, from the viewpoint of the photocurability. The upper limit thereof is more preferably 70 parts by mass or less, and still more preferably 50 parts by mass or less, from the viewpoints of copper adhesion and curability at the bottom of the pattern.

### (E) Silane Coupling Agent

In order to improve the adhesion of the cured relief pattern, the photosensitive resin composition may optionally include a silane coupling agent. Examples of the silane coupling agent include 3-mercaptopropyltrimethoxysilane (manufactured by Shin-Etsu Chemical Co., Ltd.: trade name KBM803, manufactured by CHISSO CORPORATION: trade name Sila-Ace S810), 3-mercaptopropyltriethoxysilane (manufactured by Azmax Corporation: trade name SIM6475.0), 3-mercaptopropylmethyldimethoxysilane (manufactured by Shin-Etsu Chemical Co., Ltd.: trade name LS1375, manufactured by Azmax Corporation: trade name SIM6474.0), mercaptomethyltrimethoxysilane (manufactured by Azmax Corporation: trade name SIM6473.5C), mercaptomethylmethyldimethoxysilane (manufactured by Azmax Corporation: trade name SIM6473.0), 3-mercaptopropyldiethoxymethoxysilane, 3-mercaptopropylethoxydimethoxysilane, 3-mercaptopropyltripropoxysilane, 3-mercaptopropyldiethoxypropoxysilane, 3-mercaptopropylethoxydipropoxysilane, 3-mercaptopropyldimethoxypropoxysilane, 3-mercaptopropylmethoxydipropoxysilane, 2-mercaptoethyltrimethoxysilane, 2-mercaptoethyldiethoxymethoxysilane, 2-mercaptoethylethoxydimethoxysilane, 2-mercaptoethyltripropoxysilane, 2-mercaptoethyltripropoxysilane, 2-mercaptoethylethoxydipropoxysilane, 2-mercaptoethyldimethoxypropoxysilane, 2-mercaptoethylmethoxydipropoxysilane, 4-mercaptobutyltrimethoxysilane, 4-mercaptobutyltriethoxysilane, 4-mercaptobutyltripropoxysilane and the like.

Examples of the silane coupling agent include N-(3-triethoxysilylpropyl)urea (manufactured by Shin-Etsu Chemical Co., Ltd.: trade name LS3610, manufactured by Azmax Corporation: trade name SIU9055.0), N-(3-trimethoxysilylpropyl)urea (manufactured by Azmax Corporation: trade name SIU9058.0), N-(3-diethoxymethoxysilylpropyl)urea, N-(3-ethoxydimethoxysilylpropyl)urea, N-(3-tripropoxysilylpropyl)urea, N-(3-diethoxypropoxysilylpropyl)urea, N-(3-ethoxydipropoxysilylpropyl)urea, N-(3-dimethoxypropoxysilylpropyl)urea, N-(3-methoxydipropoxysilylpropyl)urea, N-(3-trimethoxysilylethyl)urea, N-(3-ethoxydimethoxysilylethyl)urea, N-(3-tripropoxysilylethyl)urea, N-(3-tripropoxysilylethyl)urea, N-(3-ethoxydipropoxysilylethyl)urea, N-(3-dimethoxypropoxysilylethyl)urea, N-(3-methoxydipropoxysilylethyl)urea, N-(3-trimethoxysilylbutyl)urea, N-(3-triethoxysilylbutyl)urea, N-(3-tripropoxysilylbutyl)urea, 3-(m-aminophenoxy) propyltrimethoxysilane (manufactured by Azmax Corporation: trade name SLA0598.0), m-aminophenyltrimethoxysilane (manufactured by Azmax Corporation: trade name SLA0599.0), p-aminophenyltrimethoxysilane (manufactured by Azmax Corporation: trade name SLA0599.1) aminophenyltrimethoxysilane (manufactured by Azmax Corporation: trade name SLA0599.2) and the like.

Examples of the silane coupling agent include 2-(trimethoxysilylethyl)pyridine (manufactured by Azmax Corporation: trade name SIT8396.0), 2-(triethoxysilylethyl)pyridine, 2-(dimethoxysilylmethylethyl)pyridine, 2-(diethoxysilylmethylethyl)pyridine, (3-triethoxysilylpropyl)-t-butyl carbamate, (3-glycidoxypropyl)triethoxysilane, tetramethoxysilane, tetraethoxysilane, tetra-n-propoxysilane, tetra-i-propoxysilane, tetra-n-butoxysilane, tetra-i-butoxysilane, tetra-t-butoxysilane, tetrakis(methoxyethoxysilane), tetrakis(methoxy-n-propoxysilane), tetrakis(ethoxyethoxysilane), tetrakis(methoxyethoxyethoxysilane), bis(trimethoxysilyl)ethane, bis(trimethoxysilyl)hexane, bis(triethoxysilyl)methane, bis(triethoxysilyl)ethane, bis(triethoxysilyl)ethylene, bis(triethoxysilyl)octane, bis(triethoxysilyl)octadiene, bis[3-(triethoxysilyl) propyl]disulfide, bis[3-(triethoxysilyl)propyl]tetrasulfide, di-t-butoxydiacetoxysilane, di-i-butoxyaluminoxytriethoxysilane, phenylsilanetriol, methylphenylsilanediol, ethylphenylsilanediol, n-propylphenylsilanediol, isopropylphenylsilanediol, n-butylphenylsilanediol, isobutylphenylsilanediol, tert-butylphenylsilanediol, diphenylsilanediol, dimethoxydiphenylsilane, diethoxydiphenylsilane, dimethoxydi-p-tolylsilane, ethylmethylphenylsilanol, n-propylmethylphenylsilanol, isopropylmethylphenylsilanol, n-butylmethylphenylsilanol, isobutylmethylphenylsilanol, tert-butylmethylphenylsilanol, ethyl n-propylphenylsilanol, ethylisopropylphenylsilanol, n-butylethylphenylsilanol, isobutylethylphenylsilanol, tert-butylethylphenylsilanol, methyldiphenylsilanol, ethyldiphenylsilanol, n-propyldiphenylsilanol, isopropyldiphenylsilanol, n-butyldiphenylsilanol, isobutyldiphenylsilanol, tert-butyldiphenylsilanol, triphenylsilanol and the like.

The silane coupling agents listed above may be used alone or in combination of plural. Of the silane coupling agents listed above, from the viewpoints of the adhesion to a substrate and storage stability, it is preferable that the silane coupling agent has a structure represented by the following general formula (29):

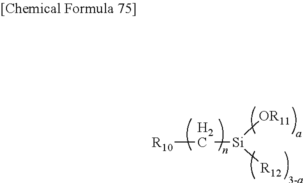

wherein R₁₀ is at least one selected from the group consisting of substituents including an epoxy group, a phenylamino group, a ureido group, an isocyanate group and an isocyanuric group, and the following general formulas (30) to (32):

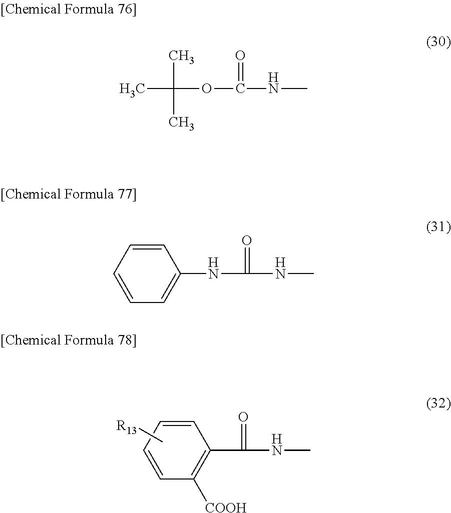

wherein R₁₃ is a monovalent organic group, R₁₁ is each independently an alkyl group having 1 to 4 carbon atoms, R₁₂ is each independently a hydroxyl group or an alkyl group having 1 to 4 carbon atoms, a is an integer of 1 to 3, and i is an integer of 1 to 6.

In formula (29), a is an integer of 1 to 3, and is preferably 2 or 3, and more preferably 3, from the viewpoint of the adhesion to metal wiring (e.g., copper wiring) in a rewiring layer. i is an integer of 1 to 6, and is preferably 1 or more and 4 or less from the viewpoint of the adhesion to metal wiring (e.g., copper wiring) in a rewiring layer, and is preferably 2 or more and 5 or less from the viewpoint of the resolution.

From the viewpoints of the resolution and adhesion to metal wiring in a rewiring layer, R₁₀ is preferably at least one selected from the group consisting of a phenylamino group-containing substituent, a ureido group-containing substituent and a phenylamino group-containing substituent, and more preferably a phenylamino group-containing substituent. R₁₁ may be an alkyl group having 1 to 4 carbon atoms, and examples thereof include a methyl group, an ethyl group, a propyl group, an isopropyl group, a butyl group, an isobutyl group, a t-butyl group and the like. R₁₂ may be a hydroxyl group or an alkyl group having 1 to 4 carbon atoms. Examples of the alkyl group having 1 to 4 carbon atoms include the same alkyl groups as for R₁₁.

Examples of the epoxy group-containing silane coupling agent include 2-(3,4-epoxycyclohexyl)ethyltrimethoxysilane, 3-glycidoxypropylmethyldimethoxysilane, 3-glycidoxypropyltrimethoxysilane, 3-glycidoxypropyltrimethoxysilane, 3-glycidoxypropylmethyldiethoxysilane, 3-glycidoxypropyltriethoxysilane and the like.

Examples of the phenylamino group-containing silane coupling agent include N-phenyl-3-aminopropyltrimethoxysilane.

Examples of the ureido group-containing silane coupling agent include 3-ureidopropyltrialkoxysilane.

Examples of the isocyanate group-containing silane coupling agent include 3-isocyanatopropyltriethoxysilane.

The silane coupling agents may be used alone or in combination of plural.

The content of the silane coupling agent in the photosensitive resin composition of the present disclosure is 0.2 part by mass to 10 parts by mass relative to 100 parts by mass of the polyimide (A). From the viewpoint of the copper adhesion, the lower limit thereof is more preferably 0.5 part by mass or more, and still more preferably 1 part by mass or more. From the viewpoint of suppressing the precipitation of the silane coupling agent, and thus suppressing the generation of foreign substances due to such precipitation, the upper limit thereof is more preferably 8 parts by mass or less, and still more preferably 6 parts by mass or less.

### (F) Rust Inhibitor

When the photosensitive resin composition of the present disclosure is used to form a cured film on a substrate made of copper or a copper alloy, the photosensitive resin composition may optionally include a rust inhibitor to suppress discoloration on copper. Examples of the rust inhibitor include an azole compound, a purine compound and the like.

Examples of the azole compound include 1H-triazole, 5-methyl-1H-triazole, 5-ethyl-TH-triazole, 4,5-dimethyl-1H-triazole, 5-phenyl-1H-triazole, 4-t-butyl-5-phenyl-1H-triazole, 5-hydroxyphenyl-1H-triazole, phenyltriazole, p-ethoxyphenyltriazole, 5-phenyl-1-(2-dimethylaminoethyl) triazole, 5-benzyl-1H-triazole, hydroxyphenyltriazole, 1,5-dimethyltriazole, 4,5-diethyl-1H-triazole, 1H-benzotriazole, 2-(5-methyl-2-hydroxyphenyl) benzotriazole, 2-[2-hydroxy-3,5-bis(α,α-dimethylbenzyl) phenyl]-benzotriazole, 2-(3,5-di-t-butyl-2-hydroxyphenyl)benzotriazole, 2-(3-t-butyl-5-methyl-2-hydroxyphenyl)-benzotriazole, 2-(3,5-di-t-amyl-2-hydroxyphenyl)benzotriazole, 2-(2′-hydroxy-5′-t-octylphenyl)benzotriazole, hydroxyphenylbenzotriazole, tolyltriazole, 5-methyl-1H-benzotriazole, 4-methyl-1H-benzotriazole, 4-carboxy-1H-benzotriazole, 5-carboxy-1H-benzotriazole, 3-mercapto-1,2,4-triazole, 1H-tetrazole, 5-methyl-TH-tetrazole, 5-phenyl-1H-tetrazole, 5-amino-1H-tetrazole, 1-methyl-1H-tetrazole and the like.

Particularly preferably, 5-amino-1H-tetrazole, tolyltriazole, 5-methyl-1H-benzotriazole and 4-methyl-1H-benzotriazole are exemplified.

Specific examples of the purine compound include purine, adenine, guanine, hypoxanthine, xanthine, theobromine, caffeine, uric acid, isoguanine, 2,6-diaminopurine, 9-methyladenine, 2-hydroxyadenine, 2-methyladenine, 1-methyladenine, N-methyladenine, N,N-dimethyladenine, 2-fluoroadenine, 9-(2-hydroxyethyl)adenine, guanineoxime, N-(2-hydroxyethyl)adenine, 8-aminoadenine, 6-amino-8-phenyl-9H-purine, 1-ethyladenine, 6-ethylaminopurine, 1-benzyladenine, N-methylguanine, 7-(2-hydroxyethyl)guanine, N-(3-chlorophenyl)guanine, N-(3-ethylphenyl)guanine, 2-azaadenin, 5-azaadenin, 8-azaadenin, 8-azaguanine, 8-azapurine, 8-azaxanthine, 8-azahypoxanthine and the like, and derivatives thereof.

The rust inhibitor may be used alone or in combination of plural.

When the photosensitive resin composition of the present disclosure includes a rust inhibitor, the mixing amount of the rust inhibitor is preferably 0.01 part by mass or more and 20 parts by mass or less relative to 100 parts by mass of the polyimide (A). The lower limit thereof is more preferably 0.03 part by mass or more, and still more preferably 0.05 part by mass or more, since discoloration of the copper or copper alloy surface is easily suppressed when the photosensitive resin composition is formed on copper or a copper alloy. The lower limit thereof is more preferably 10 parts by mass or less, and still more preferably 5 parts by mass or less, from the viewpoint of the photosensitivity.

### (G) Organic Titanium Compound

To improve the chemical resistance of the cured film, the photosensitive resin composition of the present disclosure may optionally contain an organic titanium compound.

Examples of usable organic titanium compound include those in which an organic group is bonded to a titanium atom via a covalent bond or an ionic bond. Specific examples of the organic titanium compound are shown in I) to VII) below:
I) Titanium chelate compounds: Specific examples thereof include titanium(IV) oxide acetylacetonate, titanium bis(triethanolamine) diisopropoxide, titanium di(n-butoxide) bis(2,4-pentanedionate), titanium diisopropoxide bis(2,4-pentanedionate), titanium diisopropoxide bis(tetramethylheptanedionate), titanium diisopropoxide bis(ethylacetoacetate) and the like.
II) Tetraalkoxytitanium compounds: for example, titanium tetra(n-butoxide), titanium tetraethoxide, titanium tetra(2-ethylhexoxide), titanium tetraisobutoxide, titanium tetraisopropoxide, titanium tetramethoxide, titanium tetramethoxypropoxide, titanium tetramethylphenoxide, titanium tetra(n-nonyloxide), titanium tetra(n-propoxide), titanium tetrastearyloxide, titanium tetrakis[bis{2,2-(allyloxymethyl)butoxide}] and the like.
III) Titanocene compounds: for example, pentamethylcyclopentadienyltitanium trimethoxide, bis(η⁵-2,4-cyclopentadien-1-yl)bis(2,6-difluorophenyl)titanium, bis(η⁵-2,4-cyclopentadien-1-yl)bis(2,6-difluoro-3-(1H-pyrrol-1-yl)phenyl)titanium and the like.
IV) Monoalkoxytitanium compounds: for example, titanium tris(dioctylphosphate)isopropoxide, titanium tris(dodecylbenzenesulfonate)isopropoxide and the like.
V) Titanium oxide compounds: for example, titanium oxide bis(pentanedionate), titanium oxide bis(tetramethylheptanedionate), phthalocyanine titanium oxide and the like.
VI) Titanium tetraacetylacetonate compounds: for example, titanium tetraacetylacetonate and the like.
VII) Titanate coupling agents: for example, isopropyl tridodecylbenzenesulfonyl titanate and the like.

Of these, the organic titanium compound is preferably at least one compound selected from the group consisting of I) titanium chelate compounds, II) tetraalkoxytitanium compounds and III) titanocene compounds, from the viewpoint of exhibiting better chemical resistance.

In particular, diisopropoxytitanium bis(ethyl acetate), titanium tetra(n-butoxide) and bis(η⁵-2,4-cyclopentadien-1-yl) bis(2,6-difluoro-3-(1H-pyrrol-1-yl) phenyl) titanium, titanium(IV) oxide acetylacetonate are preferable.

The organic titanium compound may be used alone or in combination of plural.

When the photosensitive resin composition of the present disclosure includes the organic titanium compound, the mixing amount is preferably 0.05 part by mass or more and 10 parts by mass or less relative to 100 parts by mass of the polyimide (A). The lower limit thereof is more preferably 0.5 part by mass or more from the viewpoint of the heat resistance and chemical resistance of the resulting cured film. The upper limit thereof is more preferably 2 parts by mass or less from the viewpoint of the storage stability of the photosensitive resin composition.

### (H) Plasticizer

The photosensitive resin composition of the present disclosure may include a plasticizer.

The plasticizer is a compound that improves the fluidity of the resin composition, which may contain a polyimide, when a coating film formed using the photosensitive resin composition of the present embodiments is dried, and when a relief pattern is heat-cured. Inclusion of the plasticizer makes it easy to improve the in-plane uniformity of a film coated with the photosensitive resin composition, to suppress precipitation during frozen storage, and to suppress deterioration of mechanical properties after reliability test.

Examples of the plasticizer include polyvalent polycarboxylate ester-based plasticizers, sulfonamide-based plasticizers, phosphate ester-based plasticizers, polyester-based plasticizers and polyalkylene glycol-based plasticizers.

Specific examples of the polyvalent carboxylate ester-based plasticizer include benzoate esters such as methyl benzoate, ethyl benzoate, propyl benzoate, butyl benzoate, pentyl benzoate, heptyl benzoate, normal octyl benzoate, nonyl benzoate, isononyl benzoate, isodecyl benzoate, 2-ethylhexyl benzoate, isodecyl benzoate, butyl benzyl benzoate, cyclopropyl benzoate, cyclobutyl benzoate, cyclopentyl benzoate, cyclohexyl benzoate, cycloheptyl benzoate, allyl benzoate, butyl benzyl benzoate, and phenyl benzoate; phthalate esters such as dimethyl phthalate, diethyl phthalate, dipropyl phthalate, dibutyl phthalate, dipentyl phthalate, diheptyl phthalate, di-n-octyl phthalate, dinonyl phthalate, diisononyl phthalate, diisodecyl phthalate, bis(2-ethylhexyl) phthalate, diisodecyl phthalate, butyl benzyl phthalate, dicyclopropyl phthalate, dicyclobutyl phthalate, dicyclopentyl phthalate, dicyclohexyl phthalate, dicycloheptyl phthalate, diallyl phthalate, bisbutyl benzyl phthalate, and diphenyl phthalate; trimellitate esters such as trimethyl trimellitate, triethyl trimellitate, tripropyl trimellitate, tributyl trimellitate, tripentyl trimellitate, triheptyl trimellitate, tri-n-octyl trimellitate, trinonyl trimellitate, triisononyl trimellitate, triisodecyl trimellitate, tris(2-ethylhexyl) trimellitate, triisodecyl trimellitate, trisbutylbenzyl trimellitate, tricyclopropyl trimellitate, tricyclobutyl trimellitate, tricyclopentyl tomate, tricyclohexyl trimellitate, tricycloheptyl trimellitate, triallyl trimellitate, trisbutylbenzyl trimellitate, and triphenyl trimellitate; adipate esters such as dimethyl adipate, diethyl adipate, dipropyl adipate, dibutyl adipate, dipentyl adipate, diheptyl adipate, di-n-octyl adipate, dinonyl adipate, diisononyl adipate, diisodecyl adipate, bis(2-ethylhexyl) adipate, diisodecyl adipate, butyl benzyl adipate, dicyclopropyl adipate, dicyclobutyl adipate, dicyclopentyl adipate, dicyclohexyl adipate, dicycloheptyl adipate, diallyl adipate, bisbutyl benzyl adipate, and diphenyl adipate; trimellitate esters such as trimethyl trimellitate, triethyl trimellitate, tripropyl trimellitate, tributyl trimellitate, tripentyl trimellitate, triheptyl trimellitate, tri-n-octyl trimellitate, trinonyl trimellitate, triisononyl trimethacrylate, triisodecyl trimellitate, tris(2-ethylhexyl) trimellitate, triisodecyl trimellitate, trisbutylbenzyl trimellitate, tricyclopropyl trimellitate, tricyclobutyl trimellitate, tricyclopentyl trimellitate, tricyclohexyl trimellitate, tricycloheptyl trimellitate, triallyl trimellitate, trisbutylbenzyl trimellitate, and triphenyl trimellitate; sebacate esters such as dimethyl sebacate, diethyl sebacate, and dipropyl, dibutyl sebacate, dipentyl sebacate, diheptyl sebacate, di-n-octyl sebacate, dinonyl sebacate, diisononyl sebacate, diisodecyl sebacate, bis(2-ethylhexyl) sebacate, diisodecyl sebacate, butyl benzyl sebacate, dicyclopropyl sebacate, dicyclobutyl sebacate, dicyclopentyl sebacate, dicyclohexyl sebacate, dicycloheptyl sebacate, diallyl sebacate, bisbutyl benzyl sebacate, and diphenyl sebacate; dimethyl succinate, diethyl succinate, dipropyl succinate, dibutyl succinate, dipentyl succinate, diheptyl succinate, di-n-octyl succinate, dinonyl succinate, diisononyl succinate, diisodecyl succinate, bis(2-ethylhexyl) succinate, diisodecyl succinate, butylbenzyl succinate, dicyclopropyl succinate, dicyclobutyl succinate, dicyclopentyl succinate, dicyclohexyl succinate, dicycloheptyl succinate, diallyl succinate, bisbutylbenzyl succinate, and diphenyl succinate.

Specific examples of the sulfonamide-based plasticizer include aromatic sulfonamide plasticizers, and specific examples thereof include N-butylbenzenesulfonamide, p-toluenesulfonamide, o-toluenesulfonamide, p-toluenesulfonamide, N-ethyl-p-toluenesulfonamide, N-ethyl-o-toluenesulfonamide, N-n-butylbenzenesulfonamide, and N-cyclohexyl-p-toluenesulfonamide. Preferred is N-butylbenzenesulfonamide.

Specific examples of the phosphate ester-based plasticizer include trimethyl phosphate, triethyl phosphate, tributyl phosphate, tris(2-ethylhexyl) phosphate, triphenyl phosphate, tricresyl phosphate, trixylenyl phosphate, cresyl diphenyl phosphate, and 2-ethylhexyl diphenyl phosphate.

Specific examples of the polyester-based plasticizer include polyesters composed of an acid component such as adipic acid, terephthalic acid, isophthalic acid or diphenyldicarboxylic acid, and a diol component such as propylene glycol, 1,3-butanediol, 1,4-butanediol, ethylene glycol or diethylene glycol; and polyesters composed of hydroxycarboxylic acids such as polycaprolactone. These polyesters may be end-capped with a monofunctional carboxylic acid or a monofunctional alcohol, or may be end-capped with an epoxy compound or the like.

Specific examples of the polyalkylene glycol-based plasticizer include polyalkylene glycols such as polyethylene glycol, polypropylene glycol, polytetramethylene ether glycol, ethylene oxide addition polymers of bisphenols, and propylene oxide addition polymers of bisphenols; and end-capped compounds such as the above-mentioned terminal epoxy-modified compounds, terminal ester-modified compounds, and terminal ether-modified compounds.

Specific examples of other plasticizers include glycerin fatty acid esters such as glycerin monoacetomonolaurate, glycerin diacetomonolaurate, and glycerin monoacetomonostearate; fatty acid amides such as stearic acid amide; aliphatic carboxylate esters such as butyl oleate; oxyacid esters such as methyl acetylricinoleate and butyl acetylricinoleate; pentaerythritol; and various sorbitols.

The plasticizers may be used alone or in combination of plural.

When the photosensitive resin composition of the present disclosure includes a plasticizer, the mixing amount is preferably 0.5 part by mass or more and 40 parts by mass or less relative to 100 parts by mass of the polyimide (A). The lower limit thereof is more preferably 1 part by mass or more from the viewpoint of the flatness of the coating film. The upper limit thereof is more preferably 30 parts by mass or less from the viewpoint of the heat resistance.

### (I) Thermal Crosslinking Agent

For the purposes of suppressing cure shrinkage, improving mechanical properties, and improving chemical resistance, the photosensitive resin composition of the present disclosure may optionally include a thermal crosslinking agent.

The thermal crosslinking agent means a compound which causes an addition reaction or a condensation polymerization reaction by heat. These reactions occur by combinations of the polyimide resin (A) and the thermal crosslinking agent, the thermal crosslinking agents, and the thermal crosslinking agent and other components mentioned later, and the reaction temperature is preferably 150° C. or higher.

Examples of the thermal crosslinking agent include alkoxymethyl compounds, epoxy compounds, oxetane compounds, bismaleimide compounds, allyl compounds and blocked isocyanate compounds.

Examples of the alkoxymethyl compound include, but are not limited to, the following compounds.

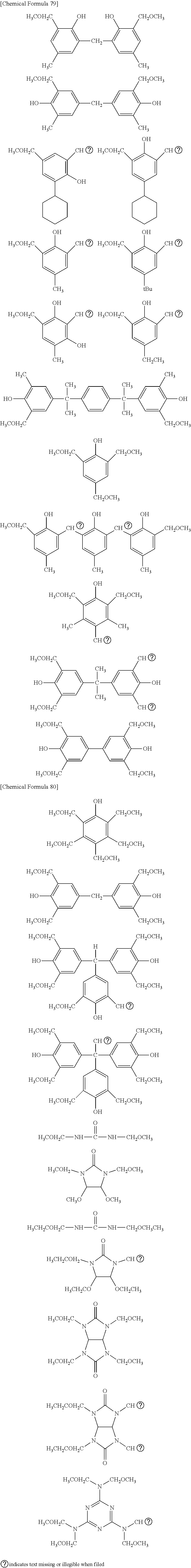

Examples of epoxy compounds include phenol novolac type epoxy resins, cresol novolac type epoxy resins, bisphenol type epoxy resins, trisphenol type epoxy resins, tetraphenol type epoxy resins, phenol-xylylene type epoxy resins, naphthol-xylylene type epoxy resins, phenol-naphthol type epoxy resins, phenol-dicyclopentadiene type epoxy resins, alicyclic epoxy resins, aliphatic epoxy resins, diethylene glycol diglycidyl ether, sorbitol polyglycidyl ether, propylene glycol diglycidyl ether, trimethylolpropane polyglycidyl ether, 1,1,2,2-tetra(p-hydroxyphenyl)ethane tetraglycidyl ether, glycerol triglycidyl ether, ortho-sec-butylphenyl glycidyl ether, 1,6-bis(2,3-epoxypropoxy)naphthalene, diglycerol polyglycidyl ether, polyethylene gly col glycidyl ether, YDB-340, YDB-412, YDF-2001 and YDF-2004 (all of which are trade names, manufactured by NIPPON STEEL Chemical & Material Co., Ltd.), NC-3000-H, EPPN-501H, EOCN-1020, NC-7000L, EPPN-201L, XD-1000 and EOCN-4600 (all of which are trade names, manufactured by Nippon Kayaku Co., Ltd.), Epicoat (registered trademark) 1001, Epicoat 1007, Epicoat 1009, Epicoat 5050, Epicoat 5051, Epicoat 1031S, Epicoat 180S65, Epicoat 157H70, YX-315-75 (all of which are trade names, manufactured by Japan Epoxy Resins Co., Ltd.), EHPE3150, Plaxel G402, PUE113601, PUE105 (all of which are trade names, manufactured by Daicel Chemical Industries, Ltd.), Epiclon (registered trademark) 830, 850, 1050, N-680, N-690, N-695, N-770, HP-7200, HP-820, EXA-4850-1000 (all of which are trade names, manufactured by DIC Corporation), DENACOL (registered trademark) EX-201, EX-251, EX-2 03, EX-313, EX-314, EX-321, EX-411, EX-511, EX-512, EX-612, EX-614, EX-614B, EX-711, EX-731, EX-810, EX-911, EM-150 (all of which are trade names, manufactured by Nagase ChemteX Corporation), Epolight (registered trademark) 70P, Epolight 100MF (all of which are trade names, manufactured by Kyoeisha Chemical Co., Ltd.) and the like.

Examples of oxetane compounds include 1,4-bis{[(3-ethyl-3-oxetanyl)methoxy]methyl}benzene, bis[1-ethyl(3-oxetanyl)]methyl ether, 4,4′-bis[(3-ethyl-3-oxetanyl)methyl]biphenyl, 4,4′-bis(3-ethyl-3-oxetanylmethoxy)biphenyl, ethylene glycol bis(3-ethyl-3-oxetanylmethyl)ether, diethylene glycol bis(3-ethyl)-3-oxetanylmethyl)ether, bis(3-ethyl-3-oxetanylmethyl)diphenoate, trimethylolpropane tris(3-ethyl-3-oxetanylmethyl)ether, pentaerythritol tetrakis(3-ethyl-3-oxetanylmethyl)ether, poly[[3-[(3-ethyl-3-oxetanyl)methoxy]propyl]silosesquioxane] derivatives, oxetanyl silicate, phenol novolac type oxetane, 1,3-bis[(3-ethyloxetan-3-yl)methoxy]benzene, OXT121 (trade name, manufactured by TOAGOSEI CO., LTD.), OXT221 (trade name manufactured by TOAGOSEI CO., LTD.) and the like.

Examples of bismaleimide compounds include 1,2-bis(maleimido)ethane, 1,3-bis(maleimido)propane, 1,4-bis(maleimido)butane, 1,5-bis(maleimido)pentane, 1,6-bis(maleimido)hexane, 2,2,4-trimethyl-1,6-bis(maleimido)hexane, N,N′-1,3-phenylenebis(maleimide), 4-methyl-N,N′-1,3-phenylenebis(maleimide), N,N′-1,4-phenylenebis(maleimide), 3-methyl-N,N′-1,4-phenylenebis(maleimide), 4,4′-bis(maleimide)diphenylmethane, 3,3′-diethyl-5,5′-dimethyl-4,4′-bis(maleimido)diphenylmethane, or 2,2-bis[4-(4-maleimidophenoxy)phenyl]propane.

Examples of allyl compounds include allyl alcohol, allylanisole, benzoic acid allyl ester, cinnamic acid allyl ester, N-allyloxyphthalimide, allylphenol, allylphenylsulfone, allyl urea, diallyl phthalate, diallyl isophthalate, diallyl terephthalate, diallyl maleate, diallyl isocyanurate, triallylamine, triallyl isocyanurate, triallyl cyanurate, triallylamine, triallyl 1,3,5-benzenetricarboxylate, triallyl trimellitate, triallyl phosphate, triallyl phosphite, triallyl citrate and the like.

Examples of blocked isocyanate compounds include hexamethylene diisocyanate-based blocked isocyanates (e.g., DURANATE SBN-70D, SBB-70P, SBF-70E, TPA-B80E, 17B-60P, MF-B60B, E402-B80B, MF-K60B and WM44-L70G manufactured by Asahi Kasei Corporation, TAKENATE B-882N manufactured by Mitsui Chemicals, Inc., 7960, 7961, 7982, 7991 and 7992 manufactured by Baxenden); tolylene diisocyanate-based blocked isocyanates (e.g., TAKENATE B-830 manufactured by Mitsui Chemicals, Inc.); 4,4′-diphenylmethane diisocyanate-based blocked isocyanates (e.g., TAKENATE B-815N manufactured by Mitsui Chemicals, Inc., BRONATE PMD-OA01 and PMD-MA01 manufactured by Daiei Sangyo Co., Ltd.); 1,3-bis(isocyanatomethyl)cyclohexane-based blocked isocyanates (e.g., TAKENATE B-846N manufactured by Mitsui Chemicals, Inc., CORONATE BI-301, 2507 and 2554 manufactured by TOSOH CORPORATION); and isophorone diisocyanate-based blocked isocyanates (e.g., 7950, 7951 and 7990 manufactured by Baxenden).

Of these, alkoxymethyl compounds and epoxy compounds are preferable from the viewpoints of the storage stability and mechanical properties. From the viewpoints of the mechanical properties and chemical resistance, the thermal crosslinking agent preferably has two or more crosslinkable functional groups in one molecule.

The thermal crosslinking agent may be used alone or in combination of plural.

The content of the thermal crosslinking agent in the photosensitive resin composition is preferably 0.2 part by mass to 40 parts by mass relative to 100 parts by mass of the polyimide (A). From the viewpoint of the chemical resistance, the lower limit thereof is more preferably 1 part by mass or more, and still more preferably 5 parts by mass or more. The upper limit thereof is more preferably 30 parts by mass or less, and still more preferably 20 parts by mass or less, from the viewpoint of the storage stability of the photosensitive resin composition.

### (J) Thermal Polymerization Initiator

The photosensitive resin composition of the present disclosure may include a thermal polymerization initiator. The thermal polymerization initiator is a compound that generates radicals by heat, and examples thereof include organic peroxides such as dialkyl peroxide, diacyl peroxide, peroxy ester and peroxy ketal, and azo-based polymerization initiators such as azonitrile, azo ester and azoamide. Of these, dialkyl peroxide and diacyl peroxide (e.g., dicumyl peroxide) are preferred from the viewpoint of the chemical resistance.

The thermal polymerization initiators may be used alone or in combination of plural.

When the photosensitive resin composition of the present disclosure includes a thermal polymerization initiator, the mixing amount is preferably 0.1 part by mass or more and 10 parts by mass or less relative to 100 parts by mass of the polyimide (A). The lower limit thereof is more preferably 0.5 part by mass or more from the viewpoint of the chemical resistance. The lower limit thereof is more preferably 5 parts by mass or less from the viewpoint of the storage stability of the photosensitive resin composition.

### Other Components

The photosensitive resin composition of the present disclosure may further include other components other than the above components (A) to (J). Examples of the other components other than the components (A) to (J) include, but are not limited to, hindered phenol compounds, adhesion aids, sensitizers, thermal polymerization inhibitors, thermal base generators, surfactants and the like. The other components may be used alone or in combination of plural.

To inhibit discoloration on the copper surface, the photosensitive resin composition may optionally include a hindered phenol compound. Examples of the hindered phenol compound include, but are not limited to, 2,6-di-t-butyl-4-methylphenol, 2,5-di-t-butyl-hydroquinone, octadecyl-3-(3,5-di-t-butyl-4-hydroxyphenyl) propionate, isooctyl-3-(3,5-di-t-butyl-4-hydroxyphenyl) propionate, 4,4′-methylenebis(2,6-di-t-butylphenol), 4,4′-thio-bis(3-methyl-6-t-butylphenol), 4,4′-butylidene-bis(3-methyl-6-t-butylphenol), triethylene glycol-bis[3-(3-t-butyl-5-methyl-4-hydroxyphenyl) propionate], 1,6-hexanediol-bis[3-(3,5-di-t-butyl-4-hydroxyphenyl) propionate], 2,2-thio-diethylenebis[3-(3,5-di-t-butyl-4-hydroxyphenyl) propionate], N,N′-hexamethylenebis(3,5-di-t-butyl-4-hydroxy-hydrocinnamide), 2,2′-methylene-bis(4-methyl-6-t-butylphenol), 2,2′-methylene-bis(4-ethyl-6-t-butylphenol), pentaerythrityl-tetrakis[3-(3,5-di-t-butyl-4-hydroxyphenyl) propionate], tris-(3,5-di-t-butyl-4-hydroxybenzyl)-isocyanurate, 1,3,5-trimethyl-2,4,6-tris(3,5-di-t-butyl-4-hydroxybenzyl) benzene, 1,3,5-tris(3-hydroxy-2,6-dimethyl-4-isopropylbenzyl)-1,3,5-triazine-2,4,6-(1H,3H,5H)-trione, 1,3,5-tris(4-t-butyl-3-hydroxy-2,6-dimethylbenzyl)-1,3,5-triazine-2,4,6-(1H,3H,5H)-trione, 1,3,5-tris(4-s-butyl-3-hydroxy-2,6-dimethylbenzyl)-1,3,5-triazine-2,4,6-(1H,3H,5H)-trione, 1,3,5-tris[4-(1-ethylpropyl)-3-hydroxy-2,6-dimethylbenzyl]-1,3,5-triazine-2,4,6-(1H,3H,5H)-trione, 1,3,5-tris[4-triethylmethyl-3-hydroxy-2,6-dimethylbenzyl]-1,3,5-triazine-2,4,6-(1H,3H,5H)-trione, 1,3,5-tris(3-hydroxy-2,6-dimethyl-4-phenylbenzyl)-1,3,5-triazine-2,4,6-(1H,3H,5H)-trione, 1,3,5-tris(4-t-butyl-3-hydroxy-2,5,6-trimethylbenzyl)-1,3,5-triazine-2,4,6-(1H,3H,5H)-trione, 1,3,5-tris(4-t-butyl-5-ethyl-3-hydroxy-2,6-dimethylbenzyl)-1,3,5-triazine-2,4,6-(1H,3H,5H)-trione, 1,3,5-tris(4-t-butyl-6-ethyl-3-hydroxy-2-methylbenzyl)-1,3,5-triazine-2,4,6-(1H,3H,5H)-trione, 1,3,5-tris(4-t-butyl-6-ethyl-3-hydroxy-2,5-dimethylbenzyl)-1,3,5-triazine-2,4,6-(1H,3H,5H)-trione, 1,3,5-tris(4-t-butyl-5,6-diethyl-3-hydroxy-2-methylbenzyl)-1,3,5-triazine-2,4,6-(1H,3H,5H)-trione, 1,3,5-tris(4-t-butyl-3-hydroxy-2-methylbenzyl)-1,3,5-triazine-2,4,6-(1H,3H,5H)-trione, 1,3,5-tris(4-t-butyl-3-hydroxy-2,5-dimethylbenzyl)-1,3,5-triazine-2,4,6-(1H,3H,5H)-trione, 1,3,5-tris(4-t-butyl-5-ethyl-3-hydroxy-2-methylbenzyl)-1,3,5-triazine-2,4,6-(1H,3H,5H)-trione and the like.

Of these, 1,3,5-tris(4-t-butyl-3-hydroxy-2,6-dimethylbenzyl)-1,3,5-triazine-2,4,6-(1H,3H,5H)-trione or the like is particularly preferable.

When the photosensitive resin composition of the present disclosure includes the hindered phenol compound, the mixing amount is preferably 0.1 part by mass or more and 20 parts by mass or less relative to 100 parts by mass of the polyimide (A).

The lower limit thereof is more preferably 0.5 part by mass or more, since when the photosensitive resin composition is formed on copper or a copper alloy, the discoloration and corrosion of the copper or copper alloy are prevented. The upper limit thereof is more preferably 10 parts by mass or less from the viewpoint of the photosensitivity.

In order to improve the adhesion between a film formed using the photosensitive resin composition, and a substrate, the photosensitive resin composition of the present disclosure may optionally contain other adhesion aids in addition to the silane coupling agent. As other adhesion aids, aluminum-based adhesion aids and the like can be used.

Examples of the aluminum-based adhesive aid include aluminum tris(ethylacetoacetate), aluminum tris(acetylacetonate), ethylacetoacetate aluminum diisopropylate and the like.

When the photosensitive resin composition of the present disclosure includes the adhesion aid, the mixing amount of the adhesion aid is preferably 0.01 part by mass or more and 25 parts by mass or less relative to 100 parts by mass of the polyimide (A). The lower limit thereof is more preferably 0.5 part by mass or more from the viewpoint of the adhesion between the coating film and the substrate. The upper limit thereof is more preferably 20 parts by mass or less from the viewpoint of the storage stability of the photosensitive resin composition.

The photosensitive resin composition of the present disclosure may optionally include a sensitizer to improve the photosensitivity. Examples of the sensitizer include Michler's ketone, 4,4′-bis(diethylamino) benzophenone, 2,5-bis(4′-diethylaminobenzal) cyclopentane, 2,6-bis(4′-diethylaminobenzal) cyclohexanone, 2,6-bis(4′-diethylaminobenzal)-4-methylcyclohexanone, 4,4′-bis(dimethylamino) chalcone, 4,4′-bis(diethylamino) chalcone, p-dimethylaminocinnamilideneindanone, p-dimethylaminobenzylideneindanone, 2-(p-dimethylaminophenylbiphenylene)-benzothiazole, 2-(p-dimethylaminophenylvinylene) benzothiazole, 2-(p-dimethylaminophenylvinylene) isonaphthothiazole, 1,3-bis(4′-dimethylaminobenzal) acetone, 1,3-bis(4′-diethylaminobenzal) acetone, 3,3′-carbonyl-bis(7-diethylaminocoumarin), 3-acetyl-7-dimethylaminocoumarin, 3-ethoxycarbonyl-7-dimethylaminocoumarin, 3-benzyloxycarbonyl-7-dimethylaminocoumarin, 3-methoxycarbonyl-7-diethylaminocoumarin, 3-ethoxycarbonyl-7-diethylaminocoumarin, N-phenyl-N′-ethylethanolamine, N-phenyldiethanolamine, N-p-tolyldiethanolamine, N-phenylethanolamine, 4-morpholinobenzophenone, isoamyl dimethylaminobenzoate, isoamyl diethylaminobenzoate, 2-mercaptobenzimidazole, 1-phenyl-5-mercaptotetrazole, 2-mercaptobenzothiazole, 2-(p-dimethylaminostyryl) benzoxazole, 2-(p-dimethylaminostyryl) benzthiazole, 2-(p-dimethylaminostyryl) naphtho(1,2-d) thiazole, 2-(p-dimethylaminobenzoyl) styrene and the like. These can be used alone or in combination of plural, for example, two to five thereof.

When the photosensitive resin composition of the present disclosure includes a sensitizer to improve the photosensitivity, the mixing amount thereof is preferably 0.1 part by mass or more and 25 parts by mass or less relative to 100 parts by mass of the polyimide (A).

The photosensitive resin composition of the present disclosure may optionally include a thermal polymerization inhibitor to improve the stability of the viscosity and photosensitivity of the photosensitive resin composition during storage, particularly in a solution containing a solvent.

It is possible to use, as the thermal polymerization inhibitor, for example, hydroquinone, N-nitrosodiphenylamine, p-tert-butylcatechol, phenothiazine, N-phenylnaphthylamine, ethylenediaminetetraacetic acid, 1,2-cyclohexanediaminetetraacetic acid, glycol ether diaminetetraacetic acid, 2,6-di-tert-butyl-p-methylphenol, 5-nitroso-8-hydroxyquinoline, 1-nitroso-2-naphthol, 2-nitroso-1-naphthol, 2-nitroso-5-(N-ethyl-N-sulfopropylamino)phenol, N-nitroso-N-phenylhydroxylamineammonium salt, N-nitroso-N(1-naphthyl)hydroxylamineammonium salt and the like.

The photosensitive resin composition of the present disclosure may optionally include a surfactant to improve the flatness of the film. Examples of the surfactant include fluorine-based surfactants, silicone-based surfactants and hydrocarbon-based surfactants.

There are no particular limitations on the fluorine-based surfactant as long as it contains a fluorine atom in the molecule. Examples of the fluorine-based surfactant include perfluoroalkyl sulfonates, perfluoroalkyl carboxylates, perfluoroalkyl alcohols, perfluoroalkyl alkylene oxide adducts, and perfluoroalkyl phosphate esters. More specifically, examples thereof include, by trade name, MEGAFAC F-114, MEGAFAC F-251, MEGAFAC F-253, MEGAFAC F-281, MEGAFAC F-410, MEGAFAC F-430, MEGAFAC F-477, MEGAFAC F-510, MEGAFAC F-551, MEGAFAC F-552, MEGAFAC F-553, MEGAFAC F-554, MEGAFAC F-555, MEGAFAC F-556, MEGAFAC F-557, MEGAFAC F-558, MEGAFAC F-559, MEGAFAC F-560, MEGAFAC F-561, MEGAFAC F-562, MEGAFAC F-563, MEGAFAC F-565, MEGAFAC F-566, MEGAFAC F-567, MEGAFAC F-569, MEGAFAC F-570, MEGAFAC F-571, MEGAFAC F-572, MEGAFAC F-573, MEGAFAC F-574, MEGAFAC F-575, MEGAFAC F-576, MEGAFAC F-577, MEGAFAC F-578, MEGAFAC F-579, MEGAFAC F-580, MEGAFAC F-581, MEGAFAC F-582, MEGAFAC F-583, MEGAFAC F-584, MEGAFAC F-585, MEGAFAC F-586, MEGAFAC F-587, MEGAFAC F-588, MEGAFAC F-589, MEGAFAC F-590, MEGAFAC F-591, MEGAFAC F-592, MEGAFAC F-593, MEGAFAC F-594, MEGAFAC F-595, MEGAFAC F-596, MEGAFAC F-597, MEGAFAC F-598, MEGAFAC F-599, MEGAFAC F-59 Fac F-568, MEGAFAC F-569, MEGAFAC F-570, MEGAFAC F-572, MEGAFAC F-574, MEGAFAC F-575, MEGAFAC F-576, MEGAFAC R-40, MEGAFAC R-40-LM, MEGAFAC R-41, MEGAFAC R-94, MEGAFAC RS-56, MEGAFAC RS-72-K, MEGAFAC RS-75, MEGAFAC RS-76-E, MEGAFAC RS-76-NS, MEGAFAC RS-78, MEGAFAC RS-90, MEGAFAC DS-21 (all of which are manufactured by DIC Corporation); FC-4430, FC-4432 (all of which are manufactured by 3M Japan Limited); SURFLON S-211, SURFLON S-221, SURFLON S-231, SURFLON S-232, SURFLON S-233, SURFLON S-241, SURFLON S-242, SURFLON S-243, SURFLON S-420, SURFLON S-431, SURFLON S-386, SURFLON S-611, SURFLON S-647, SURFLON S-651, SURFLON S-653, SURFLON S-656, SURFLON S-658, SURFLON S-693, SURFLON S-CFJ, SURFLON FPE-50 (all of which are manufactured by AGC SEIMI CHEMICAL CO., LTD.) and the like.

The silicone-based surfactant is not particularly limited as long as it has a disiloxane structure as a non-polar site. Examples of the silicone-based surfactant include polyether-modified silicones, such as linear polyether-modified silicones, linear alkyl-co-modified polyether-modified silicones, branched polyether-modified silicones, branched alkyl-co-modified polyether-modified silicones and the like. More specifically, examples thereof include, by trade name, KF-351A, KF-352A, KF-353, KF-354L, KF-355A, KF-615A, KF-945, KF-640, KF-642, KF-643, KF-644, KF-6020, KF-6204, X-22-4515, KF-6011, KF-6012, KF-6015, KF-6017, KP-301, KP-306, KP-109, KP-310, KP-310B, KP-323, KP-326, KP-341, KP-104, KP-110, KP-112 (all of which are manufactured by Shin-Etsu Chemical Co., Ltd.); DBE-224, DBE-621, DBE-712, DBE-814, DBE-821, DBE-921, DBP-732, YAD-122, YBD-125, YMS-T31, CMS-626, CMS-222, DBP-534, CMS-832, DBP-C22, QMS-435, ABP-263, DMS-R05, DMS-R11, DMS-R18, DMS-R22, DMS-R31 (all of which are manufactured by Gelest); BYK-300, BYK-301, BYK-302, BYK-306, BYK-307, BYK K-310, BYK-313, BYK-315 N, BYK-320, BYK-322, BYK-323, BYK-325 N, BYK-326, BYK-327, BYK-33 0, BYK-331, BYK-332, BYK-333, BYK-342, BYK-345, BYK-346, BYK-347, BYK-348, BYK-349, BYK-35 0, BYK-352, BYK-354, BYK-355, BYK-356, BYK-358 N, BYK-359, BYK-360 P, BYK-361 N, BYK-364 P, BYK-366 P, BYK-368 P, BYK-370, BYK-375, BYK-377, BYK-378, BYK-381, BYK-390, BYK-392, BYK-394, BYK-399, BYK-UV 3500, BYK-UV 3505, BYK-UV 3510, BYK-UV 3530, BYK-UV 3535, BYK-UV 3570, BYK-UV 3575, BYK-UV 3576 (all of which are manufactured by BYK Japan); NEWCOL 2302, NEWCOL 2303, NEWCOL 2305, NEWCOL 2307, NEWCOL 2308, NEWCOL 2308, NEWCOL 2310, NEWCOL 2312, NEWCOL 2314, NEWCOL 2318, NEWCOL 2320, NEWCOL 2327 (20), NEWCOL 2330, NEWCOL 2344, NEWCOL 2360, NEWCOL 2399-5, NEWCOL 2399-S(25) (all of which are manufactured by Nippon Nyukazai Co., Ltd.); DMC6038, OW1500, SPG128VP, L03, L033, L053, L066 (all of which are manufactured by Asahi Kasei Wacker Silicone Co., Ltd.); SH-28PA, SH-190, SH-193, SZ-6032, SF-8428, DC-57, DC-190 (all of which are manufactured by Dow Corning Toray Co., Ltd.) and the like.

The surfactant may have a crosslinkable group in the molecule. Examples of such surfactant include silicone surfactants having a crosslinkable group in the molecule, and fluorine-based surfactants having a crosslinkable group in the molecule. Examples of the crosslinkable group include thermally crosslinkable groups such as an epoxy group, an N-methylolamide group, an oxazoline group and an allyl group, and ultraviolet (UV) crosslinkable groups such as a vinyl group, a (meth)acryloyl group and an epoxy group. More specifically, examples of the surfactant having a crosslinkable group in the molecule include, by trade name, MEGAFAC RS-75-A, MEGAFAC RS-72-K, MEGAFAC RS-75-NS, MEGAFAC RS-78, MEGAFAC RS-90, MEGAFAC RS-56 (all of which are manufactured by DIC Corporation); BYK-UV3500, BYK-UV3505, BYK-UV3530, BYK-UV3570, BYK-UV3575, BYK-UV3576 (all of which are manufactured by BYK-Chemie) and the like.

The surfactant may be a surfactant from which the fluorine-containing group is eliminated by a heat treatment. Examples of such surfactant include, by trade name, MEGAFAC DS-21 (manufactured by DIC Corporation).

When the photosensitive resin composition of the present disclosure includes a surfactant, the mixing amount of the surfactant is preferably 0.001 part by mass or more and 1 part by mass or less, and more preferably 0.01 part by mass or more and 0.1 part by mass or less, relative to 100 parts by mass of the polyimide (A).

### <Method for Producing Cured Relief Pattern>

The method for producing a cured relief pattern of the present disclosure includes:
(1) a step of applying the above-mentioned photosensitive resin composition of the present disclosure on a substrate to form a photosensitive resin layer on the substrate (resin layer formation step),
(2) a step of exposing the photosensitive resin layer (exposure step),
(3) a step of the exposed photosensitive resin layer to form a relief pattern (relief pattern formation step), and
(4) a step of subjecting the relief pattern to a heat treatment to form a cured relief pattern (cured relief pattern formation step).

### (1) Resin Layer Formation Step

In this step, the photosensitive resin composition of the present disclosure is applied on a substrate, and then dried as necessary to form a photosensitive resin layer. It is possible to use, as the application method, methods conventionally used for the application of a photosensitive resin composition, for example, a method of applying using a spin coater, a bar coater, a blade coater, a curtain coater or a screen-printing machine, or a method of spray coating using a spray coater.

As necessary, the coating film containing the photosensitive resin composition can be dried. It is possible to use, as the drying method, a method such as air drying, heat drying using an oven or a hot plate, or vacuum drying.

Specifically, when air drying or heat drying is carried out, drying can be carried out under the conditions at 20° C. to 150° C. for 1 minute to 1 hour. In such manner, the photosensitive resin layer can be formed on the substrate.

### (2) Exposure Step

In this step, the photosensitive resin layer formed as mentioned above is exposed through a photomask or a reticle having a pattern or directly, using an exposure device such as a contact aligner, a mirror projection, or a stepper. By this exposure, the polymerizable group which may be possessed by the polyimide (A) included in the photosensitive resin composition, and the polymerizable functional group of the component (D) which may be optionally included are crosslinked by an action of the photopolymerization initiator (C). This crosslinking makes the exposed area insoluble in a developer mentioned later, and thus a relief pattern can be formed.

Thereafter, for the purpose of improving the photosensitivity, post-exposure baking (PEB) or pre-development baking according to a combination of an arbitrary temperature and time may be carried out, as necessary. The range of baking conditions is preferably 40° C. to 120° C., and the time is preferably 10 seconds to 240 seconds, though the baking is not limited to these ranges unless the various properties of the photosensitive resin composition of the present disclosure are inhibited thereby.

### (3) Relief Pattern Formation Step

In this step, the unexposed area of the photosensitive resin layer after exposure is developed and removed to form a relief pattern. As the developing method for developing a photosensitive resin layer after exposure (irradiation), any method can be selected and used from conventionally known methods of developing a photoresist, for example, a rotary spray method, a paddle method and an immersion method accompanied by an ultrasonic treatment. After development, for the purpose of adjusting the shape of the relief pattern, post-development baking may be carried out by a combination of an arbitrary temperature and time, as necessary.

As the developer used for development, for example, a good solvent for the photosensitive resin composition or a combination of a good solvent and a poor solvent is preferable.

As the good solvent, for example, N-methyl-2-pyrrolidone, N-cyclohexyl-2-pyrrolidone, N,N-dimethylacetamide, cyclopentanone, cyclohexanone, γ-butyrolactone and α-acetyl-γ-butyrolactone are preferable.

As the poor solvent, for example, toluene, xylene, methanol, ethanol, isopropyl alcohol, ethyl lactate, propylene glycol methyl ether acetate and water are preferable. When a good solvent and a poor solvent are mixed and used, it is preferable to adjust the ratio of the poor solvent to the good solvent in accordance with the solubility of the polymer in the photosensitive resin composition. Two or more solvents may be used, for example, a plurality thereof may be used in combination.

### (4) Cured Relief Pattern Formation Step

In this step, the relief pattern obtained by the above development is subjected to a heat treatment to dilute the photosensitive component, thus forming a cured relief pattern composed of a polyimide. It is possible to select, as the method of a heat treatment, for example, various methods such as those using a hot plate, an oven, and a temperature raising oven capable of setting a temperature program. The heat treatment can be carried out under the conditions, for example, at 160° C. to 350° C. for 30 minutes to 5 hours. The temperature of the heat treatment is preferably 300° C. or lower, and more preferably 250° C. or lower. Air may be used as an atmosphere gas during heat-curing, and an inert gas such as nitrogen or argon can also be used.

### <Cured Film>

The present disclosure also provides a cured film formed from the photosensitive resin composition of the present disclosure. The cured film formed from the photosensitive resin composition includes at least one polyimide selected from the group consisting of the following (A1) and (A2):
(A1) a polyimide having an aromatic ring in a side chain, and
(A2) a polyimide having a structure represented by the following general formula (1):

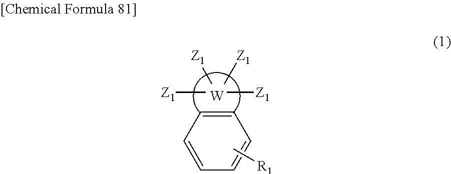

wherein W is an aromatic ring or aliphatic ring which may have any substituent other than Z₁ (in which those having an aromatic ring are excluded), at least two Z₁ of a plurality of Z₁ form a main chain together with W, the remaining Z₁ is a hydrogen atom, and R₁ is a hydrogen atom or a monovalent organic group (in which those having an aromatic ring are excluded).

### <Semiconductor Device>

In the present disclosure, there is also provided a semiconductor devices having a cured relief pattern obtained from the photosensitive resin composition described above. Specifically, there is provided a semiconductor devices having a base material which is a semiconductor element, and a cured relief pattern. The cured relief pattern may be produced by the above-mentioned method for producing a cured relief pattern using the above-described photosensitive resin composition.

The present disclosure also provides a method for producing a semiconductor devices in which a semiconductor element is used as a base material and the above-mentioned method for producing a cured relief pattern of the present embodiments is included as a part of a step. In this case, the semiconductor devices can be produced by forming a cured relief pattern formed by the above-mentioned method for producing a cured relief pattern as a surface protective film of a semiconductor devices, an interlayer insulating film, a rewiring insulating film, a protective film for flip-chip devices, or a protective film of a semiconductor devices having a bump structure, and combining it with a known method for producing a semiconductor devices.

### <Display Device>

In the present disclosure, there is provided a display device comprising a display element and a cured film provided on an upper portion of the display element, wherein the cured film is the cured relief pattern mentioned above. Here, the cured relief pattern may be laminated in direct contact with the display element or may be laminated with another layer interposed therebetween. Examples of the cured film include surface protective films, insulating films and flattening films for TFT liquid crystal display elements and color filter elements; protrusions for MVA type liquid crystal display devices; and partition walls for organic EL element cathodes.

In addition to application to semiconductor devices as mentioned above, the photosensitive resin composition of the present disclosure is also useful in applications such as interlayer insulation of multilayer circuits, cover-coating of flexible copper clad plates, solder resist films, and liquid crystal alignment films.

<Method for producing Photosensitive Resin Composition>

The method of producing a photosensitive resin composition of the present disclosure includes a step of producing (A) a polyimide by the method of the present disclosure as described above in “Method for producing (A) Polyimide”; and a step of mixing 100 parts by mass of (A) a polyimide, 30 to 1,000 parts by mass of (B) a solvent, and 1 to 30 parts by mass of (C) a photopolymerization initiator to obtain a photosensitive resin composition.

Optionally, the photosensitive resin composition may further include additives selected from the above-described (D) monomer having a polymerizable functional group (radical polymerizable compound), (E) silane coupling agent, (F) rust inhibitor, (G) organic titanium compound, (H) plasticizer, (I) thermal crosslinking agent, and (J) thermal polymerization initiator, as well as other components.

### OTHER EMBODIMENTS

Another embodiment of the invention of the present disclosure is (A) a polyimide having, as raw materials, at least an acid anhydride having a Hansen Solubility Parameter (HSP) value of 25.5<δt<28.9, as estimated by Hansen Solubility Parameters in Practice (HSPiP), and/or a diamine having an HSP value of δd>20.0 and δp<7.6.

Yet another embodiment of the invention of the present disclosure is a photosensitive resin composition including:
(A) a polyimide including, as raw materials, at least an acid anhydride having a Hansen Solubility Parameter (HSP) value of 25.5<δt<28.9, as estimated by Hansen Solubility Parameters in Practice (HSPiP), and/or a diamine having an HSP value of δd>20.0 and δp<7.6,
(B) a solvent, and
(C) a photopolymerization initiator.

In the polyimide of another embodiment, the repeating portion derived from the diamine used and having an HSP value within the above range may be 50% by mass or more, of the repeating portion derived from the diamine used. In the polyimide of another embodiment, the repeating portion derived from the acid anhydride used and having an HSP value within the above range may be 50% by mass or more, of the repeating portion derived from the acid anhydride used.

The preferred embodiment described in the first embodiment may be similarly applied to the above embodiments mentioned as another embodiment.

It may be assumed that yet another embodiment of the invention of the present disclosure does not include at least one of the following structural units:

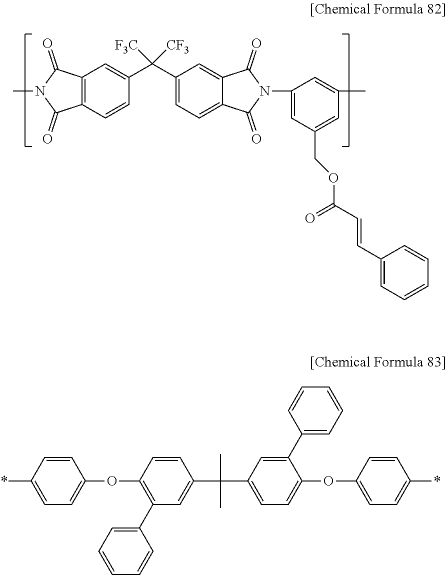

and does not include, as a raw material, the following diamine:

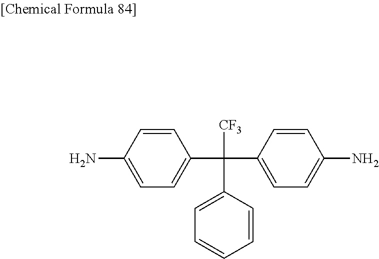 [SMILES: Nc1ccc(C(c2ccccc2)(c2ccc(N)cc2)C(F)(F)F)cc1]

### EXAMPLES

The present embodiments will be specifically described by way of the following Examples, but the present embodiments is not limited only thereto. In Examples, Comparative Examples, Production Examples and Synthesis Examples, physical properties of the polyimide, polyimide precursor or photosensitive resin composition were measured and evaluated in accordance with the following methods.

### <Measurement and Evaluation Methods>

### (1) Measurement of Weight-Average Molecular Weight (Mw), Number-Average Molecular Weight (Mn)

The weight-average molecular weight (Mw) and the number-average molecular weight (Mw) of each resin were measured by gel permeation chromatography (GPC) under the following conditions. The molecular weight distribution was calculated as Mw/Mn.

The solvent used was N-methyl-2-pyrrolidone (NMP), to which 30 mmol/L lithium bromide monohydrate (manufactured by FUJIFILM Wako Pure Chemical Corporation, purity of 99.5%) and 50 mmol/L phosphoric acid (manufactured by FUJIFILM Wako Pure Chemical Corporation, for high performance liquid chromatography) were added, followed by dissolving immediately before measurement. A calibration curve for calculating the weight-average molecular weight was made using standard polystyrene (Easical Type PS-1, manufactured by Agilent Technologies).
Apparatus: HLC-8320GPC (manufactured by TOSOH CORPORATION)
Column: Tsk gel Super HM-H×2 (manufactured by TOSOH CORPORATION), Tsk gel
Super H-RC×1
Flow rate: 0.5 mL/min
Column temperature: 40° C.
Detector: UV-8320 (UV-VIS: ultraviolet-visible spectrophotometer, manufactured by TOSOH CORPORATION)

### (2) Evaluation of Solubility

The photosensitive resin composition prepared and filtered by the method described below was spin-coated on a 6-inch silicon wafer (manufactured by Fujimi Electronics Co., Ltd., thickness of 625±25 m) using a coater developer (model D-Spin 60A, manufactured by SOKUDO Co., Ltd.), and pre-baked on a hot plate at 110° C. for 180 seconds, thereby forming an about 10.0 m-thick coating film. Regarding problems occurred during each process of preparation, filtration and spin-coating, the solubility was rated as soluble (G: Good), semi-insoluble (A: Average) or insoluble (F: Fail) according to the following criteria.

### (Evaluation Criteria)

If any of the following applies, it was rated as “F: Fail”.

The undissolved residue was observed in the prepared photosensitive resin composition.

The prepared photosensitive resin composition was in a gel form.

The prepared photosensitive resin composition was opaque.

The residue was observed on a filter paper after filtration.

Due to clogging or the like during filtration, filtration could not be completed within a normal test period.

If the following applies, it was rated as “A: Average”.

It did not meet “F: Fail”, but irregularities and/or repelling were observed on the surface of the coating film after pre-baking.

If the following applies, it was rated as “G: Good”

It did not meet either “F: Fail” or “A: Average”, namely, none of the above problems were observed.

For the above evaluation of solubility, the observation was conducted visually and basically at room temperature (23° C.).

Regarding “F: Fail”,
the photosensitive resin composition was judged as being “gel-like” if no flow was visually observed when the composition was tilted at a 450 angle; and
the photosensitive resin composition was judged as being “undissolved” or “opaque” if turbidity was visually observed in the photosensitive resin composition.

### (3) Breaking Elongation

The photosensitive resin composition prepared by the method described below was spin-coated on a 6-inch silicon wafer (manufactured by Fujimi Electronics Industry Co., Ltd., thickness of 625±25 μm) using a coater developer (model D-Spin60A, manufactured by SOKUDO Co., Ltd.). Thereafter, the wafer was prebaked on a hot plate at 110° C. for 180 seconds to form an about 10.0 m-thick coating film. The entire surface of this coating film was exposed to light at an exposure dose of 1,000 mJ/cm² using Prisma GHI (manufactured by Ultratech Co., Ltd.). The exposed film thus obtained was subjected to a heat treatment in a nitrogen atmosphere at 230° C. for 2 hours, using a temperature programmed curing furnace (Model VF-2000, manufactured by Koyo Lindberg, Co., Ltd.) to obtain a cured film (polyimide film). The cured film thus obtained was cut into a width of 3 mm as the shape of strip of paper by a dicing saw (model DAD3350, manufactured by DISCO Corporation) and then separated from the silicon wafer by a treatment with 46% hydrofluoric acid. Thereby, a polyimide tape was obtained. The polyimide tape thus obtained was left to stand for 24 hours or more in an atmosphere of a temperature of 23° C. and a relative humidity of 50%. After being left to stand, the breaking elongation (%) of the polyimide tape was measured using a tensile tester (model UTM-II-20, manufactured by ORIENTEC CO., LTD.) under conditions of a test speed of 40 mm/min and an initial load of 0.5 fs, and was evaluated based on the following criteria.
“E: Excellent”: 45% or more
“G: Good”: 30% or more and less than 45%
“A: Average”: 20% or more and less than 30%
“F: Fail”: less than 20%

The breaking elongation (%) of the polyimide tape was calculated by the following formula:

$$Elongation ( \% ) = 100 \times ( L - L 0 ) / L 0$$

where
L: length of polyimide tape just before it breaks in the tensile test, and
L0: length of polyimide tape before the test.

### (4) Copper Migration

A substrate was prepared using a semi-additive process (SAP) on which comb-shaped wiring with a line/space of 5 um/5 um was formed. The photosensitive resin composition prepared and filtered by the method described below was spin-coated on the comb-shaped wiring using a coater developer (model D-Spin60A, manufactured by SOKUDO Co., Ltd.), followed by pre-baking on a hot plate at 110° C. for 180 seconds to form a coating film. The entire surface of this coating film was exposed to light at an exposure dose of 1,000 mJ/cm² using Prisma GHI (manufactured by Ultratech Co., Ltd.). The exposed film thus obtained was subjected to a heat treatment in a nitrogen atmosphere at 230° C. for 2 hours, using a temperature programmed curing furnace (Model VF-2000, manufactured by Koyo Lindberg, Co., Ltd.) to obtain a 5 um-thick cured film for evaluation. The cured film was left to stand under the conditions of 85% humidity and a temperature of 130° C. in a state where a voltage of 5.0 V was applied to the comb-shaped wiring, and the resistance between the anode and cathode was measured over time. When the resistance value after a lapse of 200 hours was 1.0E+5Ω or more, it was rated as G: Good, and when the resistance value was less than 1.0E+5Ω, it was rated as F: Fail.

(5) Production of Cured Relief Pattern used for Evaluation of Flatness of Prebaked Film

The photosensitive resin composition prepared by the method described below was spin-coated on a 6-inch silicon wafer (manufactured by Fujimi Electronics Industry Co., Ltd., thickness of 625±25 m) using a coater developer (model D-Spin60A, manufactured by SOKUDO Co., Ltd.), and then the wafer was prebaked on a hot plate at 110° C. for 180 seconds to form an about 15 m-thick coating film. An energy dose of 500 mJ/cm² was applied to this coating film by an equal magnification projection exposure system Prisma GHI S/N5503 (manufactured by Ultratech Co., Ltd.) equipped with a gh-ray cut filter, using a mask with a test pattern. Next, this coating film was spray-developed by a coater developer (model D-Spin 60A, manufactured by SOKUDO Co., Ltd.) using cyclopentanone as a developer for a time period equal to 1.4 times the time required for the unexposed areas to completely dissolve and disappear. This was followed by a 10 second spin spray rinse with propylene glycol methyl ether acetate to obtain a relief pattern on Si.

The wafer with a relief pattern formed on Si was subjected to a heat treatment in a nitrogen atmosphere at 230° C. for 2 hours, using a temperature programmed curing furnace (Model VF-2000, manufactured by Koyo Lindberg, Co., Ltd.) to obtain a cured relief pattern on Si, which was made of the resin composition and had a thickness of about 12 m and had vias (circular openings) with a diameter of 20 m. On the cured relief pattern thus obtained, Ti having a thickness of 200 nm and Cu having a thickness of 400 nm were sputtered in this order using a sputtering device (L-440S-FHL model, manufactured by Canon Anelva Corporation).

### (6) Flatness of Prebaked Film

To evaluate the in-plane uniformity of the prebaked film, the flatness was evaluated as shown below.

On the relief pattern obtained by the method (5) above, a photosensitive resin composition prepared by the method described below was applied by spin coating using a coater developer (model D-Spin 60A, manufactured by SOKUDO Co., Ltd.) so that the film thickness after pre-baking would be 7 μm, followed by drying at 110° C. for 180 seconds to form a prebaked film. Thereby, a substrate with the pre-baked film (film-coated substrate) was obtained.

The substrate with the film thus obtained was split along an imaginary line passing through the center of the vias, and the cross-section was polished. Then, cross-sectional SEM images were obtained. The image was observed, and the surface irregularities of the photosensitive resin composition film were evaluated based on the following criteria.
“E: Excellent”: less than 1.0 μm
“G: Good”: 1.0 m or more and less than 2.0 μm
“A: Average”: 2.0 m or more and less than 4.0 μm
“F: Fail”: 4.0 m or more

The numerical value of the surface irregularities is calculated as follows.

That is, the difference between the film thickness of the cured relief pattern obtained by the method (5) above and the total thickness of the prebaked film formed on that pattern, and the thickness of the prebaked film formed in the vias is calculated as the numerical value of the surface irregularities.

### (7) Change in Film Thickness Before and After Curing Treatment

Ti having a thickness of 200 nm and Cu having a thickness of 400 nm were sputtered in this order on a 6-inch silicon wafer (manufactured by Fujimi Electronics Industry Co., Ltd., thickness of 625±25 m) using a sputtering device (Model L-440S-FHL, manufactured by Canon Anelva Corporation). Subsequently, a photosensitive resin composition prepared by the method described below was spin-coated on this wafer using a coater developer (model D-Spin60A, manufactured by SOKUDO Co., Ltd.), followed by pre-baking on a hot plate at 110° C. for 180 seconds to form an about 7.5 μm-thick coating film. The entire surface of this coating film was exposed to light at an exposure dose of 500 mJ/cm² by an equal magnification projection exposure system Prisma GHI S/N5503 (manufactured by Ultratech Co., Ltd.) equipped with a gh-ray cut filter, using a mask with a test pattern. Thereafter, the coating film formed on the wafer was spray-developed using cyclopentanone in a developing machine (model D-SPIN636, manufactured by Dainippon Screen Mfg. Co., Ltd., Japan). After rinsing with propylene glycol methyl ether acetate, drying was carried out by spin drying. The film thickness after this development and drying was measured, and the obtained film thickness was defined as film thickness 1. This developed and dried film was further subjected to a heat treatment in a nitrogen atmosphere at 230° C. for 2 hours, using a temperature programmed curing furnace (Model VF-2000, manufactured by Koyo Lindberg, Co., Ltd.) to obtain a cured film (polyimide film). The film thickness after the heat treatment was measured, and the obtained film thickness was defined as film thickness 2. Using these film thicknesses, the change in film thickness before and after the heat treatment was calculated using the following formula:

Film remaining ratio (%) before and after heat treatment=(film thickness 2/film thickness 1)×100, followed by evaluation based on the following criteria.
E: Excellent: film remaining ratio before and after a heat treatment is 95% or more
G: Good: film remaining ratio before and after a heat treatment is 90% or more and less than 95%
F: Fail: film remaining ratio before and after a heat treatment is less than 90%

### (8) Copper Adhesion

Ti having a thickness of 200 nm and Cu having a thickness of 400 nm were sputtered in this order on a 6-inch silicon wafer (manufactured by Fujimi Electronics Industry Co., Ltd., thickness of 625±25 m) using a sputtering device (Model L-440S-FHL, manufactured by Canon Anelva Corporation). Subsequently, a photosensitive resin composition prepared by the method described below was spin-coated on this wafer using a coater developer (model D-Spin60A, manufactured by SOKUDO Co., Ltd.), and prebaked on a hot plate at 110° C. for 180 seconds to form a coating film of the photosensitive resin composition on Cu. This coating film was irradiated with energy of 1,000 mJ/cm² using Prisma GHI (manufactured by Ultratech Co., Ltd.) without using a mask with a test pattern. Next, the wafer was subjected to a heat treatment in a nitrogen atmosphere at 230° C. for 2 hours, using a temperature programmed curing furnace (Model VF-2000, manufactured by Koyo Lindberg, Co., Ltd.) to obtain an about 8 m-thick cured film made of the resin composition on Cu. In accordance with JIS K 5600-5-6 standard cross-cut method, the adhesive properties between the copper substrate and the cured resin coating film of the heat-treated film were evaluated by the following criteria.
“G: Good”: the number of grids of the cured resin coating film adhered to the substrate is 100
“F: Fail”: the number of grids of the cured resin coating film adhered to the substrate is less than 100

### (8) Production of Cured Relief Pattern Used for Evaluation of Chemical Resistance

Ti having a thickness of 200 nm and Cu having a thickness of 400 nm were sputtered in this order on a 6-inch silicon wafer (manufactured by Fujimi Electronics Industry Co., Ltd., thickness of 625±25 m) using a sputtering device (Model L-440S-FHL, manufactured by Canon Anelva Corporation). Subsequently, a photosensitive resin composition prepared by the method described below was spin-coated on this wafer using a coater developer (model D-Spin60A, manufactured by SOKUDO Co., Ltd.), and prebaked on a hot plate at 110° C. for 180 seconds to form a coating film of the photosensitive resin composition. This coating film was irradiated with energy of 1,000 mJ/cm² by Prisma GHI (manufactured by Ultratech Co., Ltd.) without using a mask with a test pattern. Next, the wafer was subjected to a heat treatment in a nitrogen atmosphere at 230° C. for 2 hours, using a temperature programmed curing furnace (Model VF-2000, manufactured by Koyo Lindberg, Co., Ltd.) to obtain an about 8 μm-thick cured film made of the resin composition on Cu.

### (9) Chemical Resistance of Cured Relief Pattern (Polyimide Coating Film)

A cured film produced in accordance with “(8) Production of Cured Relief Pattern used for Evaluation of Chemical Resistance” was immersed in a standard TMAH solution {dimethyl sulfoxide (DMSO): 97.62% by mass, tetramethylammonium hydroxide pentahydrate (TMAH): 2.38% by mass} heated to 50° C. for 10 minutes. The cured film was then washed with running water for 30 minutes and air-dried. Thereafter, the film thickness was measured before and after immersion in the standard TMAH solution, and the chemical resistance was evaluated based on the amount of change in the resulting film thickness (amount dissolved) in accordance with the following criteria.
“E: Excellent”: amount of change in film thickness is less than 100 nm
“G: Good”: amount of change in film thickness is 100 nm or more and less than 200150 nm
“A: Average”: amount of change in film thickness is 200150 nm or more and less than 400 nm
“F: Fail”: amount of change in film thickness is 400 nm or more

Hereinafter, each abbreviation means the following compound name.
ODPA: 4,4′-Oxydiphthalic dianhydride
BPADA: 4,4′-(4,4′-Isopropylidenediphenoxy)diphthalic anhydride
PMDA: Pyromellitic anhydride
CpODA: Norbornane-2-spiro-α-cyclopentanone-α′-spiro-2″-norbornane-5,5″,6,6″-tetracarboxylic dianhydride
BCD: Bicyclo[2.2.2.]oct-7-ene-2,3,5,6-tetracarboxylic dianhydride
SFDA: Spiro[difuro[3,4-b:3′,4′i]xantene-11,9′-fluorene]-1,3,7,9-tetraone
BPAF: 4,4′-(9H-Fluorene-9,9-diyl)diphthalic anhydride
6FDA: 4,4′-(Hexafluoroisopropylidene)diphthalic anhydride
PDPE: 4,4′-Diamino-2-phenyldiphenyl ether
m-TB: 4,4′-Dimethylbiphenyl-4,4′-diamine
DADPE: 4,4′-Diaminodiphenyl ether
BAFL: 9,9-Bis(4-aminophenyl)fluorene
TFMB: 2,2′-Bis(trifluoromethyl) benzidine
HEMA: 2-Hydroxyethyl methacrylate
DCC: Dicyclohexylcarbodiimide
NMP: N-Methylpyrrolidone
GBL: γ-Butyrolactone

### <Synthesis Example 1> (Synthesis of (A) Polyimide A-1)

In a nitrogen-purged three-necked flask equipped with a Dean-Stark extraction apparatus, 200.0 g of NMP and 22.1 g (0.08 mol) of PDPE were added and dissolved. Then, 31.0 g (0.1 mol) of ODPA and 48.4 g of toluene were added thereto, followed by heating to 180° C.

After confirming that the theoretical amount of water (1.80 g) and the added toluene (48.4 g) were extracted in the Dean-Stark extraction apparatus, heating was stopped, followed by cooling to room temperature. Thereby, a reaction solution was obtained.

The reaction solution thus obtained was added to 800 g of ethyl alcohol, thereby producing a precipitate composed of a crude polymer. The crude polymer thus produced was filtered off and dissolved in 300 g of GBL to obtain a crude polymer solution. The crude polymer solution thus obtained was added dropwise in 3 kg of water to precipitate a polymer, followed by filtration of the resulting precipitate and further vacuum drying to obtain a powdered polymer (polyimide A-1). The molecular weight of the polyimide A-1 was measured by gel permeation chromatography (standard polystyrene conversion) and found that Mw was 13,600, and Mw/Mn was 1.54. The weighted average of the number of aromatic rings of a tetracarboxylic acid derivative used as a raw material was 2.0, as calculated by the following formula:

$$( Number of aromatic rings contained in ODPA [ 2 ] \times mixing amount of ODPA [ 31. ] ) / ( mixing amount of ODPA [ 31. ] ) = 2. .$$

### <Synthesis Example 2> (Synthesis of (A) Polyimide A-2)

In the same manner as in the method described in Synthesis Example 1, except that the amount of ODPA in Synthesis Example 1 was changed to 52.0 g of BPADA, the reaction was carried out to obtain a polyimide A-2. The molecular weight of the polyimide A-2 was measured by gel permeation chromatography (standard polystyrene conversion) and found that Mw was 15,200, and Mw/Mn was 1.58. The weighted average of the number of aromatic rings of a tetracarboxylic acid derivative used as a raw material was 4.0.

### <Synthesis Example 3> (Synthesis of (A) Polyimide A-3)

In the same manner as in the method described in Synthesis Example 1, except that the amount of ODPA in Synthesis Example 1 was changed to 10.9 g of PMDA and 15.5 g of ODPA, the reaction was carried out to obtain a polyimide A-3. The molecular weight of the polyimide A-3 was measured by gel permeation chromatography (standard polystyrene conversion) and found that Mw was 16,000, and Mw/Mn was 1.61. The weighted average of the number of aromatic rings of a tetracarboxylic acid derivative used as a raw material was 1.6, as calculated by the following formula: {(number of aromatic rings contained in PMDA [1]×mixing amount of PMDA [10.9])+(number of aromatic rings contained in ODPA [2]×mixing amount of PMDA [15.5])}/(mixing amount of PMDA [10.9]+mixing amount of ODPA [15.5])=1.61 1.6.

### <Synthesis Example 4> (Synthesis of (A) Polyimide A-4)

In the same manner as in the method described in Synthesis Example 1, except that the amount of ODPA in Synthesis Example 1 was changed to 10.9 g of PMDA and 19.2 g of CpODA described below, the reaction was carried out to obtain a polyimide A-4. The molecular weight of the polyimide A-4 was measured by gel permeation chromatography (standard polystyrene conversion) and found that Mw was 13,600, and Mw/Mn was 1.62. The weighted average of the number of aromatic rings of a tetracarboxylic acid derivative used as a raw material was 0.4.

### <Synthesis Example 5> (Synthesis of (A) Polyimide A-5)

In the same manner as in the method described in Synthesis Example 1, except that the amount of ODPA in Synthesis Example 1 was changed to 10.9 g of PMDA and 12.4 g of BCD, the reaction was carried out to obtain a polyimide A-5. The molecular weight of the polyimide A-5 was measured by gel permeation chromatography (standard polystyrene conversion) and found that Mw was 14,400, and Mw/Mn was 1.64. The weighted average of the number of aromatic rings of a tetracarboxylic acid derivative used as a raw material was 0.5.

### <Synthesis Example 6> (Synthesis of (A) Polyimide A-6)

In the same manner as in the method described in Synthesis Example 3, except that 22.1 g of PDPE in Synthesis Example 3 was changed to 18.4 g, the reaction was carried out to obtain a polyimide A-6. The molecular weight of the polyimide A-6 was measured by gel permeation chromatography (standard polystyrene conversion) and found that Mw was 9,300, and Mw/Mn was 1.40. The weighted average of the number of aromatic rings of a tetracarboxylic acid derivative used as a raw material was 1.6.

### <Synthesis Example 7> (Synthesis of (A) Polyimide A-7)

In the same manner as in the method described in Synthesis Example 3, except that 22.1 g of PDPE in Synthesis Example 3 was changed to 24.2 g, the reaction was carried out to obtain a polyimide A-7. The molecular weight of the polyimide A-7 was measured by gel permeation chromatography (standard polystyrene conversion) and found that Mw was 24,000, and Mw/Mn was 1.71. The weighted average of the number of aromatic rings of a tetracarboxylic acid derivative used as a raw material was 1.6.

### <Synthesis Example 8> (Synthesis of (A) Polyimide A-8)

In the same manner as in the method described in Synthesis Example 3, except that 22.1 g of PDPE in Synthesis Example 3 was changed to 25.1 g, the reaction was carried out to obtain a polyimide A-8. The molecular weight of the polyimide A-8 was measured by gel permeation chromatography (standard polystyrene conversion) and found that Mw was 32,000, and Mw/Mn was 1.75. The weighted average of the number of aromatic rings of a tetracarboxylic acid derivative used as a raw material was 1.6.

### <Synthesis Example 9> (Synthesis of (A) Polyimide A-9)

In the same manner as in the method described in Synthesis Example 3, except that 22.1 g of PDPE in Synthesis Example 3 was changed to 34.5 g, the reaction was carried out to obtain a polyimide A-9. The molecular weight of the polyimide A-9 was measured by gel permeation chromatography (standard polystyrene conversion) and found that Mw was 15,200, and Mw/Mn was 1.55. The weighted average of the number of aromatic rings of a tetracarboxylic acid derivative used as a raw material was 1.6.

### <Synthesis Example 10> (Synthesis of (A) Polyimide A-10)

In a nitrogen-purged three-necked flask equipped with a Dean-Stark extraction apparatus, 200 g of GBL and 22.1 g of PDPE were added and dissolved. Then, 10.9 g of PMDA, 15.5 g of ODPA and 48.4 g of toluene were added thereto, followed by heating to 180° C.

After confirming that the theoretical amount of water (1.80 g) and the added toluene (48.4 g) were extracted in the Dean-Stark extraction apparatus, heating was stopped, followed by cooling to room temperature.

Next, under ice-cooling, a solution prepared by dissolving 16.5 g of DCC in 16.5 g of GBL was added to the reaction mixture while stirring, and 10.4 g of HEMA was subsequently added. Further, 5.0 g of 4-dimethylaminopyridine was added, followed by stirring at room temperature. The precipitated produced in the reaction mixture was removed by filtration to obtain a reaction solution. Thereby, a reaction solution was obtained.

The reaction solution thus obtained was added to 500 g of ethyl alcohol, thereby producing a precipitate composed of a crude polymer. The crude polymer thus produced was filtered off and dissolved in 300 g of GBL to obtain a crude polymer solution. The crude polymer solution thus obtained was added dropwise in 3 kg of water to precipitate a polymer, followed by filtration of the resulting precipitate and further vacuum drying to obtain a powdered polymer (polyimide A-10). The molecular weight of the polyimide A-10 was measured by gel permeation chromatography (standard polystyrene conversion) and found that Mw was 16,800, and Mw/Mn was 1.63. The weighted average of the number of aromatic rings of a tetracarboxylic acid derivative used as a raw material was 1.6.

### <Synthesis Example 11> (Synthesis of (A) Polyimide A-11)

In a nitrogen-purged three-necked flask equipped with a Dean-Stark extraction apparatus, 200 g of GBL and 34.5 g of PDPE were added and dissolved. Then, 10.9 g of PMDA, 15.5 g of ODPA and 48.4 g of toluene were added thereto, followed by heating to 180° C.

After confirming that the theoretical amount of water (1.80 g) and the added toluene (48.4 g) were extracted in the Dean-Stark extraction apparatus, heating was stopped, followed by cooling to room temperature. Thereby, a reaction solution was obtained.

Next, 7.8 g of Karenz MOI (trade name; Showa Denko K.K.) was added to the reaction solution thus obtained, followed by stirring to obtain a polymer solution.

The polymer solution thus obtained was added to 500 g of ethyl alcohol, thereby producing a precipitate composed of a crude polymer. The crude polymer thus produced was filtered off and dissolved in 300 g of GBL to obtain a crude polymer solution. The crude polymer solution thus obtained was added dropwise in 3 kg of water to precipitate a polymer, followed by filtration of the resulting precipitate and further vacuum drying to obtain a powdered polymer (polyimide A-11). The molecular weight of the polyimide A-11 was measured by gel permeation chromatography (standard polystyrene conversion) and found that Mw was 16,000, and Mw/Mn was 1.66. The weighted average of the number of aromatic rings of a tetracarboxylic acid derivative used as a raw material was 1.6.

### <Synthesis Example 12> (Synthesis of (A) Polyimide A-12)

In the same manner as in the method described in Synthesis Example 3, except that 22.1 g of PDPE in Synthesis Example 3 was changed to 11.1 g of PDPE and 8.5 g of m-TB, the reaction was carried out to obtain a polyimide A-12. The molecular weight of the polyimide A-12 was measured by gel permeation chromatography (standard polystyrene conversion) and found that Mw was 14,400, and Mw/Mn was 1.58. The weighted average of the number of aromatic rings of a tetracarboxylic acid derivative used as a raw material was 1.6.

### <Synthesis Example 13> (Synthesis of (A) Polyimide A-13)

In the same manner as in the method mentioned in Synthesis Example 1, except that 22.1 g of PDPE in Synthesis Example 1 was changed to 29.5 g of 1,4-bis(4-aminophenoxy)-2-phenylbenzene, the reaction was carried out to obtain a polyimide A-13. The molecular weight of the polyimide A-13 was measured by gel permeation chromatography (standard polystyrene conversion) and found that Mw was 15,200, and Mw/Mn was 1.61. The weighted average of the number of aromatic rings of a tetracarboxylic acid derivative used as a raw material was 2.0.

### <Synthesis Example 14> (Synthesis of (A) Polyimide A-14)

In the same manner as in the method described in Synthesis Example 3, except that 22.1 g of PDPE in Synthesis Example 3 was changed to 29.5 g of 1,4-bis(4-aminophenoxy)-2-phenylbenzene, the reaction was carried out to obtain a polyimide A-14. The molecular weight of the polyimide A-14 was measured by gel permeation chromatography (standard polystyrene conversion) and found that Mw was 17,600, and Mw/Mn was 1.68. The weighted average of the number of aromatic rings of a tetracarboxylic acid derivative used as a raw material was 1.6.

### <Synthesis Example 15> (Synthesis of (A) Polyimide A-15)

In the same manner as in the method described in Synthesis Example 1, except that 22.1 g of PDPE in Synthesis Example 1 was changed to 16.0 g of 2-phenoxybenzene-1,4-diamine, the reaction was carried out to obtain a polyimide A-15. The molecular weight of the polyimide A-15 was measured by gel permeation chromatography (standard polystyrene conversion) and found that Mw was 13,200, and Mw/Mn was 1.56. The weighted average of the number of aromatic rings of a tetracarboxylic acid derivative used as a raw material was 2.0.

### <Synthesis Example 16> (Synthesis of (A) Polyimide A-16)

In the same manner as in the method described in Synthesis Example 1, except that 22.1 g of PDPE in Synthesis Example 1 was changed to 41.7 g of 3,3′-diphenyl-4,4′-bis(4-aminophenoxy)biphenyl, the reaction was carried out to obtain a polyimide A-16. The molecular weight of the polyimide A-16 was measured by gel permeation chromatography (standard polystyrene conversion) and found that Mw was 16,800, and Mw/Mn was 1.66. The weighted average of the number of aromatic rings of a tetracarboxylic acid derivative used as a raw material was 2.0.

### <Synthesis Example 17> (Synthesis of (A) Polyimide A-17)

In the same manner as in the method described in Synthesis Example 1, except that 22.1 g of PDPE in Synthesis Example 1 was changed to 45.0 g of 2,2′-bis[3-phenyl-4-(4-aminophenoxy)phenyl]propane, the reaction was carried out to obtain a polyimide A-17. The molecular weight of the polyimide A-17 was measured by gel permeation chromatography (standard polystyrene conversion) and found that Mw was 17,200, and Mw/Mn was 1.63. The weighted average of the number of aromatic rings of a tetracarboxylic acid derivative used as a raw material was 2.0.

### <Synthesis Example 18> (Synthesis of (A) Polyimide A-18)

In the same manner as in the method described in Synthesis Example 1, except that 22.1 g of PDPE in Synthesis Example 1 was changed to 22.0 g of 4,4′-diaminotriphenylamine, the reaction was carried out to obtain a polyimide A-18. The molecular weight of the polyimide resin A-18 was measured by gel permeation chromatography (standard polystyrene conversion) and found that Mw was 14,000, and Mw/Mn was 1.56. The weighted average of the number of aromatic rings of a tetracarboxylic acid derivative used as a raw material was 2.0.

### <Synthesis Example 19> (Synthesis of (A) Polyimide A-19)

In the same manner as in the method described in Synthesis Example 1, except that 22.1 g of PDPE in Synthesis Example 1 was changed to 27.4 g of 1,4-bis(4-aminophenoxy)naphthalene, the reaction was carried out to obtain a polyimide A-19. The molecular weight of the polyimide A-19 was measured by gel permeation chromatography (standard polystyrene conversion) and found that Mw was 12,800, and Mw/Mn was 1.54. The weighted average of the number of aromatic rings of a tetracarboxylic acid derivative used as a raw material was 2.0.

### <Synthesis Example 20> (Synthesis of (A) Polyimide A-20)

In the same manner as in the method described in Synthesis Example 1, except that 22.1 g of PDPE in Synthesis Example 1 was changed to 16.0 g of DADPE and 31.0 g of ODPA was changed to 34.0 g of RIKACID TDA-100 (manufactured by New Japan Chemical Co., Ltd.), the reaction was carried out to obtain a polyimide A-20. The molecular weight of the polyimide A-20 was measured by gel permeation chromatography (standard polystyrene conversion) and found that Mw was 13,600, and Mw/Mn was 1.56. The weighted average of the number of aromatic rings of a tetracarboxylic acid derivative used as a raw material was 1.0.

### <Synthesis Example 21> (Synthesis of (A) Polyimide A-21)

In the same manner as in the method mentioned in Synthesis Example 5, except that 10.9 g of PMDA in Synthesis Example 5 was changed to 15.5 g of ODPA, the reaction was carried out to obtain a polyimide A-21. The molecular weight of the polyimide A-21 was measured by gel permeation chromatography (standard polystyrene conversion) and found that Mw was 15,200, and Mw/Mn was 1.67. The weighted average of the number of aromatic rings of a tetracarboxylic acid derivative used as a raw material was 1.1.

### <Synthesis Example 22> (Synthesis of (A) Polyimide A-22)

In the same manner as in the method mentioned in Synthesis Example 11, except that 34.5 g of PDPE in Synthesis Example 11 was changed to 33.2 g and 15.5 g of ODPA was changed to 12.4 g of BCD, the reaction was carried out to obtain a polyimide A-22. The molecular weight of the polyimide A-22 was measured by gel permeation chromatography (standard polystyrene conversion) and found that Mw was 17,600, and Mw/Mn was 1.55. The weighted average of the number of aromatic rings of a tetracarboxylic acid derivative used as a raw material was 0.5.

### <Synthesis Example 23> (Synthesis of (A) Polyimide A-23)

In the same manner as in the method described in Synthesis Example 1, except that 31.0 g of ODPA in Synthesis Example 1 was changed to 47.2 g of SFDA, the reaction was carried out to obtain a polyimide A-23. The molecular weight of the polyimide A-23 was measured by gel permeation chromatography (standard polystyrene conversion) and found that Mw was 16,000, and Mw/Mn was 1.61. The weighted average of the number of aromatic rings of a tetracarboxylic acid derivative used as a raw material was 4.0.

### <Synthesis Example 24> (Synthesis of (A) Polyimide A-24)

In the same manner as in the method described in Synthesis Example 1, except that 31.0 g of ODPA in Synthesis Example 1 was changed to 45.8 g of BPAF, the reaction was carried out to obtain a polyimide A-24. The molecular weight of the polyimide A-24 was measured by gel permeation chromatography (standard polystyrene conversion) and found that Mw was 14,400, and Mw/Mn was 1.57. The weighted average of the number of aromatic rings of a tetracarboxylic acid derivative used as a raw material was 4.0.

### <Synthesis Example 25> (Synthesis of (A) Polyimide A-24)

In the same manner as in the method described in Synthesis Example 1, except that 22.1 g of PDPE in Synthesis Example 1 was changed to 27.9 g of BAFL, the reaction was carried out to obtain a polyimide A-25. The molecular weight of the polyimide A-25 was measured by gel permeation chromatography (standard polystyrene conversion) and found that Mw was 15,200, and Mw/Mn was 1.66. The weighted average of the number of aromatic rings of a tetracarboxylic acid derivative used as a raw material was 2.0.

### <Synthesis Example 26> (Synthesis of (A′) Polyimide A′-1)

In the same manner as in the method described in Synthesis Example 1, except that 22.1 g of PDPE in Synthesis Example 1 was changed to 16.0 g of DADPE, the reaction was carried out to obtain a polyimide A′-1. Haze was observed in the resulting polymer solution. The molecular weight of the polyimide A′-1 was measured by gel permeation chromatography (standard polystyrene conversion) and found that Mw was 12,800, and Mw/Mn was 1.55. The weighted average of the number of aromatic rings of a tetracarboxylic acid derivative used as a raw material was 2.0.

### <Synthesis Example 27> (Synthesis of (A′) Polyimide A′-2)

In the same manner as in the method described in Synthesis Example 3, except that 22.1 g of PDPE in Synthesis Example 3 was changed to 16.0 g of DADPE, the reaction was carried out. During the synthesis, a gel-like precipitate was produced, and the precipitate was insoluble (Polyimide A′-2). Due to the insolubility of the precipitate, gel permeation chromatography (standard polystyrene conversion) could not be carried out. The weighted average of the number of aromatic rings of a tetracarboxylic acid derivative used as a raw material was 1.6.

### <Synthesis Example 28> (Synthesis of (A′) Polyimide A′-3)

In the same manner as in the method described in Synthesis Example 3, except that 22.1 g of PDPE in Synthesis Example 3 was changed to 17.0 g of m-TB, the reaction was carried out. During the synthesis, a gel-like precipitate was produced, and the precipitate was insoluble (Polyimide A′-3). Due to the insolubility of the precipitate, gel permeation chromatography (standard polystyrene conversion) could not be carried out. The weighted average of the number of aromatic rings of a tetracarboxylic acid derivative used as a raw material was 1.6.

### <Synthesis Example 29> (Synthesis of (A′) Polyimide A′-4)

In the same manner as in the method described in Synthesis Example 3, except that 22.1 g of PDPE in Synthesis Example 3 was changed to 25.6 g of TFMB, the reaction was carried out to obtain a polyimide A′-4. The molecular weight of the polyimide A′-4 was measured by gel permeation chromatography (standard polystyrene conversion) and found that Mw was 14,000, and Mw/Mn was 1.58. The weighted average of the number of aromatic rings of a tetracarboxylic acid derivative used as a raw material was 1.6.

### <Synthesis Example 30> (Synthesis of (A) Polyimide A′-5)

In the same manner as in the method described in Synthesis Example 26, except that 31.0 g of ODPA in Synthesis Example 26 was changed to 44.4 g of 6FDA, the reaction was carried out to obtain a polyimide A′-5. The molecular weight of the polyimide A′-5 was measured by gel permeation chromatography (standard polystyrene conversion) and found that Mw was 15,200, and Mw/Mn was 1.62. The weighted average of the number of aromatic rings of a tetracarboxylic acid derivative used as a raw material was 2.0.

### <Synthesis Example 31> (Synthesis of (A) Polyimide A′-6)

In the same manner as in the method described in Synthesis Example 26, except that 16.0 g of DADPE in Synthesis Example 26 was changed to 10.0 g, the reaction was carried out to obtain a polyimide A′-6. The molecular weight of the polyimide A′-6 was measured by gel permeation chromatography (standard polystyrene conversion) and found that Mw was 4,350, and Mw/Mn was 1.31. The weighted average of the number of aromatic rings of a tetracarboxylic acid derivative used as a raw material was 2.0.

### <Synthesis Example 32> (Synthesis of (A) Polyimide Precursor A′-7)

In a 1 L separable flask, 31.0 g (0.1 mol) of ODPA was charged, and 80 g of GBL was further added. Next, 27.1 g of HEMA was added, and then 15.8 g of pyridine was added while stirring, followed by stirring using an oil bath at 40° C. for 5 hours, thereby obtaining a reaction mixture. After completion of the reaction, the reaction mixture was allowed to cool to room temperature and then left to stand for 16 hours.

Next, while stirring the reaction mixture after standing, a solution prepared by dissolving 41 g of DCC in 41 g of GBL was added over 40 minutes under ice-cooling, and then a suspension prepared by suspending 22.1 g (0.08 mol) of PDPE in 70 g of GBL was added over 60 minutes. After stirring at room temperature for 2 hours, 10 g of ethyl alcohol was added, followed by stirring for additional 1 hour and further addition of 150 g of GBL. The reaction mixture was filtered to remove the precipitate produced in the reaction system, thereby obtaining a reaction solution.

The reaction solution thus obtained was added to 1.2 kg of ethyl alcohol, thereby precipitating a crude polymer. The precipitated crude polymer was collected by filtration and dissolved in 300 g of GBL to obtain a crude polymer solution. The crude polymer solution thus obtained was added dropwise in 3.0 kg of water to reprecipitate a polymer. The resulting reprecipitate was collected by filtration and then vacuum-dried to obtain a powdered polymer (Polymer A′-7). The molecular weight of the polyimide A′-7 was measured by gel permeation chromatography (standard polystyrene conversion) and found that Mw was 14,000, and Mw/Mn was 1.55. The weighted average of the number of aromatic rings of a tetracarboxylic acid derivative used as a raw material was 2.0.

### <<Preparation of Resin Composition>>

### Examples 1 to 37 and Comparative Examples 1 to 7

(A) a polyimide, (B) a solvent, (C) a photopolymerization initiator, (D) a radical polymerizable compound, (E) a silane coupling agent, (F) a rust inhibitor, (G) an organic titanium compound, (H) a plasticizer, (I) a thermal crosslinking agent, and (J) a thermal polymerization initiator were mixed in the mixing amounts shown in the table below to prepare a resin composition solution. The mixing amounts in the table below are parts by mass of each component when the component (A) is taken as 100 parts by mass. The solution thus obtained was filtered through a polyethylene filter having pores of 0.2 m, thereby obtaining the resin compositions of Examples 1 to 37 and Comparative Examples 1 to 7. The symbols in the table represent the following components. The composition was evaluated according to the methods described above, and the results are shown in the table below.
(B-1): γ-Butyllactone
(B-2): Dimethyl sulfoxide
(B-3): N-Methylpyrrolidone
(B-4): 3-Methoxy-N,N-dimethylpropaneamide
(C-1): PBG-3057 (trade name, manufactured by Changzhou Tronly New Electronic Materials Co., Ltd.)
(C-2): Irugacure OXE02 (trade name, manufactured by BASF Japan Ltd.)
(C-3): 1-Phenyl-1,2-propanedione-2-(o-benzoyl)oxime
(C-4): N-Phenyldiethanolamine
(D-1): Tris-(2-acryloxyethyl)isocyanurate
(D-2): Tetraethylene glycol dimethacrylate
(D-3): A-DPH (trade name, manufactured by SHIN-NAKAMURA CHEMICAL CO., LTD.; dipentaerythritol polyacrylate)
(D-4): Dicyclopentanyl acrylate
(E-1): N-Phenyl-3-aminopropyltrimethoxysilane
(E-2): 2-(3,4-Epoxycyclohexyl)ethyltrimethoxysilane
(F-1): 8-Azaadenin
(F-2): 5-Amino-1H-tetrazole
(G-1): Diisopropoxytitanium bis(ethyl acetate)
(H-1): P-toluenesulfonamide
(I-1): 1,3,4,6-Tetrakis(methoxymethyl)glycoluril
(I-2): 1,3-Bis(methoxymethyl)urea
(J-1): PERCUMYL D (trade name, manufactured by NOF CORPORATION)

TABLE 4

| | Exam- | Exam- | Exam- | Exam- | Exam- | Exam- | Exam- | Exam- | Exam- | Exam- |
|---|---|---|---|---|---|---|---|---|---|---|
| Lot | ple 1 | ple 2 | ple 3 | ple 4 | ple 5 | ple 6 | ple 7 | ple 8 | ple 9 | ple 10 |
| A-1 | 100 | | | | | | | | | |
| A-2 | | 100 | | | | | | | | |
| A-3 | | | 100 | | | | | | | |
| A-4 | | | | 100 | | | | | | |
| A-5 | | | | | 100 | | | | | |
| A-6 | | | | | | 100 | | | | |
| A-7 | | | | | | | 100 | | | |
| A-8 | | | | | | | | 100 | | |
| A-9 | | | | | | | | | 100 | |
| A-10 | | | | | | | | | | 100 |
| A-11 | | | | | | | | | | |
| A-12 | | | | | | | | | | |
| A-13 | | | | | | | | | | |
| A-14 | | | | | | | | | | |
| A-15 | | | | | | | | | | |
| A-16 | | | | | | | | | | |
| A-17 | | | | | | | | | | |
| A-18 | | | | | | | | | | |
| A-19 | | | | | | | | | | |
| A-20 | | | | | | | | | | |
| A-21 | | | | | | | | | | |
| A-22 | | | | | | | | | | |
| A-23 | | | | | | | | | | |
| A-24 | | | | | | | | | | |
| A-25 | | | | | | | | | | |
| A′-1 | | | | | | | | | | |
| A′-2 | | | | | | | | | | |
| A′-3 | | | | | | | | | | |
| A′-4 | | | | | | | | | | |
| A′-5 | | | | | | | | | | |
| A′-6 | | | | | | | | | | |
| A′-7 | | | | | | | | | | |
| B-1 | 112 | 112 | 112 | 112 | 112 | 112 | 112 | 112 | 112 | 112 |
| B-2 | 28 | 28 | 28 | 28 | 28 | 28 | 28 | 28 | 28 | 28 |
| B-3 | | | | | | | | | | |
| B-4 | | | | | | | | | | |
| C-1 | 5 | 5 | 5 | 5 | 5 | 5 | 5 | 5 | 5 | 5 |
| C-2 | | | | | | | | | | |
| C-3 | | | | | | | | | | |
| C-4 | | | | | | | | | | |
| D-1 | 25 | 25 | 25 | 25 | 25 | 25 | 25 | 25 | 25 | 25 |
| D-2 | 25 | 25 | 25 | 25 | 25 | 25 | 25 | 25 | 25 | 25 |
| D-3 | | | | | | | | | | |
| D-4 | | | | | | | | | | |
| E-1 | 1 | 1 | 1 | 1 | 1 | 1 | 1 | 1 | 1 | 1 |
| E-2 | | | | | | | | | | |
| F-1 | 0.5 | 0.5 | 0.5 | 0.5 | 0.5 | 0.5 | 0.5 | 0.5 | 0.5 | 0.5 |
| F-2 | | | | | | | | | | |
| G-1 | 1 | 1 | 1 | 1 | 1 | 1 | 1 | 1 | 1 | 1 |
| H-1 | | | | | | | | | | |
| I-1 | | | | | | | | | | |
| I-2 | | | | | | | | | | |
| J-1 | | | | | | | | | | |
| Solubility | G: Good | G: Good | G: Good | G: Good | G: Good | G: Good | G: Good | A: | G: Good | G: Good |
| | | | | | | | | Average | | |
| Breaking | G: Good | G: Good | G: Good | G: Good | G: Good | G: Good | E: | A: | G: Good | E: |
| elongation | | | | | | | Excellent | Average | | Excellent |
| Copper migration | G: Good | G: Good | G: Good | G: Good | G: Good | G: Good | G: Good | G: Good | G: Good | G: Good |
| Change in film | G: Good | G: Good | G: Good | G: Good | G: Good | G: Good | G: Good | G: Good | G: Good | G: Good |
| thickness before | | | | | | | | | | |
| and after curing | | | | | | | | | | |
| Copper adhesion | G: Good | G: Good | G: Good | G: Good | G: Good | G: Good | G: Good | G: Good | G: Good | G: Good |
| Chemical | G: Good | A: | G: Good | G: Good | G: Good | A: | G: Good | E: | G: Good | E: |
| resistance | | Average | | | | Average | | Excellent | | Excellent |
| Flatness of | G: Good | G: Good | G: Good | G: Good | G: Good | E: | A: | F: Fail | G: Good | G: Good |
| prebaked film | | | | | | Excellent | Average | | | |

| | Exam- | Exam- | Exam- | Exam- | Exam- | Exam- | Exam- | Exam- | Exam- |
|---|---|---|---|---|---|---|---|---|---|
| Lot | ple 11 | ple 12 | ple 13 | ple 14 | ple 15 | ple 16 | ple 17 | ple 18 | ple 19 |
| A-1 | | | | | | | | | |
| A-2 | | | | | | | | | |
| A-3 | | 100 | 100 | 100 | 100 | 100 | 100 | 100 | 100 |
| A-4 | | | | | | | | | |
| A-5 | | | | | | | | | |
| A-6 | | | | | | | | | |
| A-7 | | | | | | | | | |
| A-8 | | | | | | | | | |
| A-9 | | | | | | | | | |
| A-10 | | | | | | | | | |
| A-11 | 100 | | | | | | | | |
| A-12 | | | | | | | | | |
| A-13 | | | | | | | | | |
| A-14 | | | | | | | | | |
| A-15 | | | | | | | | | |
| A-16 | | | | | | | | | |
| A-17 | | | | | | | | | |
| A-18 | | | | | | | | | |
| A-19 | | | | | | | | | |
| A-20 | | | | | | | | | |
| A-21 | | | | | | | | | |
| A-22 | | | | | | | | | |
| A-23 | | | | | | | | | |
| A-24 | | | | | | | | | |
| A-25 | | | | | | | | | |
| A′-1 | | | | | | | | | |
| A′-2 | | | | | | | | | |
| A′-3 | | | | | | | | | |
| A′-4 | | | | | | | | | |
| A′-5 | | | | | | | | | |
| A′-6 | | | | | | | | | |
| A′-7 | | | | | | | | | |
| B-1 | 112 | 112 | 112 | 112 | 112 | | | 112 | 112 |
| B-2 | 28 | 28 | 28 | 28 | 28 | | | 28 | 28 |
| B-3 | | | | | | 140 | | | |
| B-4 | | | | | | | 140 | | |
| C-1 | 5 | 5 | 5 | 5 | 5 | 5 | 5 | | |
| C-2 | | | | | | | | 5 | |
| C-3 | | | | | | | | | 5 |
| C-4 | | | | | | | | | 10 |
| D-1 | 25 | 25 | 25 | 25 | 25 | 25 | 25 | 25 | 25 |
| D-2 | 25 | 25 | 25 | 25 | 25 | 25 | 25 | 25 | 25 |
| D-3 | | | | | | | | | |
| D-4 | | | | | | | | | |
| E-1 | 1 | 1 | 1 | 1 | 1 | 1 | 1 | 1 | 1 |
| E-2 | | | | | | | | | |
| F-1 | 0.5 | 0.5 | 0.5 | 0.5 | 0.5 | 0.5 | 0.5 | 0.5 | 0.5 |
| F-2 | | | | | | | | | |
| G-1 | 1 | 1 | 1 | 1 | 1 | 1 | 1 | 1 | 1 |
| H-1 | | | | | 5 | | | | |
| I-1 | | 10 | | | | | | | |
| I-2 | | | 10 | | | | | | |
| J-1 | | | | 5 | | | | | |
| Solubility | G: Good | G: Good | G: Good | G: Good | G: Good | G: Good | G: Good | G: Good | G: Good |
| Breaking | E: | E: | E: | G: Good | G: Good | G: Good | G: Good | G: Good | G: Good |
| elongation | Excellent | Excellent | Excellent | | | | | | |
| Copper migration | G: Good | G: Good | G: Good | G: Good | G: Good | G: Good | G: Good | G: Good | G: Good |
| Change in film | G: Good | E: | E: | E: | G: Good | G: Good | G: Good | G: Good | G: Good |
| thickness before | | Excellent | Excellent | Excellent | | | | | |
| and after curing | | | | | | | | | |
| Copper adhesion | G: Good | G: Good | G: Good | G: Good | G: Good | G: Good | G: Good | G: Good | G: Good |
| Chemical | E: | E: | E: | E: | G: Good | G: Good | G: Good | G: Good | G: Good |
| resistance | Excellent | Excellent | Excellent | Excellent | | | | | |
| Flatness of | G: Good | G: Good | G: Good | G: Good | E: | E: | E: | G: Good | G: Good |
| prebaked film | | | | | Excellent | Excellent | Excellent | | |

TABLE 5

| | Exam- | Exam- | Exam- | Exam- | Exam- | Exam- | Exam- |
|---|---|---|---|---|---|---|---|
| Lot | ple 20 | ple 21 | ple 22 | ple 23 | ple 24 | ple 25 | ple 26 |
| A-1 | | | | | | | |
| A-2 | | | | | | | |
| A-3 | 100 | 100 | 100 | | | | |
| A-4 | | | | | | | |
| A-5 | | | | | | | |
| A-6 | | | | | | | |
| A-7 | | | | | | | |
| A-8 | | | | | | | |
| A-9 | | | | | | | |
| A-10 | | | | | | | |
| A-11 | | | | | | | |
| A-12 | | | | 100 | | | |
| A-13 | | | | | 100 | | |
| A-14 | | | | | | 100 | |
| A-15 | | | | | | | 100 |
| A-16 | | | | | | | |
| A-17 | | | | | | | |
| A-18 | | | | | | | |
| A-19 | | | | | | | |
| A-20 | | | | | | | |
| A-21 | | | | | | | |
| A-22 | | | | | | | |
| A-23 | | | | | | | |
| A-24 | | | | | | | |
| A-25 | | | | | | | |
| A′-1 | | | | | | | |
| A′-2 | | | | | | | |
| A′-3 | | | | | | | |
| A′-4 | | | | | | | |
| A′-5 | | | | | | | |
| A′-6 | | | | | | | |
| A′-7 | | | | | | | |
| B-1 | 112 | 112 | 112 | 112 | 112 | 112 | 112 |
| B-2 | 28 | 28 | 28 | 28 | 28 | 28 | 28 |
| B-3 | | | | | | | |
| B-4 | | | | | | | |
| C-1 | 5 | 5 | 5 | 5 | 5 | 5 | 5 |
| C-2 | | | | | | | |
| C-3 | | | | | | | |
| C-4 | | | | | | | |
| D-1 | 25 | 25 | 25 | 25 | 25 | 25 | 25 |
| D-2 | | 25 | 25 | 25 | 25 | 25 | 25 |
| D-3 | 25 | | | | | | |
| D-4 | | | | | | | |
| E-1 | 1 | 1 | | 1 | 1 | 1 | 1 |
| E-2 | | | 1 | | | | |
| F-1 | 0.5 | | 0.5 | 0.5 | 0.5 | 0.5 | 0.5 |
| F-2 | | 0.5 | | | | | |
| G-1 | 1 | 1 | 1 | 1 | 1 | 1 | 1 |
| H-1 | | | | | | | |
| I-1 | | | | | | | |
| I-2 | | | | | | | |
| J-1 | | | | | | | |
| Solubility | G: Good | G: Good | G: Good | G: Good | G: Good | G: Good | G: Good |
| Breaking | G: Good | G: Good | G: Good | G: Good | E: | E: | G: Good |
| elongation | | | | | Excellent | Excellent | |
| Copper migration | G: Good | G: Good | G: Good | G: Good | G: Good | G: Good | G: Good |
| Change in film | G: Good | G: Good | G: Good | G: Good | G: Good | G: Good | G: Good |
| thickness before | | | | | | | |
| and after curing | | | | | | | |
| Copper adhesion | G: Good | G: Good | G: Good | G: Good | G: Good | G: Good | G: Good |
| Chemical | G: Good | G: Good | G: Good | G: Good | A: | A: | G: Good |
| resistance | | | | | Average | Average | |
| Flatness of | G: Good | G: Good | G: Good | A: | E: | E: | A: |
| prebaked film | | | | Average | Excellent | Excellent | Average |

| | Exam- | Exam- | Exam- | Exam- | Exam- | Exam- |
|---|---|---|---|---|---|---|
| Lot | ple 27 | ple 28 | ple 29 | ple 30 | ple 31 | ple 32 |
| A-1 | | | | | | |
| A-2 | | | | | | |
| A-3 | | | | | | |
| A-4 | | | | | | |
| A-5 | | | | | | |
| A-6 | | | | | | |
| A-7 | | | | | | |
| A-8 | | | | | | |
| A-9 | | | | | | |
| A-10 | | | | | | |
| A-11 | | | | | | |
| A-12 | | | | | | |
| A-13 | | | | | | |
| A-14 | | | | | | |
| A-15 | | | | | | |
| A-16 | 100 | | | | | |
| A-17 | | 100 | | | | |
| A-18 | | | 100 | | | |
| A-19 | | | | 100 | | |
| A-20 | | | | | 100 | |
| A-21 | | | | | | 100 |
| A-22 | | | | | | |
| A-23 | | | | | | |
| A-24 | | | | | | |
| A-25 | | | | | | |
| A′-1 | | | | | | |
| A′-2 | | | | | | |
| A′-3 | | | | | | |
| A′-4 | | | | | | |
| A′-5 | | | | | | |
| A′-6 | | | | | | |
| A′-7 | | | | | | |
| B-1 | 112 | 112 | 112 | 112 | 112 | 112 |
| B-2 | 28 | 28 | 28 | 28 | 28 | 28 |
| B-3 | | | | | | |
| B-4 | | | | | | |
| C-1 | 5 | 5 | 5 | 5 | 5 | 5 |
| C-2 | | | | | | |
| C-3 | | | | | | |
| C-4 | | | | | | |
| D-1 | 25 | 25 | 25 | 25 | 25 | 25 |
| D-2 | 25 | 25 | 25 | 25 | 25 | 25 |
| D-3 | | | | | | |
| D-4 | | | | | | |
| E-1 | 1 | 1 | 1 | 1 | 1 | 1 |
| E-2 | | | | | | |
| F-1 | 0.5 | 0.5 | 0.5 | 0.5 | 0.5 | 0.5 |
| F-2 | | | | | | |
| G-1 | 1 | 1 | 1 | 1 | 1 | 1 |
| H-1 | | | | | | |
| I-1 | | | | | | |
| I-2 | | | | | | |
| J-1 | | | | | | |
| Solubility | G: Good | G: Good | G: Good | A: | G: Good | G: Good |
| | | | | Average | | |
| Breaking | E: | E: | G: Good | A: | A: | G: Good |
| elongation | Excellent | Excellent | | Average | Average | |
| Copper migration | G: Good | G: Good | G: Good | G: Good | G: Good | G: Good |
| Change in film | G: Good | G: Good | G: Good | G: Good | G: Good | G: Good |
| thickness before | | | | | | |
| and after curing | | | | | | |
| Copper adhesion | G: Good | G: Good | G: Good | G: Good | G: Good | G: Good |
| Chemical | A: | A: | A: | G: Good | G: Good | G: Good |
| resistance | Average | Average | Average | | | |
| Flatness of | E: | E: | G: Good | A: | A: | G: Good |
| prebaked film | Excellent | Excellent | | Average | Average | |

TABLE 6

| | | | | | | Compar- |
|---|---|---|---|---|---|---|
| | Exam- | Exam- | Exam- | Exam- | Exam- | ative |
| Lot | ple 33 | ple 34 | ple 35 | ple 36 | ple 37 | Example 1 |
| A-1 | | | | | | |
| A-2 | | | | | | |
| A-3 | | | | | | |
| A-4 | | | | | | |
| A-5 | | | | | | |
| A-6 | | | | | | |
| A-7 | | | | | | |
| A-8 | | | | | | |
| A-9 | | | | | | |
| A-10 | | | | | | |
| A-11 | | | | | | |
| A-12 | | | | | | |
| A-13 | | | | | | |
| A-14 | | | | | | |
| A-15 | | | | | | |
| A-16 | | | | | | |
| A-17 | | | | | | |
| A-18 | | | | | | |
| A-19 | | | | | | |
| A-20 | | | | | | |
| A-21 | | | | | | |
| A-22 | 100 | 100 | | | | |
| A-23 | | | 100 | | | |
| A-24 | | | | 100 | | |
| A-25 | | | | | 100 | |
| A′-1 | | | | | | 100 |
| A′-2 | | | | | | |
| A′-3 | | | | | | |
| A′-4 | | | | | | |
| A′-5 | | | | | | |
| A′-6 | | | | | | |
| A′-7 | | | | | | |
| B-1 | 112 | 112 | 112 | 112 | 112 | 112 |
| B-2 | 28 | 28 | 28 | 28 | 28 | 28 |
| B-3 | | | | | | |
| B-4 | | | | | | |
| C-1 | 5 | 5 | 5 | 5 | 5 | 5 |
| C-2 | | | | | | |
| C-3 | | | | | | |
| C-4 | | | | | | |
| D-1 | 20 | 5 | 25 | 25 | 25 | 25 |
| D-2 | | | 25 | 25 | 25 | 25 |
| D-3 | | | | | | |
| D-4 | 40 | 50 | | | | |
| E-1 | 1 | 1 | 1 | 1 | 1 | 1 |
| E-2 | | | | | | |
| F-1 | 0.5 | 0.5 | 0.5 | 0.5 | 0.5 | 0.5 |
| F-2 | | | | | | |
| G-1 | 1 | 1 | 1 | 1 | 1 | 1 |
| H-1 | | | | | | |
| I-1 | | | | | | |
| I-2 | | | | | | |
| J-1 | | | | | | |
| Solubility | G: Good | G: Good | G: Good | G: Good | G: Good | F: Fail |
| Breaking | E: | E: | A: | A: | A: | — |
| elongation | Excellent | Excellent | Average | Average | Average | |
| Copper migration | G: Good | G: Good | G: Good | G: Good | G: Good | — |
| Change in film | G: Good | G: Good | G: Good | G: Good | G: Good | — |
| thickness before | | | | | | |
| and after curing | | | | | | |
| Copper adhesion | G: Good | G: Good | G: Good | G: Good | G: Good | — |
| Chemical | G: Good | A: | A: | A: | G: Good | — |
| resistance | | Average | Average | Average | | |
| Flatness of | G: Good | G: Good | G: Good | G: Good | G: Good | — |
| prebaked film | | | | | | |
| | Compar- | Compar- | Compar- | Compar- | Compar- | Compar- |
| | ative | ative | ative | ative | ative | ative |
| Lot | Example 2 | Example 3 | Example 4 | Example 5 | Example 6 | Example 7 |
| A-1 | | | | | | |
| A-2 | | | | | | |
| A-3 | | | | | | |
| A-4 | | | | | | |
| A-5 | | | | | | |
| A-6 | | | | | | |
| A-7 | | | | | | |
| A-8 | | | | | | |
| A-9 | | | | | | |
| A-10 | | | | | | |
| A-11 | | | | | | |
| A-12 | | | | | | |
| A-13 | | | | | | |
| A-14 | | | | | | |
| A-15 | | | | | | |
| A-16 | | | | | | |
| A-17 | | | | | | |
| A-18 | | | | | | |
| A-19 | | | | | | |
| A-20 | | | | | | |
| A-21 | | | | | | |
| A-22 | | | | | | |
| A-23 | | | | | | |
| A-24 | | | | | | |
| A-25 | | | | | | |
| A′-1 | | | | | | |
| A′-2 | 100 | | | | | |
| A′-3 | | 100 | | | | |
| A′-4 | | | 100 | | | |
| A′-5 | | | | 100 | | |
| A′-6 | | | | | 100 | |
| A′-7 | | | | | | 100 |
| B-1 | 112 | 112 | 112 | 112 | 112 | 112 |
| B-2 | 28 | 28 | 28 | 28 | 28 | 28 |
| B-3 | | | | | | |
| B-4 | | | | | | |
| C-1 | 5 | 5 | 5 | 5 | 5 | 5 |
| C-2 | | | | | | |
| C-3 | | | | | | |
| C-4 | | | | | | |
| D-1 | 25 | 25 | 25 | 25 | 25 | 25 |
| D-2 | 25 | 25 | 25 | 25 | 25 | 25 |
| D-3 | | | | | | |
| D-4 | | | | | | |
| E-1 | 1 | 1 | 1 | 1 | 1 | 1 |
| E-2 | | | | | | |
| F-1 | 0.5 | 0.5 | 0.5 | 0.5 | 0.5 | 0.5 |
| F-2 | | | | | | |
| G-1 | 1 | 1 | 1 | 1 | 1 | 1 |
| H-1 | | | | | | |
| I-1 | | | | | | |
| I-2 | | | | | | |
| J-1 | | | | | | |
| Solubility | F: Fail | F: Fail | G: Good | G: Good | G: Good | G: Good |
| Breaking | — | — | A: | A: | F: Fail | G: Good |
| elongation | | | Average | Average | | |
| Copper migration | — | — | F: Fail | F: Fail | G: Good | G: Good |
| Change in film | — | — | G: Good | G: Good | G: Good | F: Fail |
| thickness before | | | | | | |
| and after curing | | | | | | |
| Copper adhesion | — | — | G: Good | G: Good | G: Good | F: Fail |
| Chemical | — | — | A: | A: | F: Fail | G: Good |
| resistance | | | Average | Average | | |
| Flatness of | — | — | A: | A: | E: | E: |
| prebaked film | | | Average | Average | Excellent | Excellent |

It can be seen that Examples have higher solubility as compared with Comparative Examples 1 to 3. In Comparative Examples 1 to 3, the polymer was insoluble in the solvent, thus failing to obtain a photosensitive resin composition, and therefore each evaluation was not carried out.

Since the polymers of the present Example have high solubility, the high molecular weight substance can be applied to a photosensitive resin composition. As a result, it was confirmed that the Examples have higher mechanical properties and chemical resistance as compared with Comparative Example 6. Furthermore, it was confirmed that the Examples have higher copper migration suppression performance as compared with Comparative Examples 4 and 5 in which a polyimide having a fluorine atom in the main chain skeleton was used. Since the Examples use a soluble polyimide having a ring-closed structure, it was confirmed that the change in film thickness before and after curing can be suppressed and high copper adhesion can be achieved, as compared with the case in which a polyimide precursor such as that in Comparative Example 7 is used as the component (A).

### INDUSTRIAL APPLICABILITY

By using the photosensitive resin composition according to the present invention, it is possible to provide a photosensitive resin composition which has high solubility despite using a resin having has an already ring-closed structure, and which is capable of forming a cured relief pattern that can achieve improved mechanical properties, suppressed cure shrinkage, improved copper adhesion, improved chemical resistance, and suppressed copper migration. The photosensitive resin composition according to the present invention, as well as a method for producing a polyimide cured film and a cured film using the same, can be suitably used in the field of photosensitive materials that are useful for producing electric and electronic materials such as semiconductor devices and multilayer wiring boards.

1. A photosensitive resin composition comprising:
(A) a polyimide of the following (A1) and/or (A2):
(A1) a polyimide having an aromatic ring in a side chain, and
(A2) a polyimide having a structure represented by the following general formula (1): 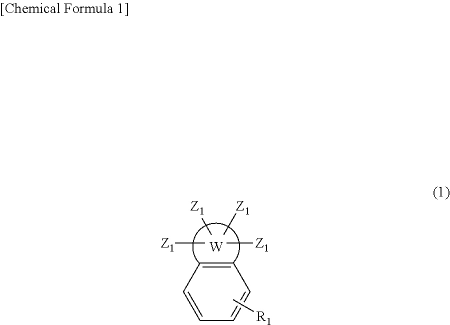
wherein W is an aromatic ring or aliphatic ring which may have any substituent other than Z₁ (in which those having an aromatic ring are excluded), at least two Z₁ of a plurality of Z₁ form a main chain together with W, the remaining Z₁ is a hydrogen atom, and R₁ is a hydrogen atom or a monovalent organic group (in which those having an aromatic ring are excluded),
(B) a solvent, and
(C) a photopolymerization initiator.

2. The photosensitive resin composition according to claim 1, wherein, in (A1), the side chain has a structure represented by the following general formula (2): 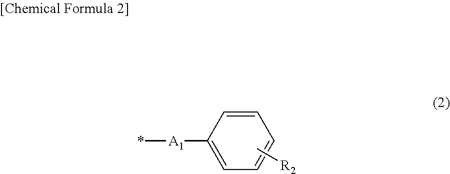
wherein A1 is a single bond, an alkylene group or an oxygen atom, * is a bonding site to the main chain, and R₂ is a hydrogen atom or a monovalent organic group, and
in the side chain, a ring containing an aromatic ring and R₂ in the general formula (2) may be formed.

3. The photosensitive resin composition according to claim 2, wherein the polyimide (A) does not have a photopolymerizable group in the side chain,
in the general formula (2), * is a bonding site to the aromatic ring of the main chain, and
the photopolymerization initiator (C) is a photoradical polymerization initiator.

4. The photosensitive resin composition according to claim 2, wherein the polyimide (A) does not contain a fluorine atom and a weighted average of the number of aromatic rings of a tetracarboxylic acid derivative used as a raw material is 2.0 or less, and
in which the weighted average is a weighted average of the number of aromatic rings contained in the tetracarboxylic acid derivative used as the raw material when the mixing amount of the tetracarboxylic acid derivative used as the raw material is treated as weight, and
the photopolymerization initiator (C) is a photoradical polymerization initiator.

5. The photosensitive resin composition according to claim 2, wherein the weighted average of the number of aromatic rings of a tetracarboxylic acid derivative used as a raw material of the polyimide (A) is 2 or less, and
in the general formula (2), * isa bonding site to the aromatic ring of the main chain, and
the photopolymerization initiator (C) is a photoradical polymerization initiator.

6. The photosensitive resin composition according to claim 2, wherein the polyimide (A) does not contain a fluorine atom, and does not have a photopolymerizable group in the side chain, and
the photopolymerization initiator (C) is a photoradical polymerization initiator.

7. The photosensitive resin composition according to claim 1, wherein the general formula (1) has a structure represented by the following formula: 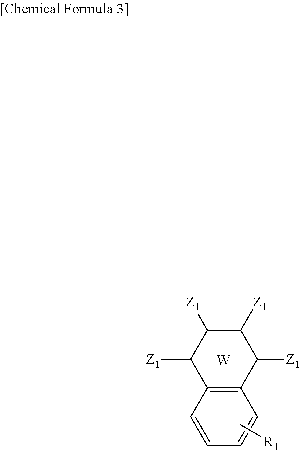
wherein W is a 6-membered ring, and Z1 and R1 are the same as in the general formula (1).

8. The photosensitive resin composition according to claim 1, wherein, in (A1), R2 of the general formula (2) is a hydrogen atom.

9. The photosensitive resin composition according to claim 1, wherein the polyimide (A) has a structure represented by the following general formula (3): 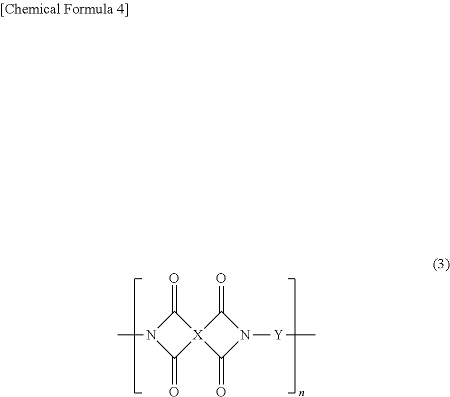
wherein n is a positive integer, and X is a tetravalent organic group having a structure represented by at least one selected from the group consisting of the following general formulas (4), (5) and (6): 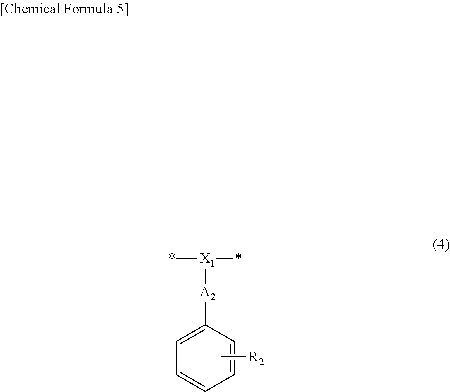
wherein X₁ is CH, C(CH₂)ₘCH₃ or a nitrogen atom, * forms a main chain together with X₁, A₂ is a single bond, an alkylene group or an oxygen atom, R₂ is a hydrogen atom or a monovalent organic group, and m is an integer of 0 to 10: 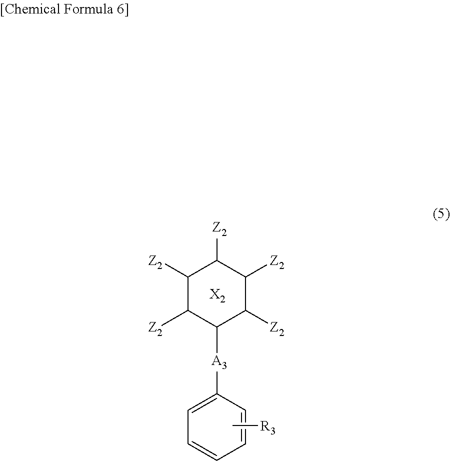
wherein X₂ is a 6-membered aromatic ring or 6-membered aliphatic ring which may have any substituent other than Z₂, A₃ is a single bond, an alkylene group or an oxygen atom, one to three Z₂ of a plurality of Z₂ is/are a hydrogen atom, the remaining Z₂ forms a main chain together with X₂, and R₃ is a hydrogen atom or a monovalent organic group, and: 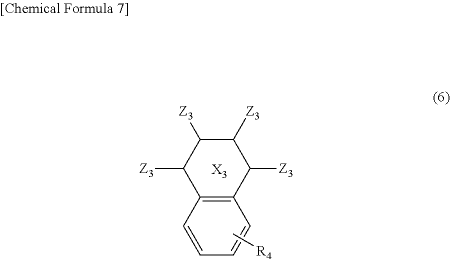
wherein X₃ is an aromatic ring or aliphatic ring which may have any substituent other than Z₃, zero to two Z₃ of a plurality of Z₃ is/are a hydrogen atom, the remaining Z₃ forms a main chain together with X₃, and R₄ is a hydrogen atom or a monovalent organic group, and/or
Y is a divalent organic group having a structure represented by at least one selected from the group consisting of the following general formulas (7) and (8): 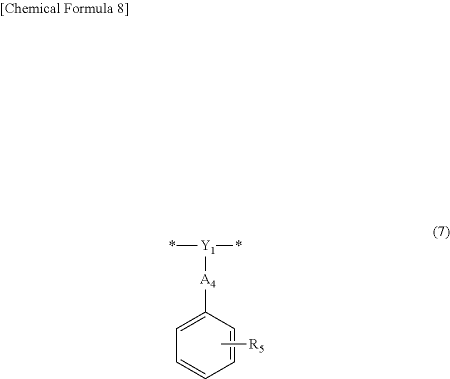
wherein Y₁ is CH, C(CH₂)ₘCH₃, a nitrogen atom, or a 6-membered aromatic ring, * forms a main chain together with Y₁, A₄ is a single bond, an alkylene group, or an oxygen atom, R₅ is a hydrogen atom or a monovalent organic group, and m is an integer of 0 to 10, and: 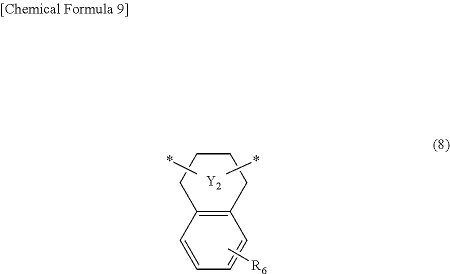
wherein Y₂ is a 6-membered aromatic ring or a 6-membered aliphatic ring, * forms a main chain together with Y₂, and R₆ is a hydrogen atom or a monovalent organic group.

10. The photosensitive resin composition according to claim 9, wherein, in the general formulas (4) to (8), R₂ to R₆ are each independently a hydrogen atom or a hydroxy group.

11. The photosensitive resin composition according to claim 1, wherein X in the general formula (3) has a structure represented by the following general formula (9):

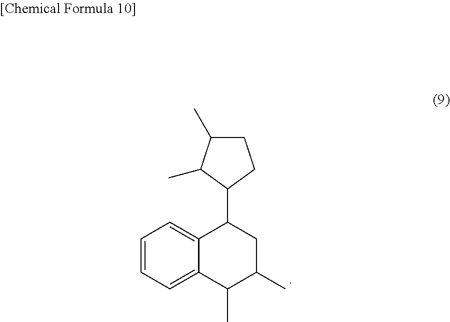

12. The photosensitive resin composition according to claim 9, wherein Y in the general formula (3) has a structure represented by the following general formula (10): 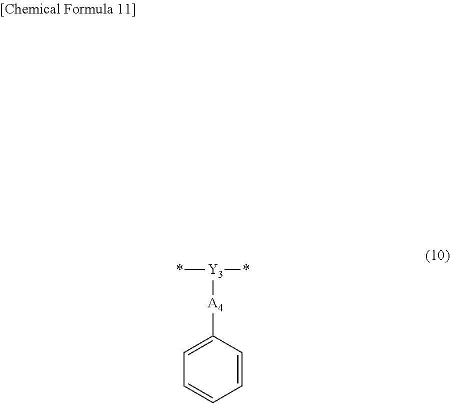
wherein Y₃ is a nitrogen atom, CH, C(CH₃) or an aromatic ring, * forms a main chain together with Y₃, and A₄ is a single bond or an oxygen atom.

13. The photosensitive resin composition according to claim 9, wherein Y in the general formula (3) has a structure represented by at least one selected from the group consisting of the following general formulas (11) to (14): 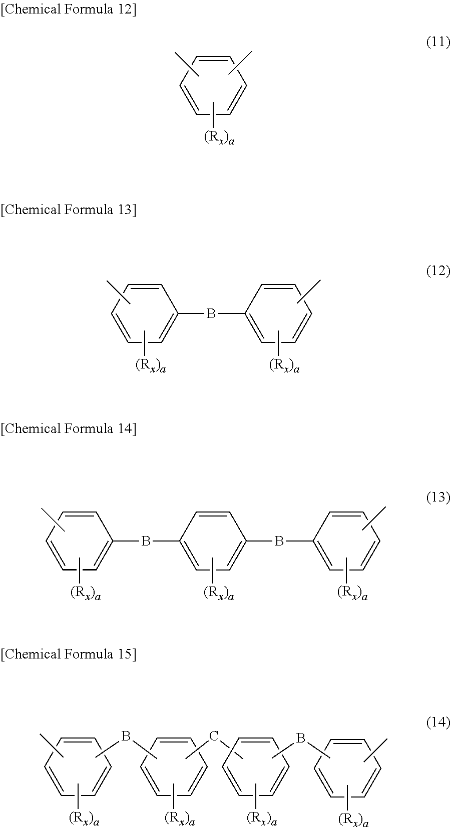
wherein R_{X} is each independently a monovalent organic group having 1 to 10 carbon atoms, and at least one of R_{X} as the side chain contains an aromatic ring, and a is each independently an integer of 0 to 4 (in which a corresponding to R_{X} as the side chain is an integer of 1 or more), B is a single bond, a methylene group or an oxygen atom, and C is a single bond or at least one selected from the group consisting of the following formulas, and:

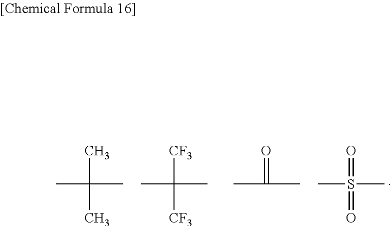

14. The photosensitive resin composition according to claim 9, wherein Y in the general formula (3) has a structure represented by at least one selected from the group consisting of the following general formulas (15) to (19):

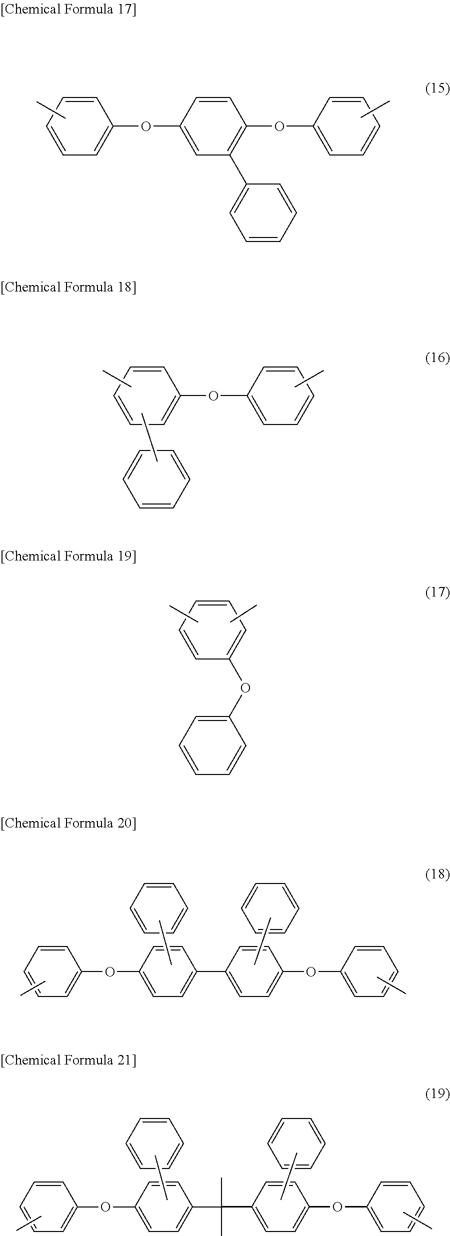

15. The photosensitive resin composition according to claim 9, wherein X in the general formula (3) has a structure represented by at least one selected from the group consisting of the following general formulas (20) to (25):

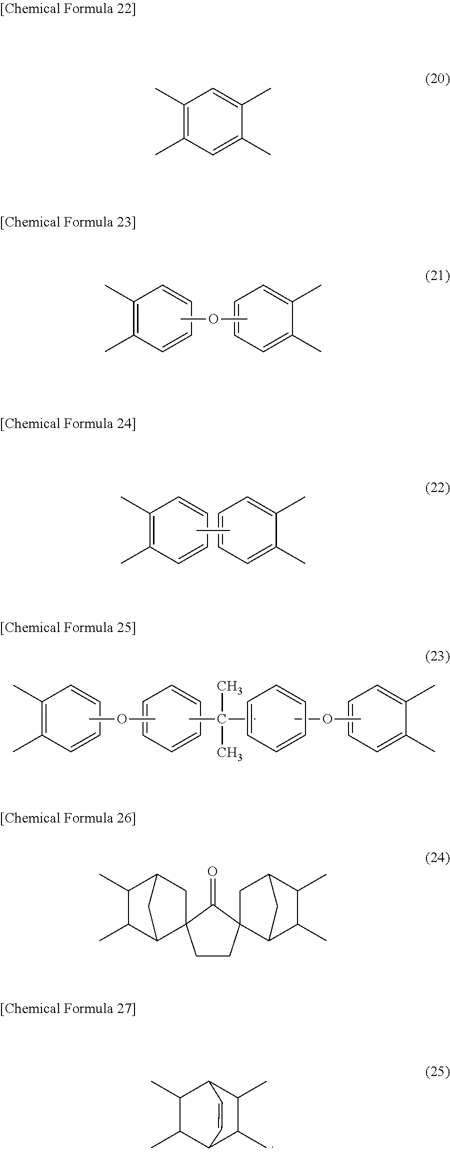

16. The photosensitive resin composition according to claim 9, wherein Y in the general formula (3) has a structure represented by at least one selected from the group consisting of the following general formulas (26) to (28): 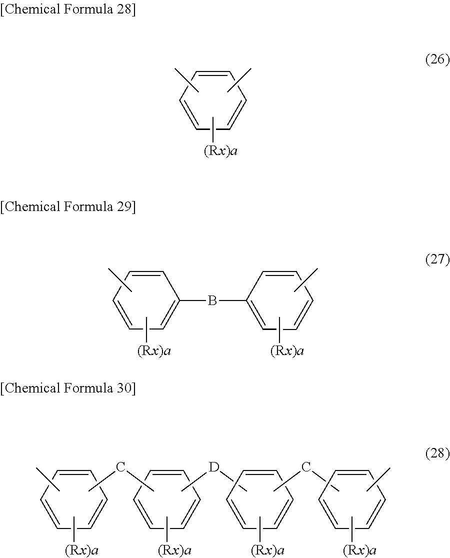
wherein R_{X} is each independently a monovalent organic group having 1 to 10 carbon atoms (in which those having an aromatic ring are excluded), a is each independently an integer of 0 to 4, B is a single bond, a methylene group, an oxygen atom or a sulfur atom, C is each independently an oxygen atom or a sulfur atom, and D is at least one selected from the group consisting of the following formulas:

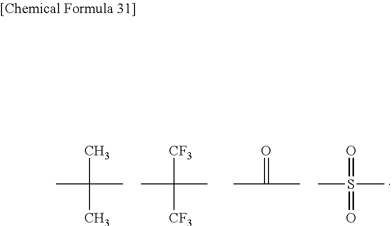

17. (canceled)

18. The photosensitive resin composition according to claim 1, further comprising, as (D) a monomer having a polymerizable functional group, (D1) a monofunctional monomer and (D2) a polyfunctional monomer, wherein a mass ratio (D1/D2) of the monofunctional monomer (D1) with respect to the polyfunctional monomer (D2) is more than 0.01 and less than 5.

19. (canceled)

20. The photosensitive resin composition according to claim 1, further comprising (F) a rust inhibitor.

21. The photosensitive resin composition according to claim 1, further comprising (G) an organic titanium compound.

22. The photosensitive resin composition according to claim 1, further comprising (H) a plasticizer.

23. (canceled)

24. (canceled)

25. The photosensitive resin composition according to claim 1, wherein the polyimide (A) has polymerizable functional group at the end of the main chain.

26. (canceled)

27. (canceled)

28. (canceled)

29. (canceled)

30. (canceled)

31. (canceled)
